(19) United States
(12) Patent Application Publication
(10) Pub. No.: US 2021/0317144 A1
(43) Pub. Date: Oct. 14, 2021

(54) Boron compound and organic light emitting diode including the same

(71) Applicant: SFC CO., LTD., Cheongju-si (KR)

(72) Inventors: Kyung-Tae Kim, Cheongju-si (KR); Se-Jin Lee, Cheongju-si (KR); Yeong-Tae Choi, Cheongju-si (KR); Ji-Yung Kim, Cheongju-si (KR); Myeong-Jun Kim, Cheongju-si (KR); Kyeong-Hyeon Kim, Cheongju-si (KR)

(21) Appl. No.: 17/218,196

(22) Filed: Mar. 31, 2021

(30) Foreign Application Priority Data
Apr. 2, 2020 (KR) 10-2020-0040548
Mar. 26, 2021 (KR) 10-2021-0039419

(51) Int. Cl. C07F 5/02; H01L 51/00

(52) U.S. Cl. CPC C07F 5/02; H01L 51/006; H01L 51/0061; H01L 51/0072; H01L 51/5012; H01L 51/0073; H01L 51/0074; H01L 51/0052; H01L 51/0094

(57) ABSTRACT

Disclosed herein are a boron compound available for an organic light-emitting diode and an organic light-emitting diode including same. More particularly, a boron compound represented by Chemical Formula A and an organic light-emitting diode including same are provided. Chemical Formula A is as defined in the description.

### CROSS-REFERENCE TO RELATED APPLICATIONS

This application claims the priority of the Korean Patent Applications NO 10-2020-0040548 filed on Apr. 2, 2020, and NO 10-2021-0039419 filed on Mar. 26, 2021 in the Korean Intellectual Property Office, the disclosure of which is incorporated herein by reference.

### BACKGROUND OF THE INVENTION

### 1. Field of the Invention

The present disclosure relates to a novel boron compound useful for an organic light-emitting diode and, more particularly, to a novel boron compound that can be used as a dopant material in an organic light-emitting diode and allow for excellent diode characteristics including high luminous efficiency, and an organic light-emitting diode comprising the same.

### 2. Description of the Related Art

Organic light-emitting diodes (OLEDs), based on self-luminescence, are used to create digital displays with the advantage of having a wide viewing angle and being able to be made thinner and lighter than liquid crystal displays. In addition, an OLED display exhibits a very fast response time. Accordingly, OLEDs find applications in the full color display field or the illumination field.

In general, the team “organic light-emitting phenomenon” refers to a phenomenon in which electrical energy is converted to light energy by means of an organic material. An organic light-emitting diode using the organic light-emitting phenomenon has a structure usually including an anode, a cathode, and an organic material layer interposed therebetween. In this regard, the organic material layer may have, for the most part, a multilayer structure consisting of different materials, for example, a hole injection layer, a hole transport layer, a light-emitting layer, an electron transport layer, and an electron injection layer in order to enhance the efficiency and stability of the organic light-emitting diode. In the organic light-emitting diode having such a structure, application of a voltage between the two electrodes injects a hole from the anode and an electron from the cathode to the organic layer. In the luminescent zone, the hole and the electron recombine to produce an exciton. When the exciton returns to the ground state from the excited state, the molecule of the organic layer emits light. Such an organic light-emitting diode is known to have characteristics such as self-luminescence, high luminance, high efficiency, low driving voltage, a wide viewing angle, high contrast, and high-speed response.

Materials used as organic layers in OLEDs may be divided according to functions into luminescent materials and charge transport materials, for example, a hole injection material, a hole transport material, an electron transport material, and an electron injection material and, as needed, further into an electron-blocking material or a hole-blocking material.

As for the luminescent materials, there are two main families of OLED: those based on small molecules and those employing polymers. The light-emitting mechanism forms the basis of classification of luminescent materials as fluorescent and phosphorescent materials, which use excitons in singlet and triplet states, respectively.

When a single material is employed as the luminescent material, intermolecular actions cause the maximum luminescence wavelength to shift toward a longer wavelength, resulting in a reduction in color purity and luminous efficiency due to light attenuation. In this regard, a host-dopant system may be used as a luminescent material so as to increase the color purity and the luminous efficiency through energy transfer.

This is based on the principle whereby, when a dopant which is smaller in energy band gap than a host foaming a light-emitting layer is added in a small amount to the light-emitting layer, excitons are generated from the light-emitting layer and transported to the dopant, emitting light at high efficiency. Here, light with desired wavelengths can be obtained depending on the kind of the dopant because the wavelength of the host moves to the wavelength range of the dopant.

With regard to related art pertaining to the use of boron compounds as dopant compounds, reference may be made to Korean Patent No. 10-2016-0119683 A (issued Oct. 14, 2016), which discloses an organic light-emitting diode employing a novel polycyclic aromatic compound in which multiple aromatic rings are connected via boron and oxygen atoms. In addition, International Patent No. WO 2017/188111 (Nov. 2, 2017) disclosed an organic light emitting diode employing a light emitting layer in which a compound structured to connect polycyclic aromatic rings via boron and nitrogen atoms and an anthracene derivative are employed.

In spite of a variety of kinds of compounds prepared for use in light emitting layers in organic light emitting diodes including the related arts, there is still a continuing need to develop a novel compound that allows an OLED to be stably driven and exhibits high efficiency, and an OLED including the same.

### Related Documents

Korean Patent Number 10-2016-0119683 A (Oct. 14, 2016)

International Patent Number WO/KR2017/188111 A (2017 Nov. 2)

### SUMMARY OF THE INVENTION

Therefore, an aspect of the present disclosure is to provide a boron compound having a novel structure which can be used as a dopant material in a light-emitting layer of an organic light-emitting diode.

In addition, another aspect of the present invention is to provide an organic light-emitting diode (OLED) having the boron compound applied as a dopant material therein and exhibiting excellent diode characteristics including high luminous efficiency.

In order to accomplish the purposes, the present disclosure provides a boron compound represented by the following Chemical Formula A:

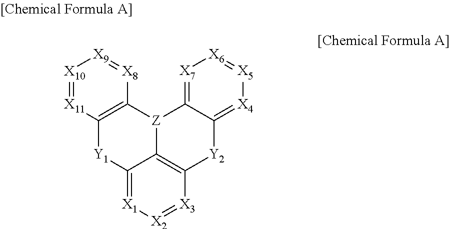

wherein,

X₁ is C—R₁ or a nitrogen atom (N),

X₂ is C—R₂ or a nitrogen atom (N),

X₃ is C—R₃ or a nitrogen atom (N),

X₄ is C—R₄ or a nitrogen atom (N),

X₅ is C—R₅ or a nitrogen atom (N),

X₆ is C—R₆ or a nitrogen atom (N),

X₇ is C—R₇ or a nitrogen atom (N),

X₈ is C—R₈ or a nitrogen atom (N),

X₉ is C—R₉ or a nitrogen atom (N),

X₁₀ is C—R₁₀ or a nitrogen atom (N),

X₁₁ is C—Rn or a nitrogen atom (N),

with a proviso that only one of X₁ to X₃ is a nitrogen atom (N) such that the aromatic ring moiety bearing X₁ to X₃ is a pyridine ring, only one of X₄ to X₇ is a nitrogen atom (N) such that the aromatic ring moiety bearing X₄ to X₇ is a pyridine ring; and/or only one of X₈ to X₁₁ is a nitrogen atom (N) such that the aromatic ring moiety bearing X₈ to X₁₁ is a pyridine ring, whereby one to three pyridine rings exist in Chemical Formula A,

Z is any one selected from B, P, P═O, and P═S,

Y₁ is any one selected from CR₂₁R₂₂, NR₂₃, O, and S,

Y₂ is any one selected from CR₂₄R₂₅, NR₂₆, O, and S,

R₁ to R₁₁ and R₂₁ to R₂₆, which may be same or different, are each independently any one selected from a hydrogen atom, a deuterium, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted alkylsilyl of 1 to 30 carbon atoms, a substituted or unsubstituted arylsilyl of 6 to 30 carbon atoms, a nitro, a cyano, a halogen, and —N(R₂₇)(R₂₈),

R₂₇ and R₂₈, which are same or different, are each independently selected from a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, and a substituted or unsubstituted heteroaryl of 2 to 50 carbon atoms, and may be connected to each other to additionally form an aliphatic or aromatic mono- or polycyclic ring,

adjacent any two of R₁ to R₁₁ may be connected to each other to additionally form an aliphatic or aromatic mono- or polycyclic ring,

R₂₁ and R₂₂ may be connected to each other to additionally form an aliphatic or aromatic mono- or polycyclic ring,

R₂₄ and R₂₅ may be connected to each other to additionally form an aliphatic or aromatic mono- or polycyclic ring,

one of R₂₁ to R₂₃ may be connected to R₁ or CR₁₁ to additionally form an aliphatic or aromatic mono- or polycyclic ring, and

one of R₂₄ to R₂₆ may be connected to R₃ or R₄ to additionally form an aliphatic or aromatic mono- or polycyclic ring,

wherein, the term “substituted” in the expression “substituted or unsubstituted” used for compounds of Chemical Formula A means having at least one substituent selected from the group consisting of a deuterium atom, a cyano, a halogen, a hydroxy, a thiol, a nitro, an alkyl of 1 to 24 carbon atoms, a halogenated alkyl of 1 to 24 carbon atoms, an alkenyl of 2 to 24 carbon atoms, an alkynyl of 2 to 24 carbon atoms, a heteroalkyl of 1 to 24 carbon atoms, a cycloalkyl of 3 to 24 carbon atoms, an aryl of 6 to 24 carbon atoms, an arylalkyl of 7 to 24 carbon atoms, an alkylaryl of 7 to 24 carbon atoms, a heteroaryl of 2 to 24 carbon atoms, a heteroarylalkyl of 2 to 24 carbon atoms, an alkoxy of 1 to 24 carbon atoms, an alkylamino of 1 to 24 carbon atoms, a diarylamino of 12 to 24 carbon atoms, a diheteroarylamino of 2 to 24 carbon atoms, an aryl(heteroaryl)amino of 7 to 24 carbon atoms, an alkylsilyl of 1 to 24 carbon atoms, an arylsilyl of 6 to 24 carbon atoms, an aryloxy of 6 to 24 carbon atoms, and an arylthionyl group of 6 to 24 carbon atoms.

### BRIEF DESCRIPTION OF THE DRAWINGS

FIG. 1 is a schematic diagram of an organic light-emitting diode according to some embodiments of the present disclosure.

### DETAILED DESCRIPTION

Below, a detailed description will be given of the present disclosure. In each drawing of the present disclosure, sizes or scales of components may be enlarged or reduced from their actual sizes or scales for better illustration, and known components may not be depicted therein to clearly show features of the present disclosure. Therefore, the present disclosure is not limited to the drawings. When describing the principle of the embodiments of the present disclosure in detail, details of well-known functions and features may be omitted to avoid unnecessarily obscuring the presented embodiments.

In drawings, for convenience of description, sizes of components may be exaggerated for clarity. For example, since sizes and thicknesses of components in drawings are arbitrarily shown for convenience of description, the sizes and thicknesses are not limited thereto. Furthermore, throughout the description, the terms “on” and “over” are used to refer to the relative positioning, and mean not only that one component or layer is directly disposed on another component or layer but also that one component or layer is indirectly disposed on another component or layer with a further component or layer being interposed therebetween. Also, spatially relative terms, such as “below”, “beneath”, “lower”, and “between” may be used herein for ease of description to refer to the relative positioning.

Throughout the specification, when a portion may “include” a certain constituent element, unless explicitly described to the contrary, it may not be construed to exclude another constituent element but may be construed to further include other constituent elements. Further, throughout the specification, the word “on” means positioning on or below the object portion, but does not essentially mean positioning on the lower side of the object portion based on a gravity direction.

The present disclosure provides a boron compound represented by the following Chemical Formula A:

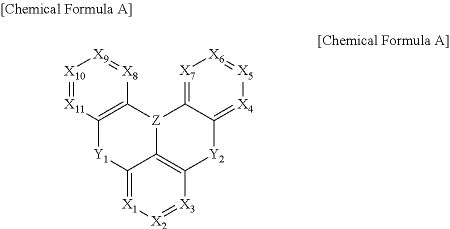

wherein,

X₁ is C—R₁ or a nitrogen atom (N),

X₂ is C—R₂ or a nitrogen atom (N),

X₃ is C—R₃ or a nitrogen atom (N),

X₄ is C—R₄ or a nitrogen atom (N),

X₅ is C—R₅ or a nitrogen atom (N),

X₆ is C—R₆ or a nitrogen atom (N),

X₇ is C—R₇ or a nitrogen atom (N),

X₈ is C—R₈ or a nitrogen atom (N),

X₉ is C—R₉ or a nitrogen atom (N),

X₁₀ is C—R₁₀ or a nitrogen atom (N),

X₁₁ is C—R₁₁ or a nitrogen atom (N),

with a proviso that only one of X₁ to X₃ is a nitrogen atom (N) such that the aromatic ring moiety bearing X₁ to X₃ is a pyridine ring, only one of X₄ to X₇ is a nitrogen atom (N) such that the aromatic ring moiety bearing X₄ to X₇ is a pyridine ring; and/or only one of X₈ to X₁₁ is a nitrogen atom (N) such that the aromatic ring moiety bearing X₈ to X₁₁ is a pyridine ring, whereby one to three pyridine rings exist in Chemical Formula A,

Z is any one selected from B, P, P═O, and P═S,

Y₁ is any one selected from CR₂₁R₂₂, NR₂₃, O, and S,

Y₂ is any one selected from CR₂₄R₂₅, NR₂₆, O, and S,

R₁ to R₁₁ and R₂₁ to R₂₆, which may be the same or different, are each independently any one selected from a hydrogen atom, a deuterium, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted alkylsilyl of 1 to 30 carbon atoms, a substituted or unsubstituted arylsilyl of 6 to 30 carbon atoms, a nitro, a cyano, a halogen, and —N(R₂₇) (R₂₈),

R₂₇ and R₂₈, which are same or different, are each independently selected from a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, and a substituted or unsubstituted heteroaryl of 2 to 50 carbon atoms, and may be connected to each other to additionally form an aliphatic or aromatic mono- or polycyclic ring,

adjacent any two of R₁ to R₁₁ may be connected to each other to additionally form an aliphatic or aromatic mono- or polycyclic ring,

R₂₁ and R₂₂ may be connected to each other to additionally form an aliphatic or aromatic mono- or polycyclic ring,

R₂₄ and R₂₅ may be connected to each other to additionally form an aliphatic or aromatic mono- or polycyclic ring,

one of R₂₁ to R₂₃ may be connected to R₁ or CR₁₁ to additionally form an aliphatic or aromatic mono- or polycyclic ring, and

one of R₂₄ to R₂₆ may be connected to R₃ or R₄ to additionally form an aliphatic or aromatic mono- or polycyclic ring,

wherein, the term “substituted” in the expression “substituted or unsubstituted” used for compounds of Chemical Formula A means having at least one substituent selected from the group consisting of a deuterium atom, a cyano, a halogen, a hydroxy, a thiol, a nitro, an alkyl of 1 to 24 carbon atoms, a halogenated alkyl of 1 to 24 carbon atoms, an alkenyl of 2 to 24 carbon atoms, an alkynyl of 2 to 24 carbon atoms, a heteroalkyl of 1 to 24 carbon atoms, a cycloalkyl of 3 to 24 carbon atoms, an aryl of 6 to 24 carbon atoms, an arylalkyl of 7 to 24 carbon atoms, an alkylaryl of 7 to 24 carbon atoms, a heteroaryl of 2 to 24 carbon atoms, a heteroarylalkyl of 2 to 24 carbon atoms, an alkoxy of 1 to 24 carbon atoms, an alkylamino of 1 to 24 carbon atoms, a diarylamino of 12 to 24 carbon atoms, a diheteroarylamino of 2 to 24 carbon atoms, an aryl(heteroaryl)amino of 7 to 24 carbon atoms, an alkylsilyl of 1 to 24 carbon atoms, an arylsilyl of 6 to 24 carbon atoms, an aryloxy of 6 to 24 carbon atoms, and an arylthionyl group of 6 to 24 carbon atoms.

The expression indicating the number of carbon atoms, such as “a substituted or unsubstituted alkyl of 1 to 30 carbon atoms”, “a substituted or unsubstituted aryl of 6 to 50 carbon atoms”, etc. means the total number of carbon atoms of, for example, the alkyl or aryl radical or moiety alone, exclusive of the number of carbon atoms of substituents attached thereto. For instance, a phenyl group with a butyl at the para position falls within the scope of an aryl of 6 carbon atoms, even though it is substituted with a butyl radical of 4 carbon atoms.

As used herein, the term “aryl” means an organic radical derived from an aromatic hydrocarbon by removing one hydrogen that is bonded to the aromatic hydrocarbon. The aromatic system may include a fused ring that is formed by adjacent substituents on the aryl radical.

Concrete examples of the aryl include phenyl, o-biphenyl, m-biphenyl, p-biphenyl, o-terphenyl, m-terphenyl, p-terphenyl, naphthyl, anthryl, phenanthryl, pyrenyl, indenyl, fluorenyl, tetrahydronaphthyl, perylenyl, chrysenyl, naphthacenyl, and fluoranthenyl. At least one hydrogen atom of the aryl may be substituted by a deuterium atom, a halogen atom, a hydroxy, a nitro, a cyano, a silyl, an amino (—NH₂, —NH(R), —N(R′) (R″) wherein R′ and R″ are each independently an alkyl of 1 to 10 carbon atoms, in this case, called “alkylamino”), an amidino, a hydrazine, a hydrazone, a carboxyl, a sulfonic acid, a phosphoric acid, an alkyl of 1 to 24 carbon atoms, a halogenated alkyl of 1 to 24 carbon atoms, an alkenyl of 1 to 24 carbon atoms, an alkynyl of 1 to 24 carbon atoms, a heteroalkyl of 1 to 24 carbon atoms, an aryl of 6 to 24 carbon atoms, an arylalkyl of 6 to 24 carbon atoms, a heteroaryl of 2 to 24 carbon atoms, or a heteroarylalkyl of 2 to 24 carbon atoms.

The term “heteroaryl substituent” used in the compound of the present disclosure refers to a hetero aromatic radical of 2 to 50 carbon atoms, preferably 2 to 24 carbon atoms, bearing 1 to 3 heteroatoms selected from among N, O, P, Si, S, Ge, Se, and Te. In the aromatic radical, two or more rings may be fused. One or more hydrogen atoms on the heteroaryl may be substituted by the same substituents as on the aryl.

In addition, the term “heteroaromatic ring”, as used herein, refers to an aromatic hydrocarbon ring bearing at least one heteroatom as aromatic ring member. In the heteroaromatic ring, one to three carbon atoms of the aromatic hydrocarbon may be substituted by at least one selected particularly from N, O, P, Si, S, Ge, Se, and Te.

As used herein, the term “alkyl” refers to an alkane missing one hydrogen atom and includes linear or branched structures. Examples of the alkyl substituent useful in the present disclosure include methyl, ethyl, propyl, isopropyl, isobutyl, sec-butyl, tert-butyl, pentyl, isoamyl, and hexyl. At least one hydrogen atom of the alkyl may be substituted by the same substituent as in the aryl.

The term “cyclo” as used in cycloalkyl substituents of the present disclosure refers to a structure responsible for a mono- or polycyclic ring of saturated hydrocarbons in alkyl radicals. Concrete examples of cycloalkyl radicals include cyclopropyl, cyclobutyl, cyclopentyl, cyclohexyl, methylcyclopentyl, methylcyclohexyl, ethylcyclopentyl, ethylcyclohexyl, adamantyl, dicyclopentadienyl, decahydronaphthyl, norbornyl, bornyl, and isobornyl. One or more hydrogen atoms on the cycloalkyl may be substituted by the same substituents as on the aryl.

The term “alkoxy” as used in the compounds of the present disclosure refers to an alkyl or cycloalkyl singularly bonded to oxygen. Concrete examples of the alkoxy include methoxy, ethoxy, propoxy, isobutoxy, sec-butoxy, pentoxy, iso-amyloxy, hexyloxy, cyclobutyloxy, cyclopentyloxy, adamantyloxy, dicyclopentyloxy, bornyloxy, and isobornyloxy. One or more hydrogen atoms on the alkoxy may be substituted by the same substituents as on the aryl.

Concrete examples of the arylalkyl used in the compounds of the present disclosure include phenylmethyl (benzyl), phenylethyl, phenylpropyl, naphthylmethyl, and naphthylethyl. One or more hydrogen atoms on the arylalkyl may be substituted by the same substituents as on the aryl.

Concrete examples of the silyl radicals used in the compounds of the present disclosure include trimethylsilyl, triethylsilyl, triphenylsilyl, trimethoxysilyl, dimethoxyphenylsilyl, diphenylmethylsilyl, diphenylvinlysilyl, methylcyclobutylsilyl, and dimethyl furylsilyl. One or more hydrogen atoms on the silyl may be substituted by the same substituents as on the aryl.

As used herein, the term “alkenyl” refers to an unsaturated hydrocarbon group that contains a carbon-carbon double bond between two carbon atoms and the term “alkynyl” refers to an unsaturated hydrocarbon group group that contains a carbon-carbon triple bond between two carbon atoms.

As used herein, the term “alkylene” refers to an organic aliphatic radical regarded as derived from a linear or branched saturated hydrocarbon alkane by removal of two hydrogen atoms from different carbon atoms. Concrete examples of the alkylene include methylene, ethylene, propylene, isopropylene, isobutylene, sec-butylene, tert-butylene, pentylene, iso-amylene, hexylene, and so on. One or more hydrogen atoms on the alkylene may be substituted by the same substituents as on the aryl

Furthermore, as used herein, the term “diarylamino” refers to an amine radical having two identical or different aryl groups bonded to the nitrogen atom thereof, the term “diheteroarylamino” refers to an amine radical having two identical or different heteroaryl groups bonded to the nitrogen atom thereof, and the term “aryl (heteroaryl)amino” refers to an amine radical having an aryl group and a heteroaryl group both bonded to the nitrogen atom thereof.

As more particular examples accounting for the term “substituted” in the expression “substituted or unsubstituted” used for compounds of Chemical Formula A the compounds may be substituted by at least one substituents selected from the group consisting of a deuterium atom, a cyano, a halogen, a hydroxy, a nitro, an alkyl of 1 to 12 carbon atoms, a halogenated alkyl of 1 to 12 carbon atoms, an alkenyl of 2 to 12 carbon atoms, an alkynyl of 2 to 12 carbon atoms, a cycloalkyl of 3 to 12 carbon atoms, a heteroalkyl of 1 to 12 carbon atoms, an aryl of 6 to 18 carbon atoms, an arylalkyl of 7 to 20 carbon atoms, an alkylaryl of 7 to 20 carbon atoms, a heteroaryl of 2 to 18 carbon atoms, a heteroarylalkyl of 2 to 18 carbon atoms, an alkoxy of 1 to 12 carbon atoms, an alkylamino of 1 to 12 carbon atoms, a diarylamino of 12 to 18 carbon atoms, a diheteroarylamino of 2 to 18 carbon atoms, an aryl(heteroaryl)amino of 7 to 18, an alkylsilyl of 1 to 12 carbon atoms, an arylsilyl of 6 to 18 carbon atoms, an aryloxy of 6 to 18 carbon atoms, and an arylthionyl of 6 to 18 carbon atoms.

The boron compound, represented by [Chemical Formula A], of the present disclosure will be explained, in detail, below.

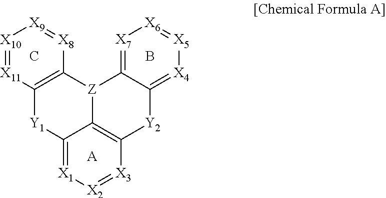

In the present disclosure, the boron compound represented by Chemical Formula A is characterized by the structure in which aromatic ring moiety A bearing X₁ to X₃, aromatic ring moiety B bearing X₄ to X₇, and aromatic ring moiety C bearing X₈ to X₁₁ are each connected to the central atom (Z), with a linkage via linker Y₁ between aromatic ring moiety A and aromatic ring moiety C and via linker Y₂ between aromatic ring moiety A and aromatic ring moiety B, wherein only one of X₁ to X₃ is a nitrogen atom (N) such that the aromatic ring moiety bearing X₁ to X₃ is a pyridine ring, only one of X₄ to X₇ is a nitrogen atom (N) such that the aromatic ring moiety bearing X₄ to X₇ is a pyridine ring; and/or only one of X₈ to X₁₁ is a nitrogen atom (N) such that the aromatic ring moiety bearing X₈ to X₁₁ is a pyridine ring, whereby one to three pyridine rings exist in Chemical Formula A.

That is, the boron compound of Chemical Formula A is structured to have aromatic ring moiety A that is linked via linker Y₁ to aromatic ring moiety C and via linker Y₂ to aromatic ring moiety B, wherein at least one of aromatic ring moiety A, aromatic ring moiety B, and aromatic ring moiety C includes a pyridine ring as the aromatic ring moiety A, the aromatic ring moiety B, and/or the aromatic ring moiety C has a pyridine ring.

In the boron compound of Chemical Formula A according to an embodiment, the linker Y₁ may be NR₂₃, or the linker Y₂ may be NR₂₆.

According to a particular embodiment, the linker Y₁ is NR₂₃ and the linker Y₂ is NR₂₆ wherein R₂₃ and R₂₆ are as defined above.

In the boron compound of Chemical Formula A according to an embodiment, the linker Y₁ is NR₂₃, or the linker Y₂ is NR₂₆ wherein R₂₃ and R₂₆, which may be same or different, are each independently a substituted or unsubstituted aryl of 6 to 18 carbon atoms or a substituted or unsubstituted heteroaryl of 2 to 18 carbon atoms.

In the boron compound of Chemical Formula A according to another embodiment, the linker Y₁ is NR₂₃, or the linker Y₂ is NR₂₆ wherein R₂₃ and R₂₆, which may be same or different, are each independently selected from a substituted or unsubstituted phenyl, a substituted or unsubstituted naphthylyl, a substituted or unsubstituted biphenyl, a substituted or unsubstituted anthracenyl, a substituted or unsubstituted phenanthrenyl, a substituted or unsubstituted fluorenyl, and a substituted or unsubstituted dibenzofuran.

According to an embodiment, the central atom (Z) in Chemical Formula A of the present disclosure is a boron (B) atom.

In the compound of Chemical Formula A according to an embodiment of the present disclosure, the aromatic ring moiety A bearing X₁ to X₃ wherein only one of X₁ to X₁₁ may be a nitrogen atom (N) is a pyridine ring while neither the aromatic ring moiety B bearing X₄ to X₇; nor the aromatic ring moiety C bearing X₈ to X₁₁ may bear a nitrogen atom (N).

That is, the boron compound represented by [Chemical Formula A] according to the present disclosure may bear a nitrogen atom (N) for only one of X₁ to X₃, amounting to any one of the following Chemical Formulas A-1 to A-3, each including pyridine ring A′, wherein X₄ to X₁₁ are CR₄ to CR₁₁ corresponding thereto, respectively.

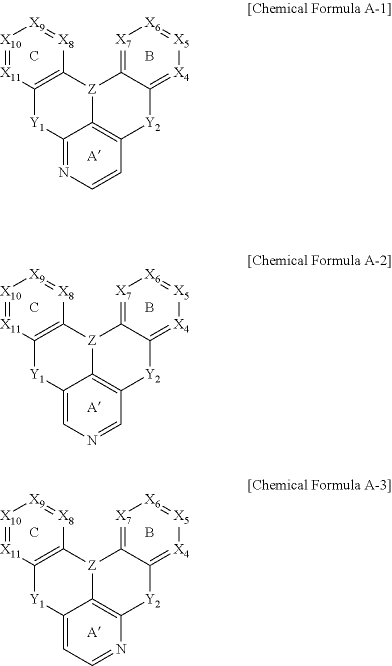

The boron compound represented by [Chemical Formula A] according to an embodiment of the present disclosure may bear a nitrogen atom (N) for only one of X₄ to X₇, amounting to any one of the following Chemical Formulas A-4 to A-7, each including pyridine ring B′, wherein X₁ to X₃ and X₈ to X₁₁ are CR₁ to CR₃ and CR₈ to CR₁₁ corresponding thereto, respectively.

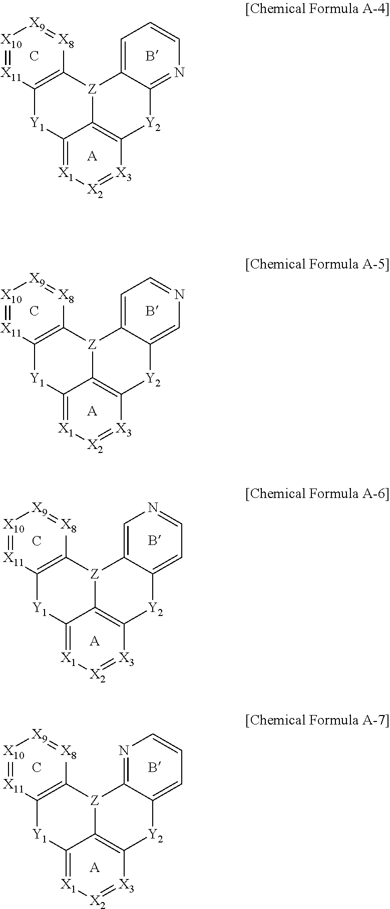

The boron compound represented by [Chemical Formula A] according to an embodiment of the present disclosure may bear a nitrogen atom (N) for only one of X₈ to X₁₁, amounting to any one of the following Chemical Formulas A-8 to A-11, each including pyridine ring C′, wherein X₁ to X₇ are CR₁ to CR₇ corresponding thereto, respectively.

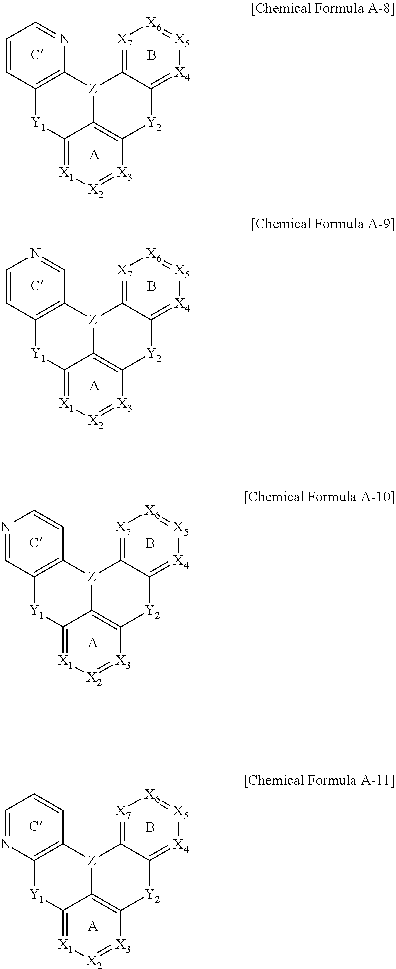

In other words, the boron compound represented by Chemical Formula A according to the present disclosure may be structurally characterized in that: by including: pyridine ring A′ resulting from a nitrogen atom (N) set to be only one of X₁ to X₃ with the other two rings being aromatic hydrocarbon rings; pyridine ring B′ resulting from a nitrogen atom (N) set to be only one of X₄ to X₇ with the other two rings being aromatic hydrocarbon rings; or pyridine ring C′ resulting from a nitrogen atom (N) set to be only one of X₈ to X₁₁ with the other two rings being aromatic hydrocarbon rings.

In addition, the boron compound represented by Chemical Formula A according to an embodiment of the present invention may include two respective pyridine rings for two of the aromatic ring moiety A bearing X₁ to X₃; the aromatic ring moiety B bearing X₄ to X₇; and the aromatic ring moiety C bearing X₈ to X₁₁, with the other one aromatic ring bearing no nitrogen atoms (N).

That is, the boron compound according to the present disclosure may include two pyridine rings which are set forth for a combination of the aromatic ring moiety A bearing X₁ to X₃ and the aromatic ring moiety B bearing X₄ to X₇, a combination of the aromatic ring moiety B bearing X₄ to X₇ and the aromatic ring moiety C bearing X₈ to X₁₁, or a combination of the aromatic ring moiety C bearing X₈ to X₁₁ and the aromatic ring moiety A bearing X₁ to X₃.

In accordance with an embodiment of the present disclosure, the boron compound represented by Chemical Formula A may include three pyridine rings set forth for all of the aromatic ring moiety A bearing X₁ to X₃; the aromatic ring moiety B bearing X₄ to X₇; and the aromatic ring moiety C bearing X₈ to X₁₁.

Given such technical features, the boron compound represented by Chemical Formula A provides an organic light-emitting device with higher efficiency than do conventional boron compounds in which the three aromatic ring moieties directly linked to the central element boron are composed of aromatic hydrocarbon ring.

In the boron compound represented by Chemical Formula A according to an embodiment of the present disclosure, adjacent two of the substituents R₁ to Ru on the aromatic hydrocarbon ring moiety (or moieties) which is (are) not a pyridine ring (or pyridine rings) may be connected to each other to additionally form an aliphatic or aromatic mono- or polycyclic ring, and particularly form a substituted or unsubstituted fluorene ring, a substituted or unsubstituted dibenzofuran ring, a substituted or unsubstituted dibenzothiophene ring, a substituted or unsubstituted carbazole ring, and so on.

By way of example, the two adjacent substituents R₄ and R₆ on B ring moiety in the compound of Chemical Formula A-3 may be connected to each other to finally form a fluorene ring inclusive of the B ring moiety. The adjacent substituents R₁ and R₂ on A ring moiety in the compound of Chemical Formula A-8 may be connected to each other to finally form a dibenzofuran ring inclusive of the A ring moiety.

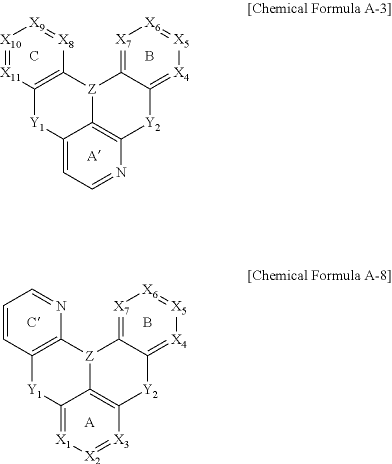

In the compound of Chemical Formula A according to an embodiment of the present disclosure, at least one of: the substituents R₁ to R₃ which each bond to an aromatic carbon atom in the aromatic ring moiety bearing X₁ to X₃; the substituents R₄ to R₇ which each bond to an aromatic carbon atom in the aromatic ring moiety bearing X₄ to X₇; and the substituents R₈ to R₁₁ which each bond to an aromatic carbon atom in the aromatic ring moiety bearing X₈ to X₁₁ may be an amine represented by —N(R₂₇) (R₂₈). Particularly, one or two of the substituents R₁ to R₁₁ may each be an amine represented by —N(R₂₇) (R₂₈). When two of R₁ to R₁₁ each are an amine represented by —N(R₂₇) (R₂₈), the corresponding amines may be same or different.

In detail, when only one of the substituents R₁ to R₁₁ in the compound of Chemical Formula A according to the present disclosure is an amine represented by —N(R₂₇) (R₂₈), it bonds to any one of the aromatic ring moiety A bearing X₁ to X₃, the aromatic ring moiety B bearing X₄ to X₇, and the aromatic ring moiety C bearing X₈ to X₁₁. In some particular embodiment, the amine is linked to the aromatic ring moiety B bearing X₄ to X₇, explaining that one of R₄ to R₇ which bond to aromatic carbon atoms in the aromatic ring moiety bearing X₄ to X₇ is an amine represented by —N(R₂₇) (R₂₈); or the amine is linked to the aromatic ring moiety C bearing X₈ to X₁₁, explaining that one of R₈ to R₁₁ bonds to aromatic carbon atoms in the aromatic ring moiety bearing X₈ to X₁₁ is an amine represented by —N(R₂₇) (R₂₈).

In addition, when only two of the substituents R₁ to R₁₁ in the compound of Chemical Formula A according to the present disclosure are amine substituents represented by —N(R₂₇) (R₂₈), which may be same or different, they may bond respectively to the aromatic ring moiety A bearing X₁ to X₃ and the aromatic ring moiety B bearing X₄ to X₇, to the aromatic ring moiety B bearing X₄ to X₇ and the aromatic ring moiety C bearing X₈ to X₁₁, or the aromatic ring moiety C bearing X₈ to X₁₁ and the aromatic ring moiety A bearing X₁ to X₃.

In addition, when any one of the R₁ to R₁₁ in Chemical Formula A is —N(R₂₇) (R₂₈), the amine may correspond to a substituent represented by the following Structural Formula A:

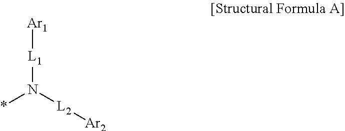

wherein,

L₁ and L₂, which are same or different, are each independently a single bond or a substituted or unsubstituted arylene of 6 to 18 carbon atoms, Ar₁ and Ar₂, which are same or different, are each independently a substituent selected from a substituted or unsubstituted alkyl of 1 to carbon atoms a substituted or unsubstituted aryl of 6 to 18 carbon atoms, a substituted or unsubstituted cycloalkyl of 3 to 15 carbon atoms, and a substituted or unsubstituted heteroaryl of 2 to 18 carbon atoms and may be connected to each other to additionally form an aliphatic or aromatic mono- or polycyclic ring. In a particular embodiment, at least one of Ar₁ and Ar₂ in Structural Formula A may be a substituted or unsubstituted aryl of 6 to 18 carbon atoms.

In more particular embodiments, the amine of [Structural Formula A] may be a substituent represented by [Structural Formula A-1] or [Structural Formula A-2]:

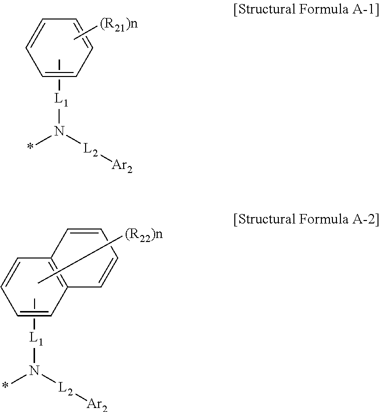

wherein,

L₁, L₂, and Ar₂ are as defined above,

R₂₁ and R₂₂, which may be same or different, are each independently any one selected from a hydrogen atom, a deuterium atom, a substituted or unsubstituted alkyl of 1 to 30 carbon atoms, and a substituted or unsubstituted aryl of 6 to 50 carbon atoms,

n is an integer of 1 to 7 wherein when n is 2 or greater, the corresponding R₂₁'s or R₂₂'s are same or different.

Concrete examples of the boron compound represented by Chemical Formula A according to the present disclosure include <Compound 1> to <Compound 166>:

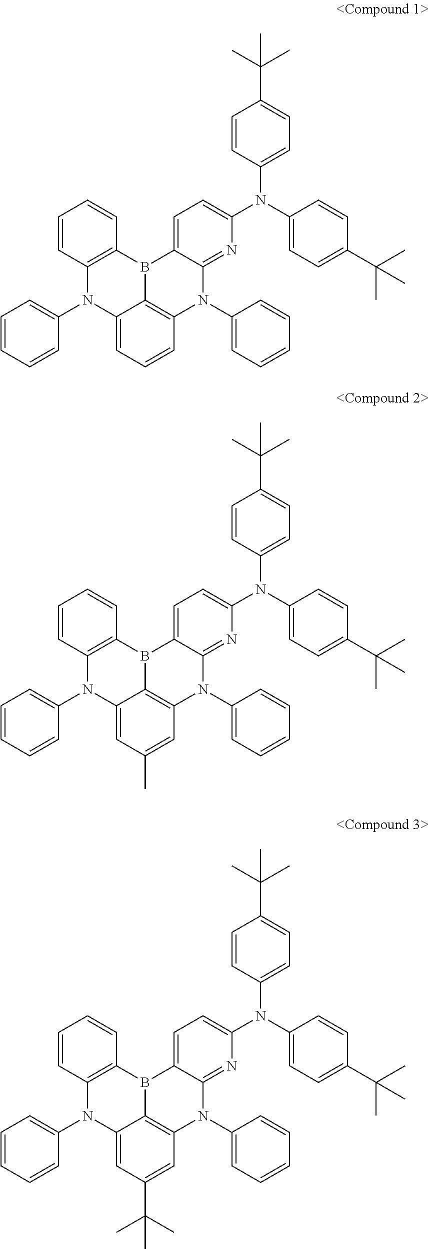 [SMILES: CC(C)(C)c1ccc(N(c2ccc(C(C)(C)C)cc2)c2ccc3c(n2)N(c2ccccc2)c2cccc4c2B3c2ccccc2N4c2ccccc2)cc1 ; Cc1cc2c3c(c1)N(c1ccccc1)c1nc(N(c4ccc(C(C)(C)C)cc4)c4ccc(C(C)(C)C)cc4)ccc1B3c1ccccc1N2c1ccccc1 ; CC(C)(C)c1ccc(N(c2ccc(C(C)(C)C)cc2)c2ccc3c(n2)N(c2ccccc2)c2cc(C(C)(C)C)cc4c2B3c2ccccc2N4c2ccccc2)cc1]

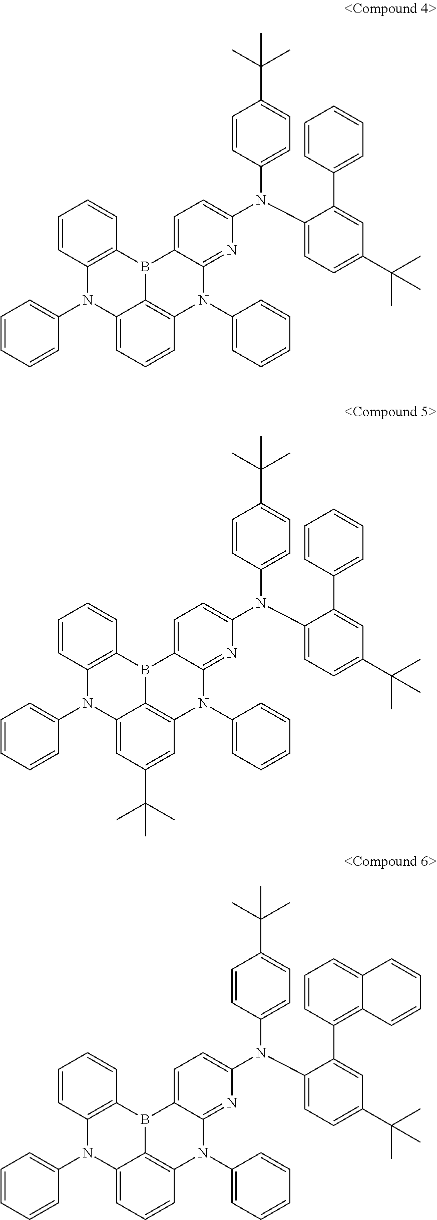 [SMILES: CC(C)(C)c1ccc(N(c2ccc3c(n2)N(c2ccccc2)c2cccc4c2B3c2ccccc2N4c2ccccc2)c2ccc(C(C)(C)C)cc2-c2ccccc2)cc1 ; CC(C)(C)c1ccc(N(c2ccc3c(n2)N(c2ccccc2)c2cc(C(C)(C)C)cc4c2B3c2ccccc2N4c2ccccc2)c2ccc(C(C)(C)C)cc2-c2ccccc2)cc1 ; CC(C)(C)c1ccc(N(c2ccc3c(n2)N(c2ccccc2)c2cccc4c2B3c2ccccc2N4c2ccccc2)c2ccc(C(C)(C)C)cc2-c2cccc3ccccc23)cc1]

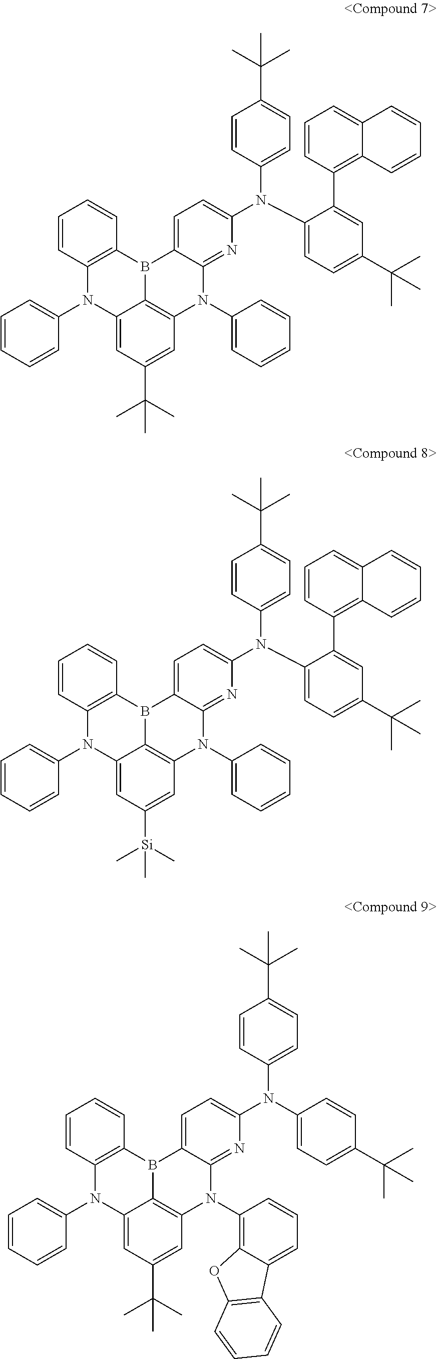 [SMILES: CC(C)(C)c1ccc(N(c2ccc3c(n2)N(c2ccccc2)c2cc(C(C)(C)C)cc4c2B3c2ccccc2N4c2ccccc2)c2ccc(C(C)(C)C)cc2-c2cccc3ccccc23)cc1 ; CC(C)(C)c1ccc(N(c2ccc3c(n2)N(c2ccccc2)c2cc([Si](C)(C)C)cc4c2B3c2ccccc2N4c2ccccc2)c2ccc(C(C)(C)C)cc2-c2cccc3ccccc23)cc1 ; CC(C)(C)c1ccc(N(c2ccc(C(C)(C)C)cc2)c2ccc3c(n2)N(c2cccc4c2oc2ccccc24)c2cc(C(C)(C)C)cc4c2B3c2ccccc2N4c2ccccc2)cc1]

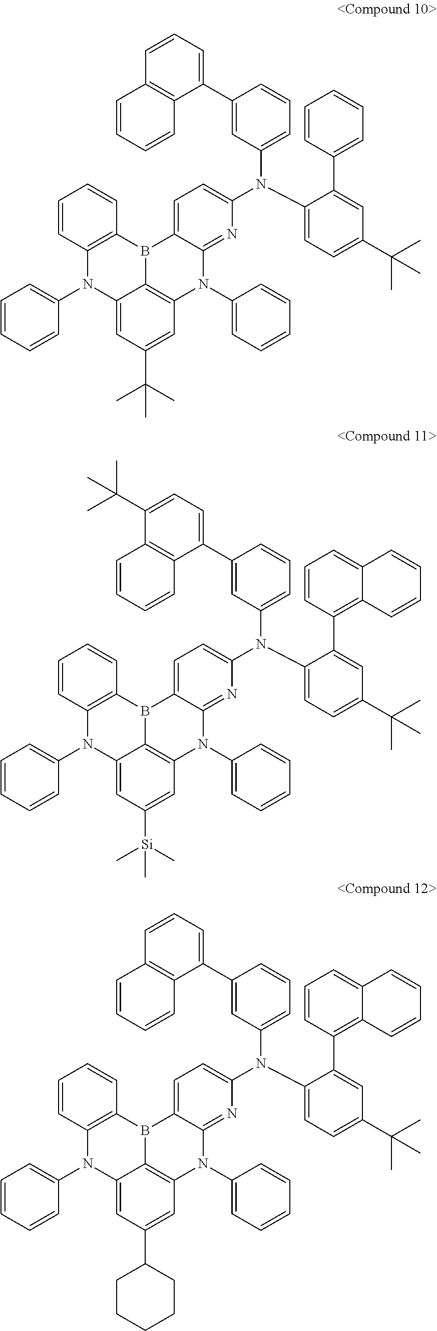

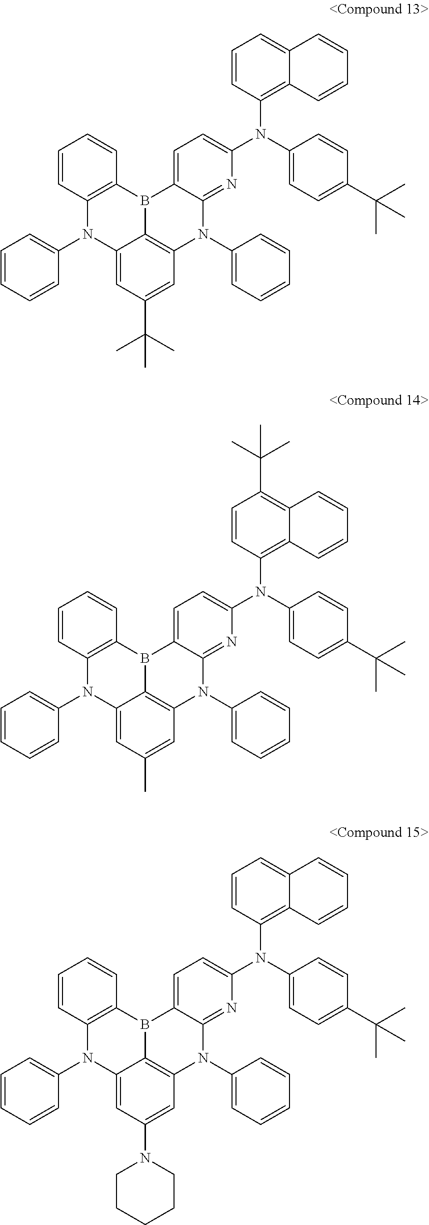 [SMILES: CC(C)(C)c1ccc(N(c2ccc3c(n2)N(c2ccccc2)c2cc(C(C)(C)C)cc4c2B3c2ccccc2N4c2ccccc2)c2cccc3ccccc23)cc1 ; Cc1cc2c3c(c1)N(c1ccccc1)c1nc(N(c4ccc(C(C)(C)C)cc4)c4ccc(C(C)(C)C)c5ccccc45)ccc1B3c1ccccc1N2c1ccccc1 ; CC(C)(C)c1ccc(N(c2ccc3c(n2)N(c2ccccc2)c2cc(N4CCCCC4)cc4c2B3c2ccccc2N4c2ccccc2)c2cccc3ccccc23)cc1]

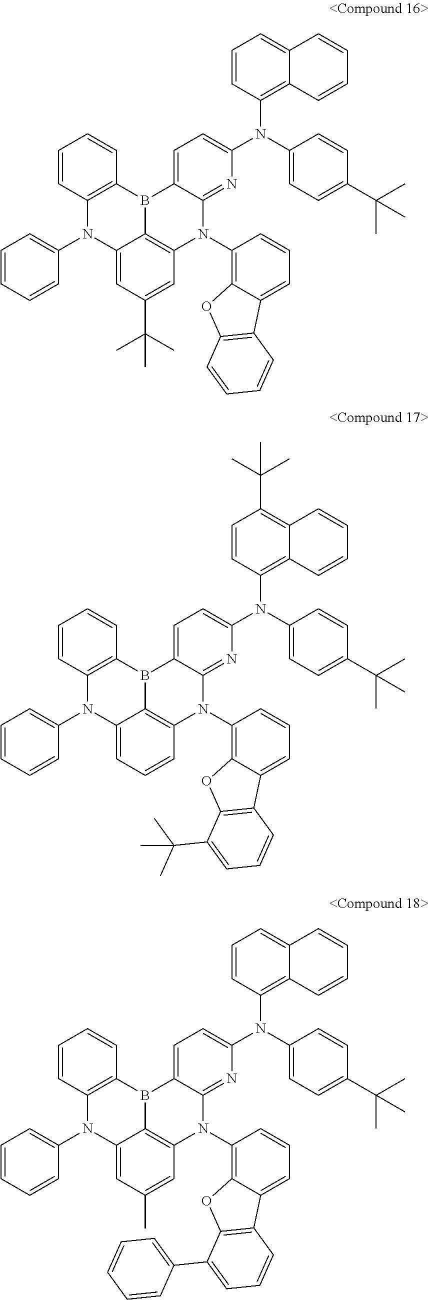 [SMILES: CC(C)(C)c1ccc(N(c2ccc3c(n2)N(c2cccc4c2oc2ccccc24)c2cc(C(C)(C)C)cc4c2B3c2ccccc2N4c2ccccc2)c2cccc3ccccc23)cc1 ; CC(C)(C)c1ccc(N(c2ccc3c(n2)N(c2cccc4c2oc2c(C(C)(C)C)cccc24)c2cccc4c2B3c2ccccc2N4c2ccccc2)c2ccc(C(C)(C)C)c3ccccc23)cc1 ; Cc1cc2c3c(c1)N(c1cccc4c1oc1c(-c5ccccc5)cccc14)c1nc(N(c4ccc(C(C)(C)C)cc4)c4cccc5ccccc45)ccc1B3c1ccccc1N2c1ccccc1]

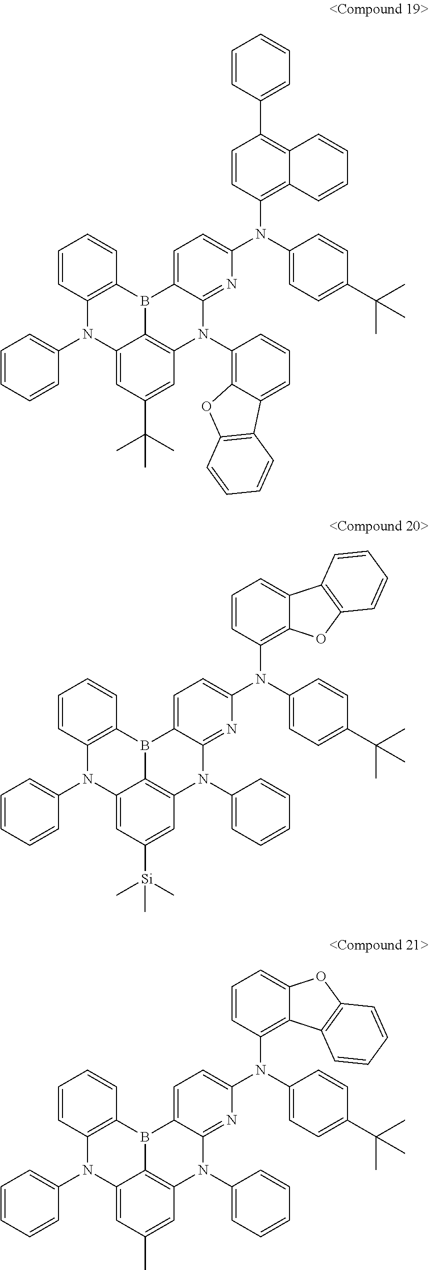 [SMILES: CC(C)(C)c1ccc(N(c2ccc3c(n2)N(c2cccc4c2oc2ccccc24)c2cc(C(C)(C)C)cc4c2B3c2ccccc2N4c2ccccc2)c2ccc(-c3ccccc3)c3ccccc23)cc1 ; CC(C)(C)c1ccc(N(c2ccc3c(n2)N(c2ccccc2)c2cc([Si](C)(C)C)cc4c2B3c2ccccc2N4c2ccccc2)c2cccc3c2oc2ccccc23)cc1 ; Cc1cc2c3c(c1)N(c1ccccc1)c1nc(N(c4ccc(C(C)(C)C)cc4)c4cccc5oc6ccccc6c45)ccc1B3c1ccccc1N2c1ccccc1]

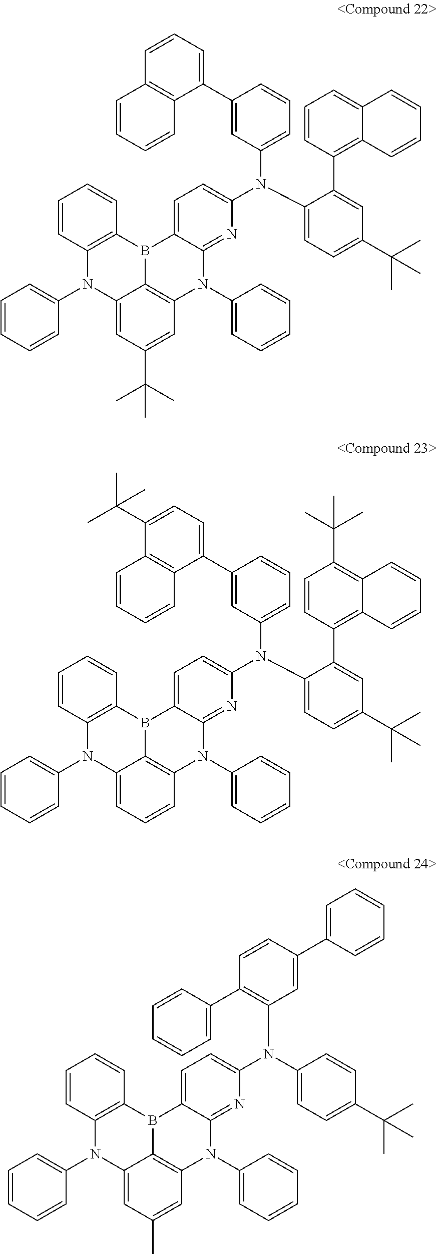 [SMILES: CC(C)(C)c1ccc(N(c2cccc(-c3cccc4ccccc34)c2)c2ccc3c(n2)N(c2ccccc2)c2cc(C(C)(C)C)cc4c2B3c2ccccc2N4c2ccccc2)c(-c2cccc3ccccc23)c1 ; CC(C)(C)c1ccc(N(c2cccc(-c3ccc(C(C)(C)C)c4ccccc34)c2)c2ccc3c(n2)N(c2ccccc2)c2cccc4c2B3c2ccccc2N4c2ccccc2)c(-c2ccc(C(C)(C)C)c3ccccc23)c1 ; Cc1cc2c3c(c1)N(c1ccccc1)c1nc(N(c4ccc(C(C)(C)C)cc4)c4cc(-c5ccccc5)ccc4-c4ccccc4)ccc1B3c1ccccc1N2c1ccccc1]

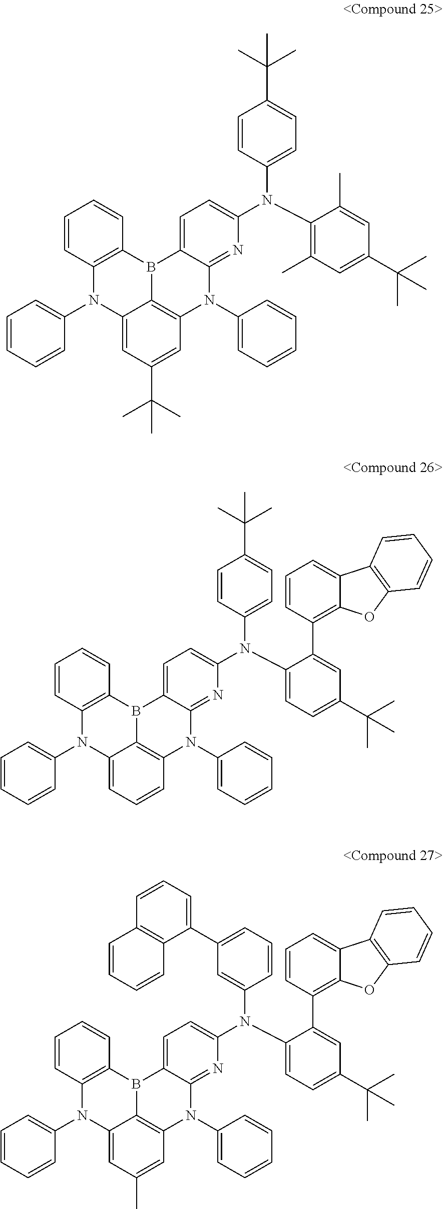 [SMILES: Cc1cc(C(C)(C)C)cc(C)c1N(c1ccc(C(C)(C)C)cc1)c1ccc2c(n1)N(c1ccccc1)c1cc(C(C)(C)C)cc3c1B2c1ccccc1N3c1ccccc1 ; CC(C)(C)c1ccc(N(c2ccc3c(n2)N(c2ccccc2)c2cccc4c2B3c2ccccc2N4c2ccccc2)c2ccc(C(C)(C)C)cc2-c2cccc3c2oc2ccccc23)cc1 ; Cc1cc2c3c(c1)N(c1ccccc1)c1nc(N(c4cccc(-c5cccc6ccccc56)c4)c4ccc(C(C)(C)C)cc4-c4cccc5c4oc4ccccc45)ccc1B3c1ccccc1N2c1ccccc1]

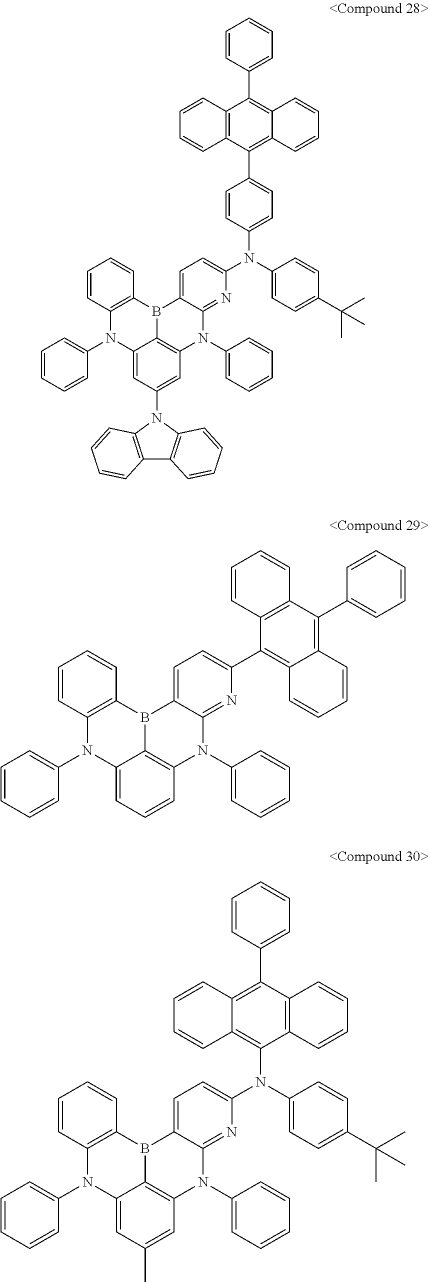 [SMILES: CC(C)(C)c1ccc(N(c2ccc(-c3c4ccccc4c(-c4ccccc4)c4ccccc34)cc2)c2ccc3c(n2)N(c2ccccc2)c2cc(-n4c5ccccc5c5ccccc54)cc4c2B3c2ccccc2N4c2ccccc2)cc1 ; c1ccc(-c2c3ccccc3c(-c3ccc4c(n3)N(c3ccccc3)c3cccc5c3B4c3ccccc3N5c3ccccc3)c3ccccc23)cc1 ; Cc1cc2c3c(c1)N(c1ccccc1)c1nc(N(c4ccc(C(C)(C)C)cc4)c4c5ccccc5c(-c5ccccc5)c5ccccc45)ccc1B3c1ccccc1N2c1ccccc1]

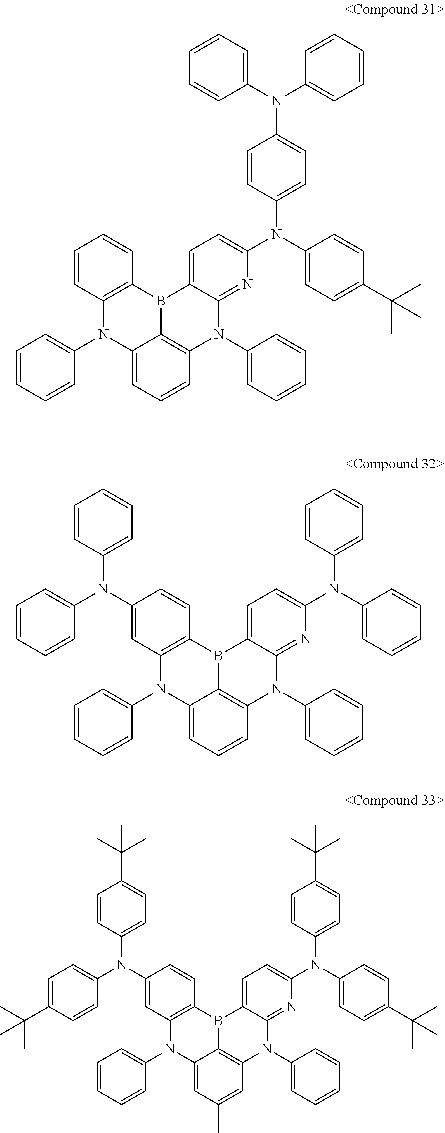

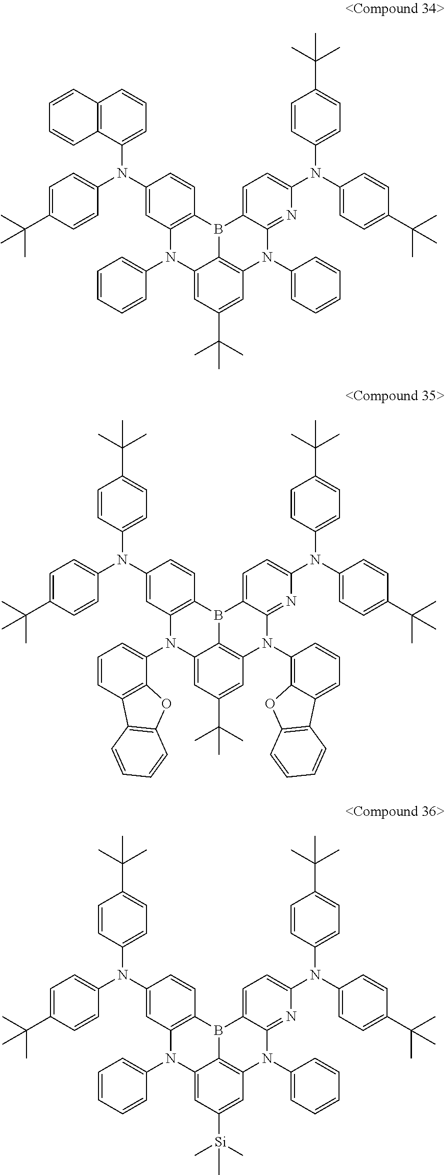

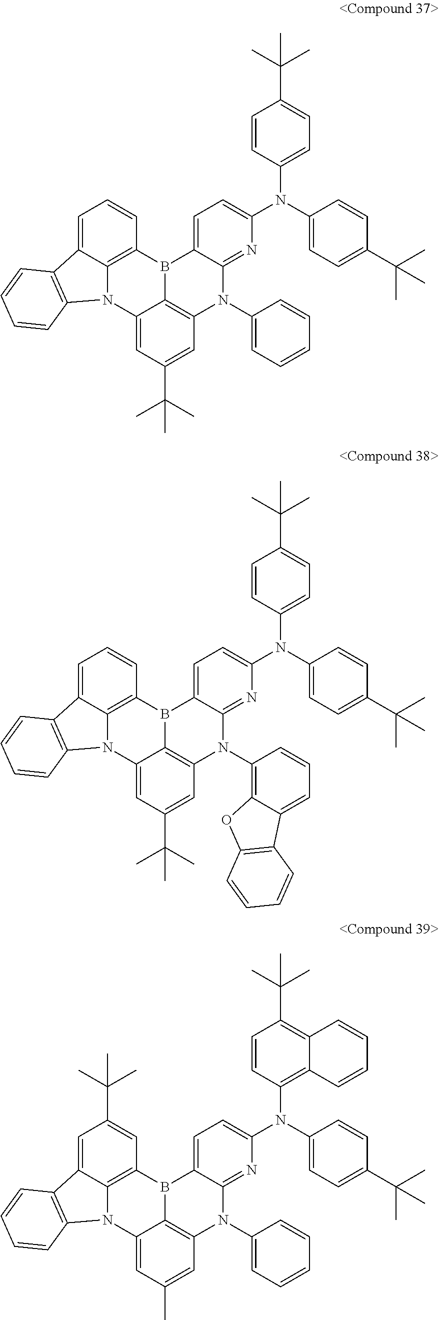 [SMILES: CC(C)(C)c1ccc(N(c2ccc(C(C)(C)C)cc2)c2ccc3c(n2)N(c2ccccc2)c2cc(C(C)(C)C)cc4c2B3c2cccc3c5ccccc5n-4c23)cc1 ; CC(C)(C)c1ccc(N(c2ccc(C(C)(C)C)cc2)c2ccc3c(n2)N(c2cccc4c2oc2ccccc24)c2cc(C(C)(C)C)cc4c2B3c2cccc3c5ccccc5n-4c23)cc1 ; Cc1cc2c3c(c1)-n1c4ccccc4c4cc(C(C)(C)C)cc(c41)B3c1ccc(N(c3ccc(C(C)(C)C)cc3)c3ccc(C(C)(C)C)c4ccccc34)nc1N2c1ccccc1]

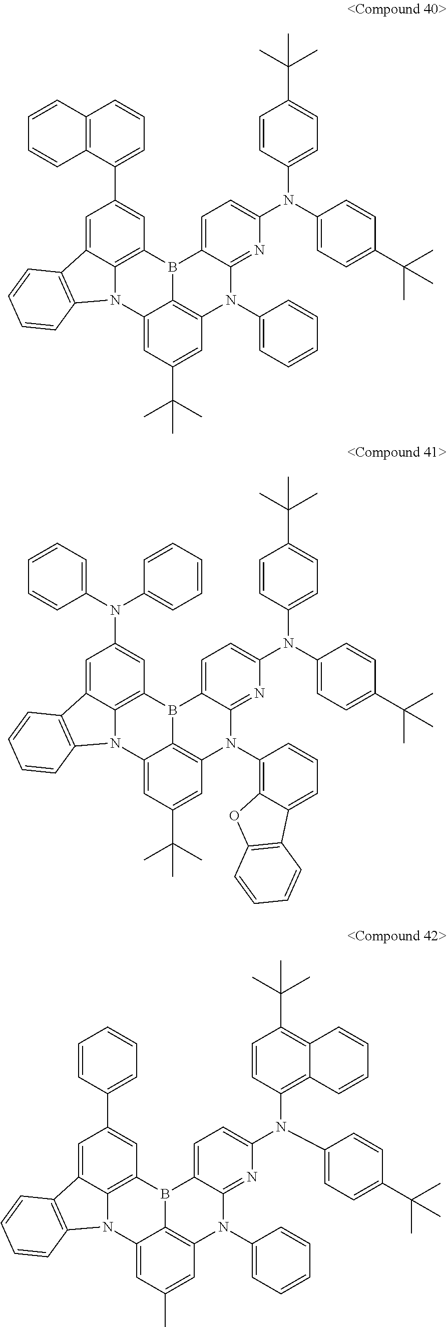 [SMILES: CC(C)(C)c1ccc(N(c2ccc(C(C)(C)C)cc2)c2ccc3c(n2)N(c2ccccc2)c2cc(C(C)(C)C)cc4c2B3c2cc(-c3cccc5ccccc35)cc3c5ccccc5n-4c23)cc1 ; CC(C)(C)c1ccc(N(c2ccc(C(C)(C)C)cc2)c2ccc3c(n2)N(c2cccc4c2oc2ccccc24)c2cc(C(C)(C)C)cc4c2B3c2cc(N(c3ccccc3)c3ccccc3)cc3c5ccccc5n-4c23)cc1 ; Cc1cc2c3c(c1)-n1c4ccccc4c4cc(-c5ccccc5)cc(c41)B3c1ccc(N(c3ccc(C(C)(C)C)cc3)c3ccc(C(C)(C)C)c4ccccc34)nc1N2c1ccccc1]

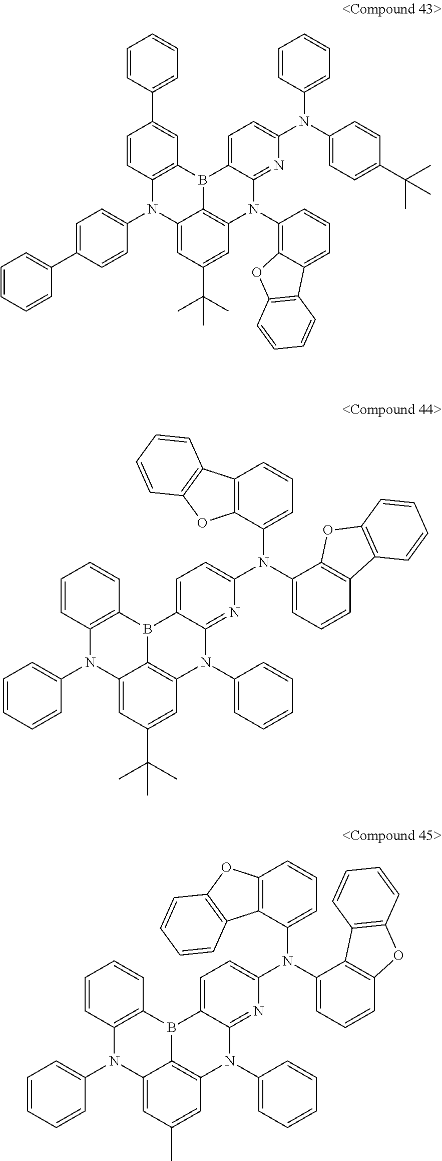 [SMILES: CC(C)(C)c1ccc(N(c2ccccc2)c2ccc3c(n2)N(c2cccc4c2oc2ccccc24)c2cc(C(C)(C)C)cc4c2B3c2cc(-c3ccccc3)ccc2N4c2ccc(-c3ccccc3)cc2)cc1 ; CC(C)(C)c1cc2c3c(c1)N(c1ccccc1)c1nc(N(c4cccc5c4oc4ccccc45)c4cccc5c4oc4ccccc45)ccc1B3c1ccccc1N2c1ccccc1 ; Cc1cc2c3c(c1)N(c1ccccc1)c1nc(N(c4cccc5oc6ccccc6c45)c4cccc5oc6ccccc6c45)ccc1B3c1ccccc1N2c1ccccc1]

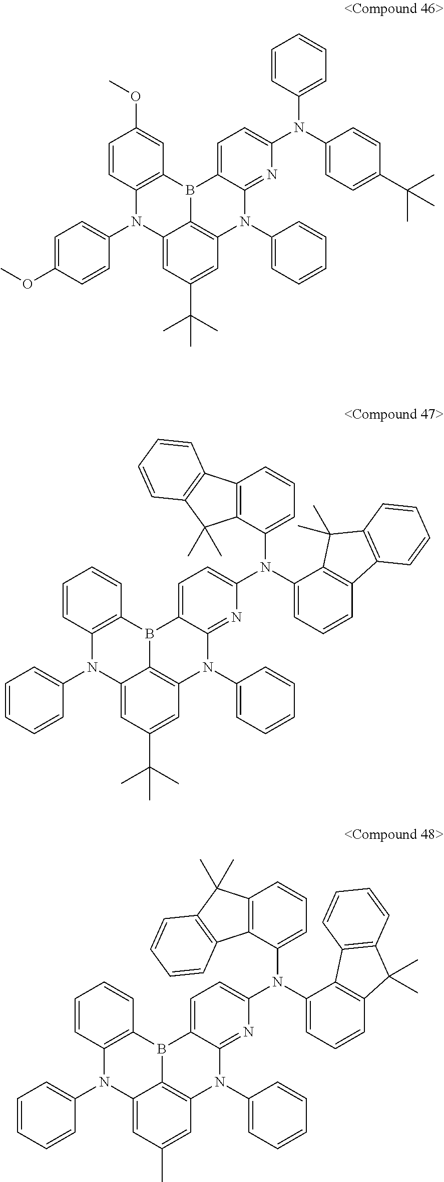 [SMILES: COc1ccc(N2c3ccc(OC)cc3B3c4ccc(N(c5ccccc5)c5ccc(C(C)(C)C)cc5)nc4N(c4ccccc4)c4cc(C(C)(C)C)cc2c43)cc1 ; CC(C)(C)c1cc2c3c(c1)N(c1ccccc1)c1nc(N(c4cccc5c4C(C)(C)c4ccccc4-5)c4cccc5c4C(C)(C)c4ccccc4-5)ccc1B3c1ccccc1N2c1ccccc1 ; Cc1cc2c3c(c1)N(c1ccccc1)c1nc(N(c4cccc5c4-c4ccccc4C5(C)C)c4cccc5c4-c4ccccc4C5(C)C)ccc1B3c1ccccc1N2c1ccccc1]

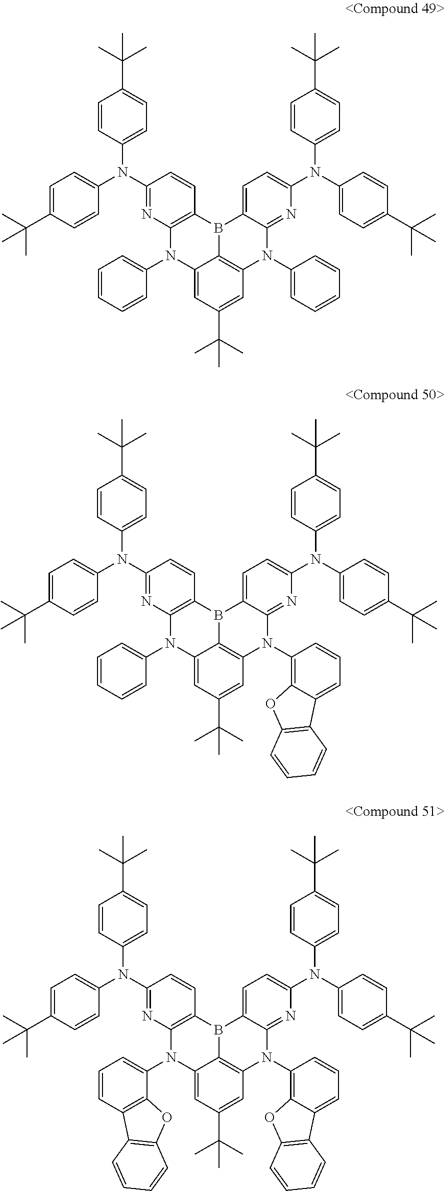

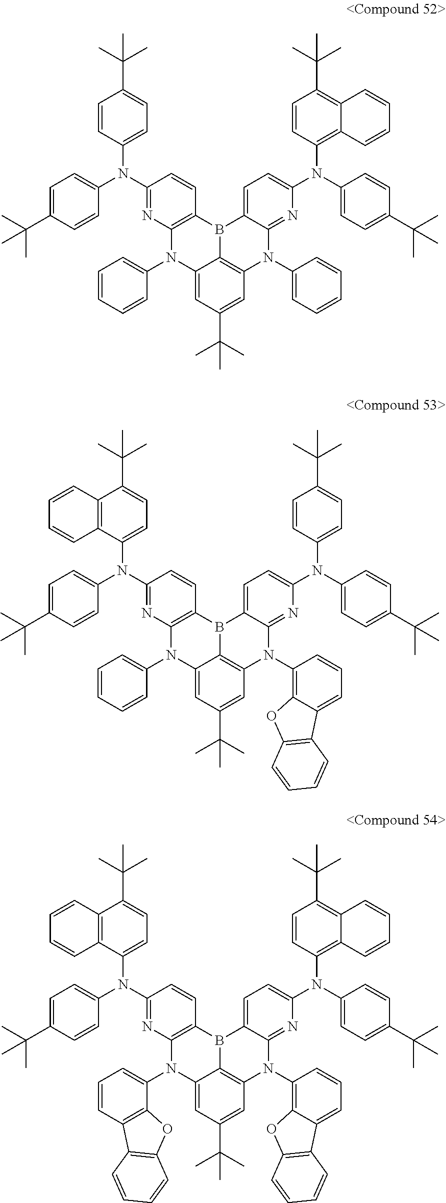

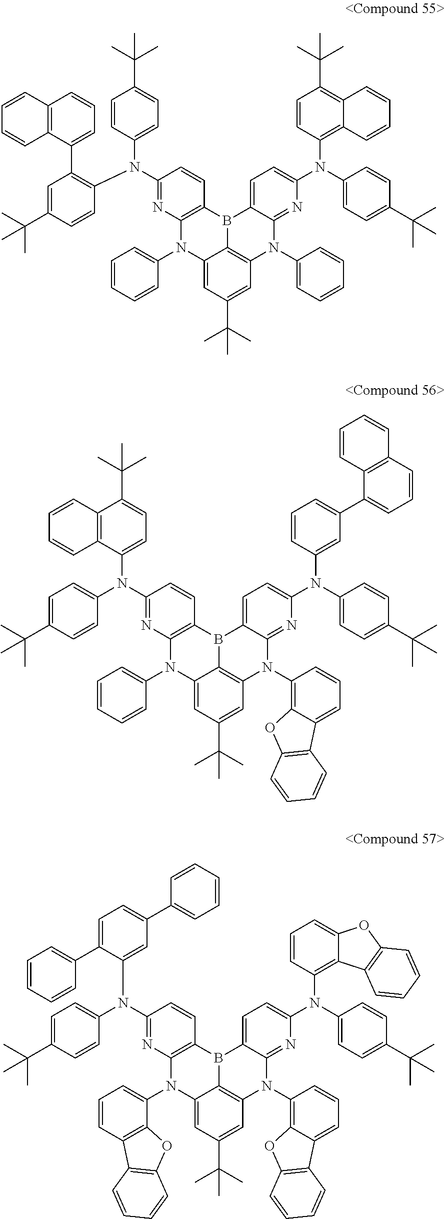

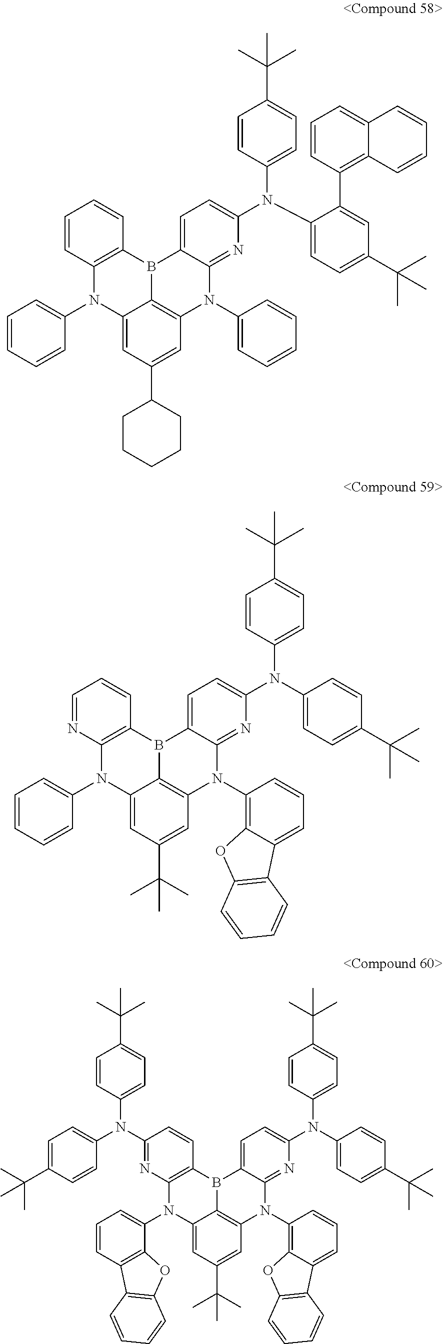

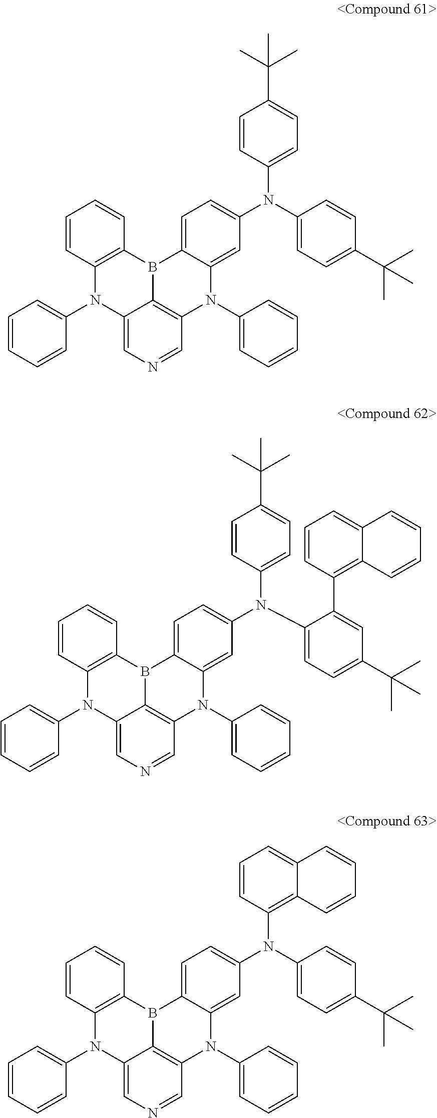 [SMILES: CC(C)(C)c1ccc(N(c2ccc(C(C)(C)C)cc2)c2ccc3c(c2)N(c2ccccc2)c2cncc4c2B3c2ccccc2N4c2ccccc2)cc1 ; CC(C)(C)c1ccc(N(c2ccc3c(c2)N(c2ccccc2)c2cncc4c2B3c2ccccc2N4c2ccccc2)c2ccc(C(C)(C)C)cc2-c2cccc3ccccc23)cc1 ; CC(C)(C)c1ccc(N(c2ccc3c(c2)N(c2ccccc2)c2cncc4c2B3c2ccccc2N4c2ccccc2)c2cccc3ccccc23)cc1]

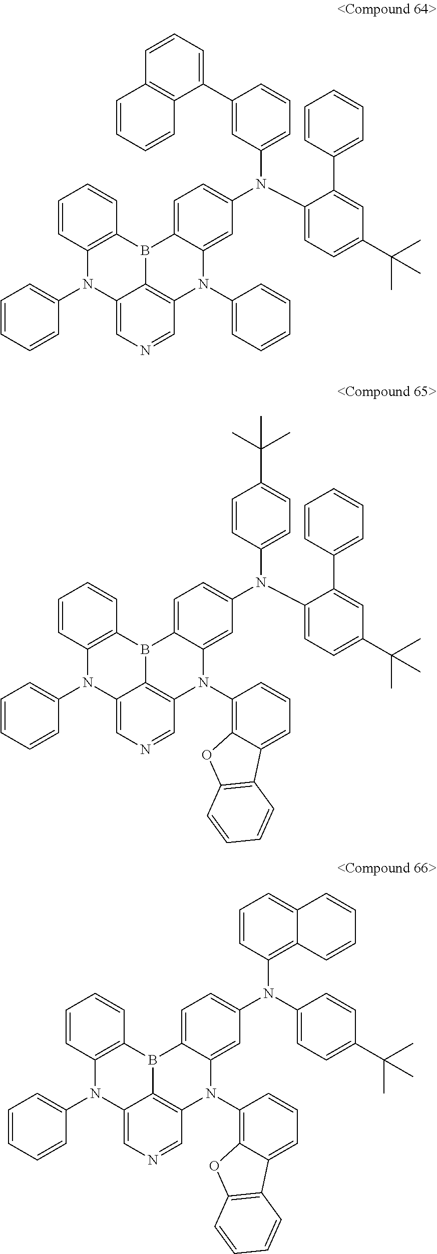 [SMILES: CC(C)(C)c1ccc(N(c2cccc(-c3cccc4ccccc34)c2)c2ccc3c(c2)N(c2ccccc2)c2cncc4c2B3c2ccccc2N4c2ccccc2)c(-c2ccccc2)c1 ; CC(C)(C)c1ccc(N(c2ccc3c(c2)N(c2cccc4c2oc2ccccc24)c2cncc4c2B3c2ccccc2N4c2ccccc2)c2ccc(C(C)(C)C)cc2-c2ccccc2)cc1 ; CC(C)(C)c1ccc(N(c2ccc3c(c2)N(c2cccc4c2oc2ccccc24)c2cncc4c2B3c2ccccc2N4c2ccccc2)c2cccc3ccccc23)cc1]

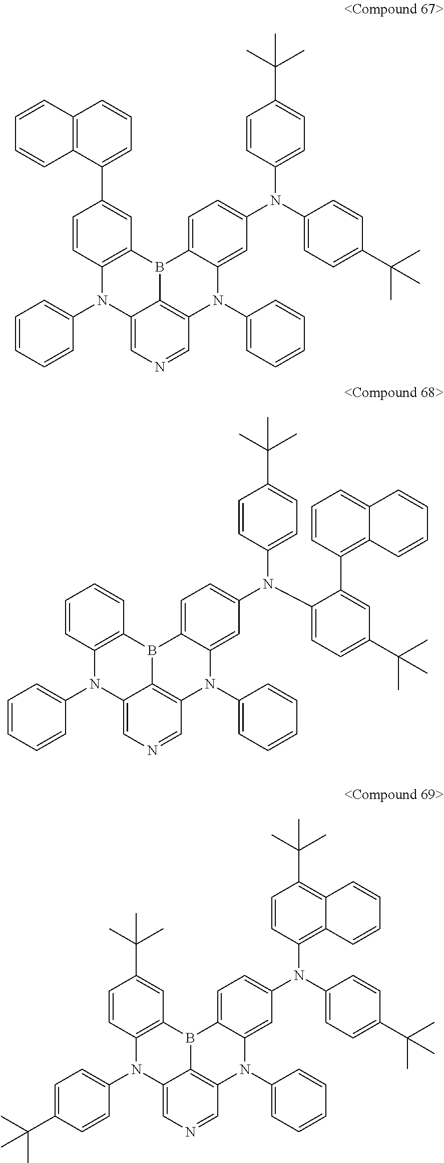

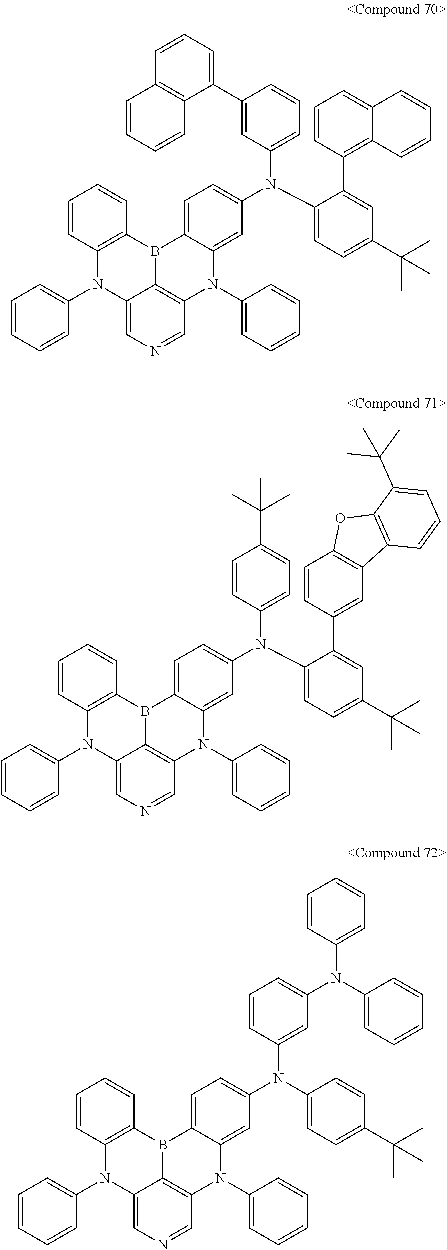 [SMILES: CC(C)(C)c1ccc(N(c2cccc(-c3cccc4ccccc34)c2)c2ccc3c(c2)N(c2ccccc2)c2cncc4c2B3c2ccccc2N4c2ccccc2)c(-c2cccc3ccccc23)c1 ; CC(C)(C)c1ccc(N(c2ccc3c(c2)N(c2ccccc2)c2cncc4c2B3c2ccccc2N4c2ccccc2)c2ccc(C(C)(C)C)cc2-c2ccc3oc4c(C(C)(C)C)cccc4c3c2)cc1 ; CC(C)(C)c1ccc(N(c2cccc(N(c3ccccc3)c3ccccc3)c2)c2ccc3c(c2)N(c2ccccc2)c2cncc4c2B3c2ccccc2N4c2ccccc2)cc1]

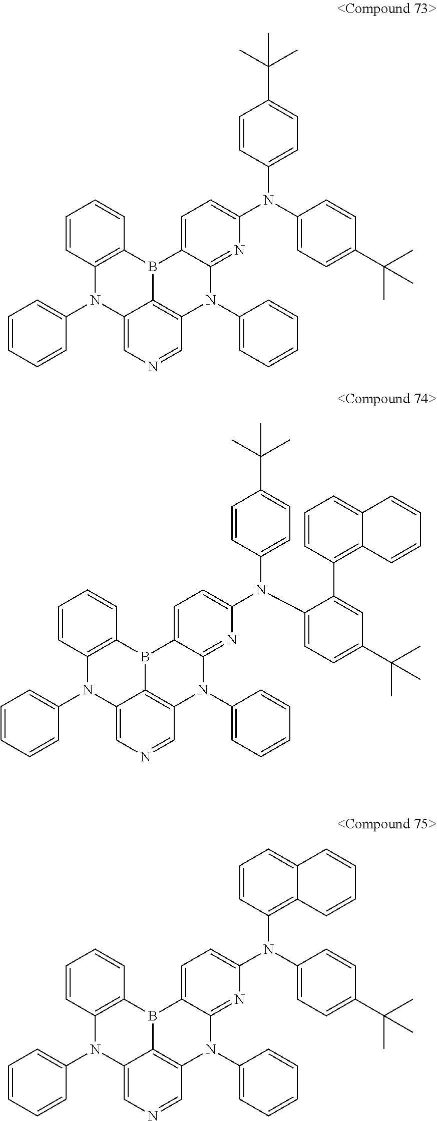 [SMILES: CC(C)(C)c1ccc(N(c2ccc(C(C)(C)C)cc2)c2ccc3c(n2)N(c2ccccc2)c2cncc4c2B3c2ccccc2N4c2ccccc2)cc1 ; CC(C)(C)c1ccc(N(c2ccc3c(n2)N(c2ccccc2)c2cncc4c2B3c2ccccc2N4c2ccccc2)c2ccc(C(C)(C)C)cc2-c2cccc3ccccc23)cc1 ; CC(C)(C)c1ccc(N(c2ccc3c(n2)N(c2ccccc2)c2cncc4c2B3c2ccccc2N4c2ccccc2)c2cccc3ccccc23)cc1]

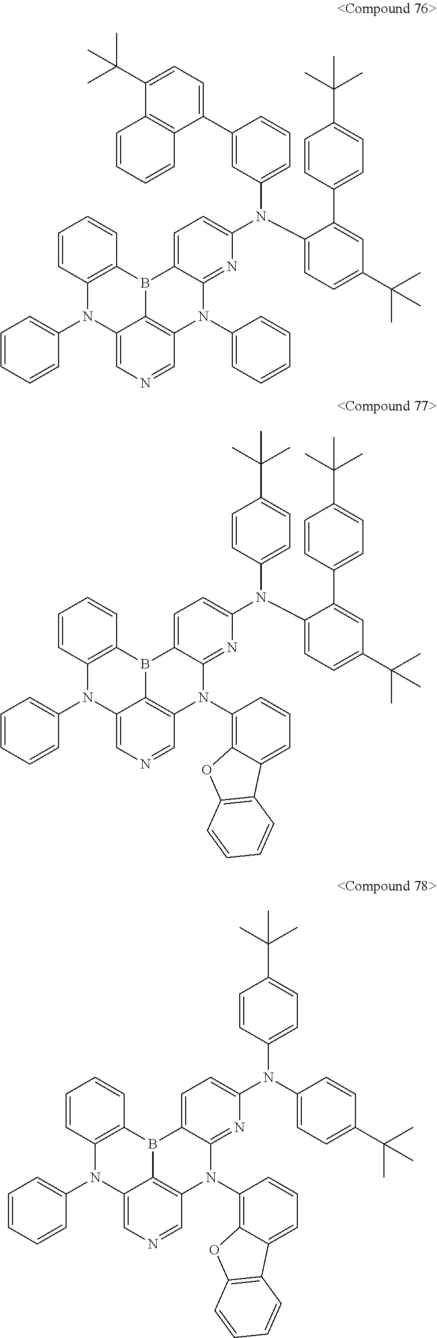 [SMILES: CC(C)(C)c1ccc(-c2cc(C(C)(C)C)ccc2N(c2cccc(-c3ccc(C(C)(C)C)c4ccccc34)c2)c2ccc3c(n2)N(c2ccccc2)c2cncc4c2B3c2ccccc2N4c2ccccc2)cc1 ; CC(C)(C)c1ccc(-c2cc(C(C)(C)C)ccc2N(c2ccc(C(C)(C)C)cc2)c2ccc3c(n2)N(c2cccc4c2oc2ccccc24)c2cncc4c2B3c2ccccc2N4c2ccccc2)cc1 ; CC(C)(C)c1ccc(N(c2ccc(C(C)(C)C)cc2)c2ccc3c(n2)N(c2cccc4c2oc2ccccc24)c2cncc4c2B3c2ccccc2N4c2ccccc2)cc1]

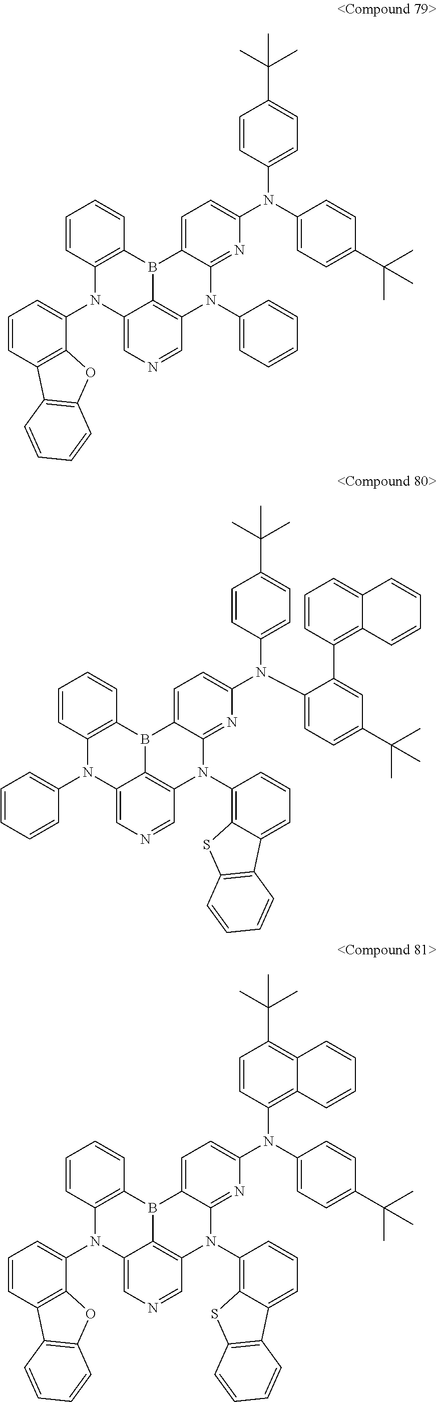

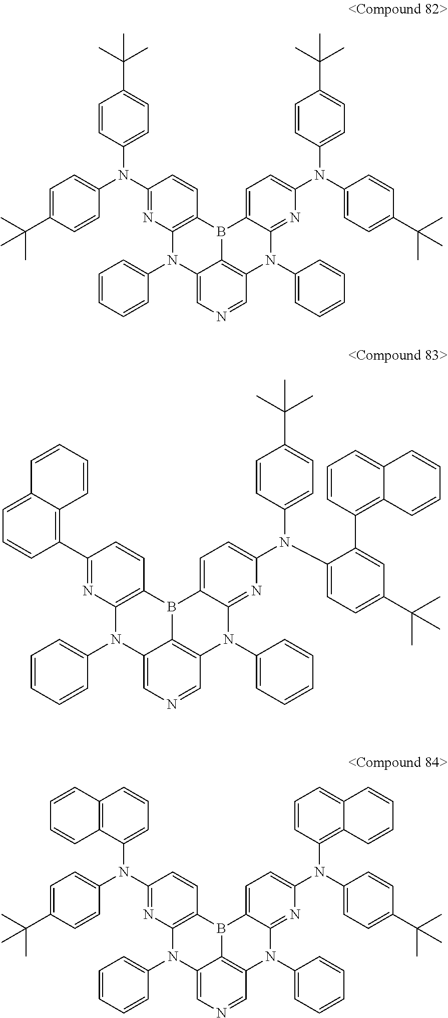

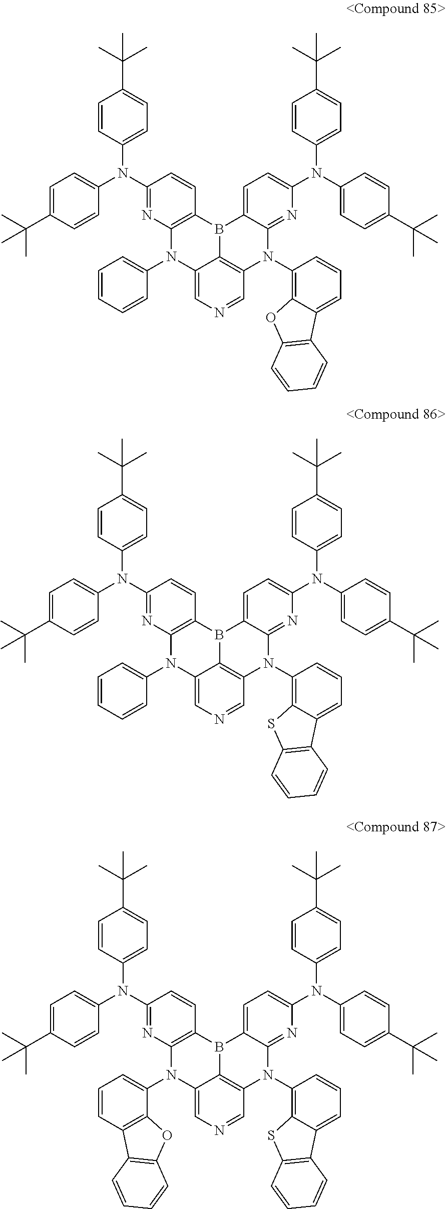

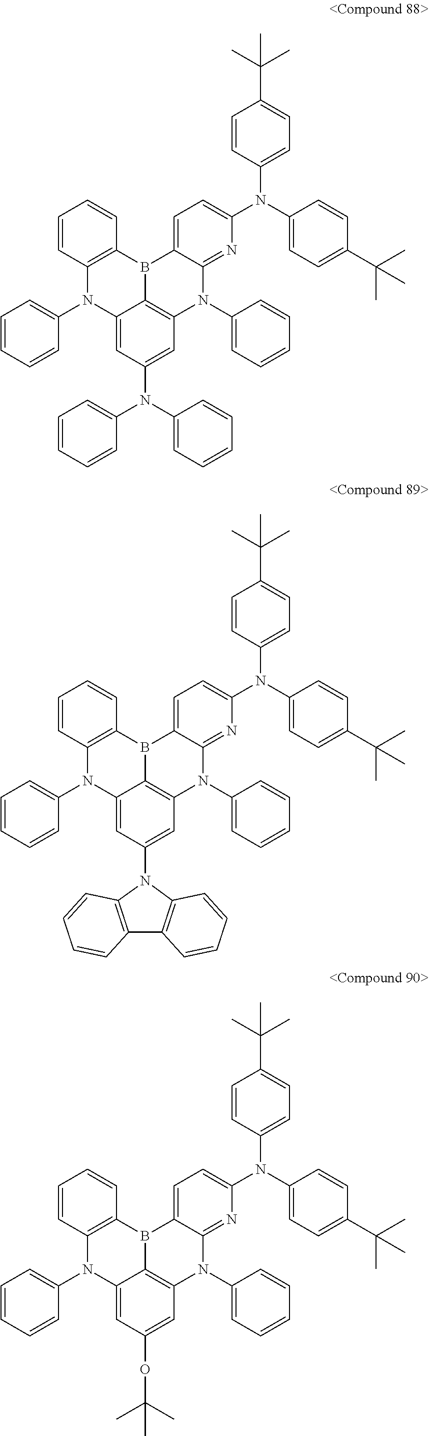 [SMILES: CC(C)(C)c1ccc(N(c2ccc(C(C)(C)C)cc2)c2ccc3c(n2)N(c2ccccc2)c2cc(N(c4ccccc4)c4ccccc4)cc4c2B3c2ccccc2N4c2ccccc2)cc1 ; CC(C)(C)c1ccc(N(c2ccc(C(C)(C)C)cc2)c2ccc3c(n2)N(c2ccccc2)c2cc(-n4c5ccccc5c5ccccc54)cc4c2B3c2ccccc2N4c2ccccc2)cc1 ; CC(C)(C)Oc1cc2c3c(c1)N(c1ccccc1)c1nc(N(c4ccc(C(C)(C)C)cc4)c4ccc(C(C)(C)C)cc4)ccc1B3c1ccccc1N2c1ccccc1]

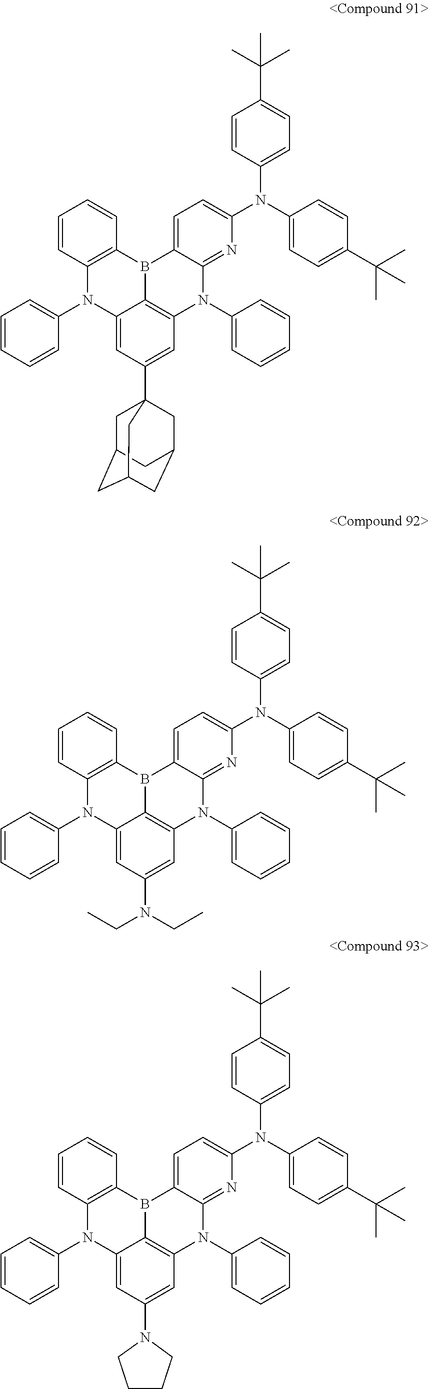 [SMILES: CC(C)(C)c1ccc(N(c2ccc(C(C)(C)C)cc2)c2ccc3c(n2)N(c2ccccc2)c2cc(C45CC6CC(CC(C6)C4)C5)cc4c2B3c2ccccc2N4c2ccccc2)cc1 ; CCN(CC)c1cc2c3c(c1)N(c1ccccc1)c1nc(N(c4ccc(C(C)(C)C)cc4)c4ccc(C(C)(C)C)cc4)ccc1B3c1ccccc1N2c1ccccc1 ; CC(C)(C)c1ccc(N(c2ccc(C(C)(C)C)cc2)c2ccc3c(n2)N(c2ccccc2)c2cc(N4CCCC4)cc4c2B3c2ccccc2N4c2ccccc2)cc1]

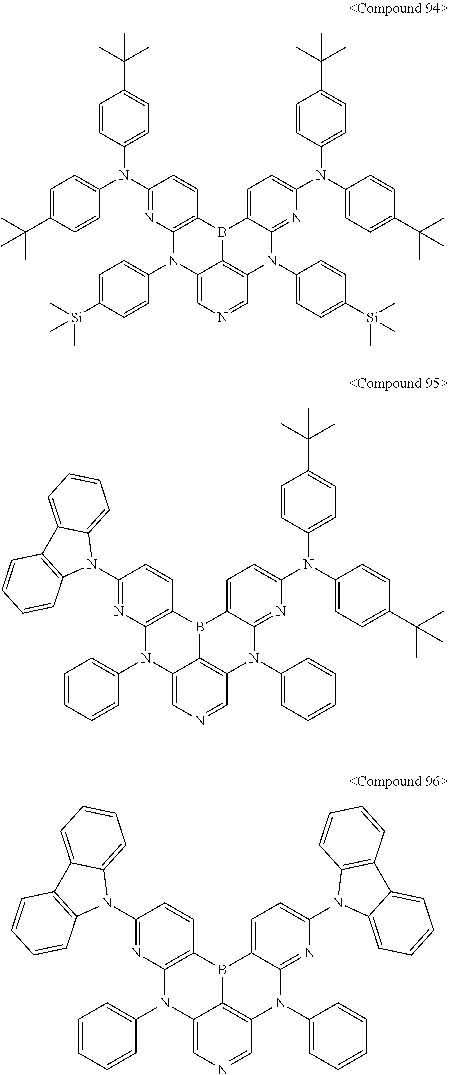 [SMILES: CC(C)(C)c1ccc(N(c2ccc(C(C)(C)C)cc2)c2ccc3c(n2)N(c2ccc([Si](C)(C)C)cc2)c2cncc4c2B3c2ccc(N(c3ccc(C(C)(C)C)cc3)c3ccc(C(C)(C)C)cc3)nc2N4c2ccc([Si](C)(C)C)cc2)cc1 ; CC(C)(C)c1ccc(N(c2ccc(C(C)(C)C)cc2)c2ccc3c(n2)N(c2ccccc2)c2cncc4c2B3c2ccc(-n3c5ccccc5c5ccccc53)nc2N4c2ccccc2)cc1 ; c1ccc(N2c3cncc4c3B(c3ccc(-n5c6ccccc6c6ccccc65)nc32)c2ccc(-n3c5ccccc5c5ccccc53)nc2N4c2ccccc2)cc1]

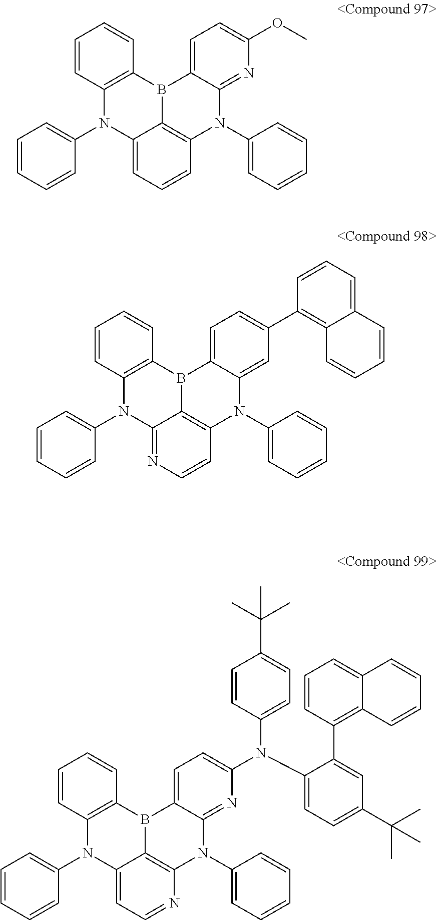 [SMILES: COc1ccc2c(n1)N(c1ccccc1)c1cccc3c1B2c1ccccc1N3c1ccccc1 ; c1ccc(N2c3cc(-c4cccc5ccccc45)ccc3B3c4ccccc4N(c4ccccc4)c4nccc2c43)cc1 ; CC(C)(C)c1ccc(N(c2ccc3c(n2)N(c2ccccc2)c2nccc4c2B3c2ccccc2N4c2ccccc2)c2ccc(C(C)(C)C)cc2-c2cccc3ccccc23)cc1]

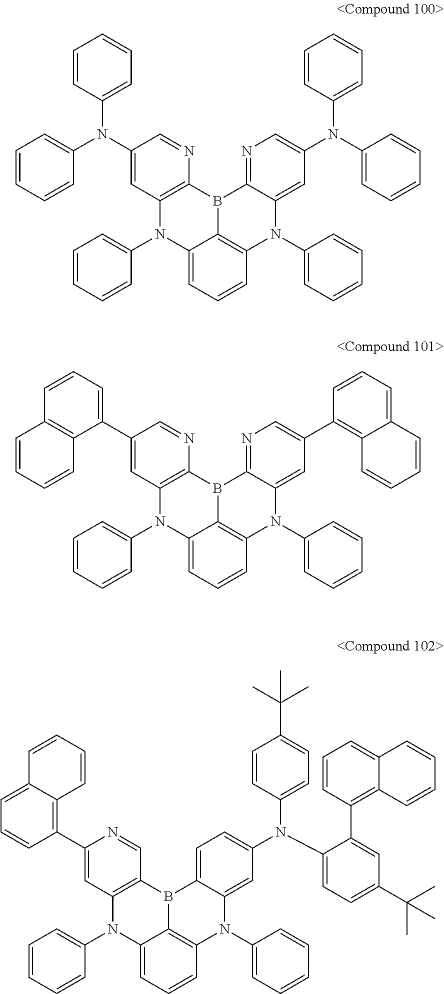 [SMILES: c1ccc(N(c2ccccc2)c2cnc3c(c2)N(c2ccccc2)c2cccc4c2B3c2ncc(N(c3ccccc3)c3ccccc3)cc2N4c2ccccc2)cc1 ; c1ccc(N2c3cc(-c4cccc5ccccc45)cnc3B3c4ncc(-c5cccc6ccccc56)cc4N(c4ccccc4)c4cccc2c43)cc1 ; CC(C)(C)c1ccc(N(c2ccc3c(c2)N(c2ccccc2)c2cccc4c2B3c2cnc(-c3cccc5ccccc35)cc2N4c2ccccc2)c2ccc(C(C)(C)C)cc2-c2cccc3ccccc23)cc1]

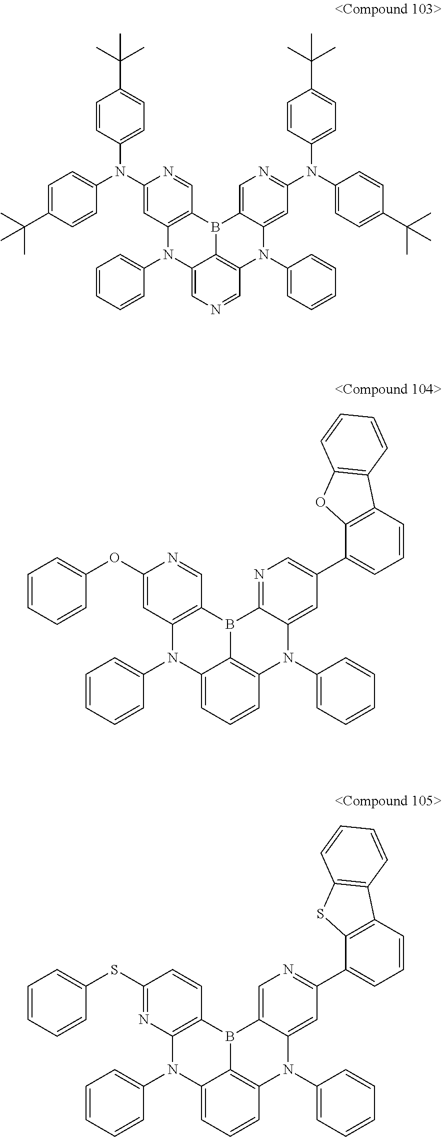 [SMILES: CC(C)(C)c1ccc(N(c2ccc(C(C)(C)C)cc2)c2cc3c(cn2)B2c4cnc(N(c5ccc(C(C)(C)C)cc5)c5ccc(C(C)(C)C)cc5)cc4N(c4ccccc4)c4cncc(c42)N3c2ccccc2)cc1 ; c1ccc(Oc2cc3c(cn2)B2c4ncc(-c5cccc6c5oc5ccccc56)cc4N(c4ccccc4)c4cccc(c42)N3c2ccccc2)cc1 ; c1ccc(Sc2ccc3c(n2)N(c2ccccc2)c2cccc4c2B3c2cnc(-c3cccc5c3sc3ccccc35)cc2N4c2ccccc2)cc1]

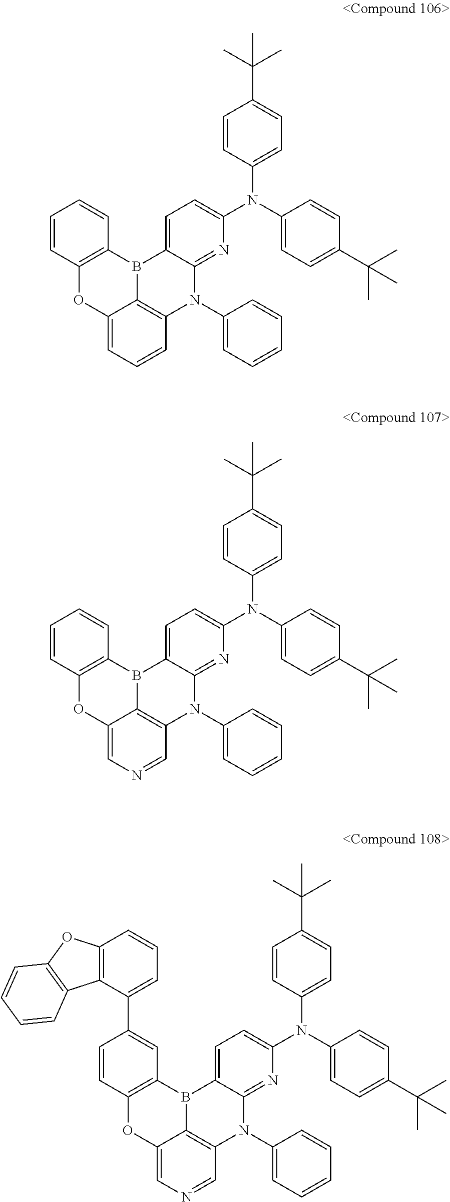 [SMILES: CC(C)(C)c1ccc(N(c2ccc(C(C)(C)C)cc2)c2ccc3c(n2)N(c2ccccc2)c2cccc4c2B3c2ccccc2O4)cc1 ; CC(C)(C)c1ccc(N(c2ccc(C(C)(C)C)cc2)c2ccc3c(n2)N(c2ccccc2)c2cncc4c2B3c2ccccc2O4)cc1 ; CC(C)(C)c1ccc(N(c2ccc(C(C)(C)C)cc2)c2ccc3c(n2)N(c2ccccc2)c2cncc4c2B3c2cc(-c3cccc5oc6ccccc6c35)ccc2O4)cc1]

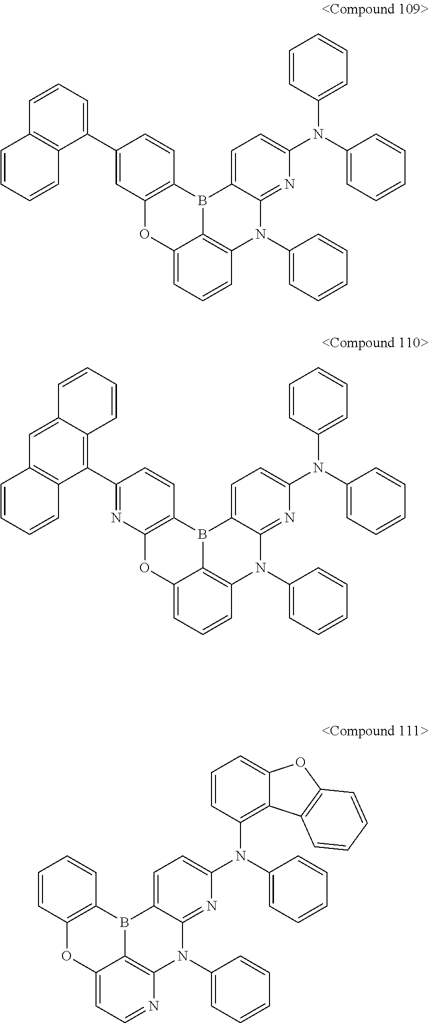 [SMILES: c1ccc(N(c2ccccc2)c2ccc3c(n2)N(c2ccccc2)c2cccc4c2B3c2ccc(-c3cccc5ccccc35)cc2O4)cc1 ; c1ccc(N(c2ccccc2)c2ccc3c(n2)N(c2ccccc2)c2cccc4c2B3c2ccc(-c3c5ccccc5cc5ccccc35)nc2O4)cc1 ; c1ccc(N2c3nc(N(c4ccccc4)c4cccc5oc6ccccc6c45)ccc3B3c4ccccc4Oc4ccnc2c43)cc1]

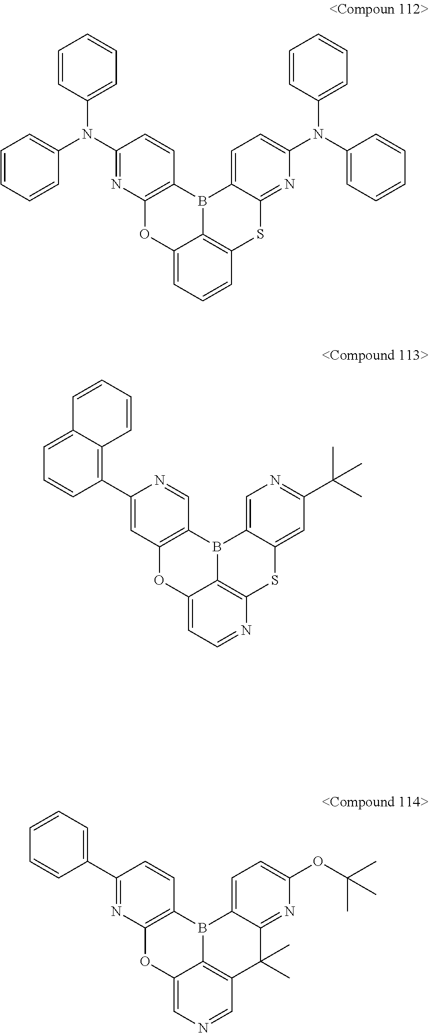 [SMILES: c1ccc(N(c2ccccc2)c2ccc3c(n2)Oc2cccc4c2B3c2ccc(N(c3ccccc3)c3ccccc3)nc2S4)cc1 ; CC(C)(C)c1cc2c(cn1)B1c3cnc(-c4cccc5ccccc45)cc3Oc3ccnc(c31)S2 ; CC(C)(C)Oc1ccc2c(n1)C(C)(C)c1cncc3c1B2c1ccc(-c2ccccc2)nc1O3]

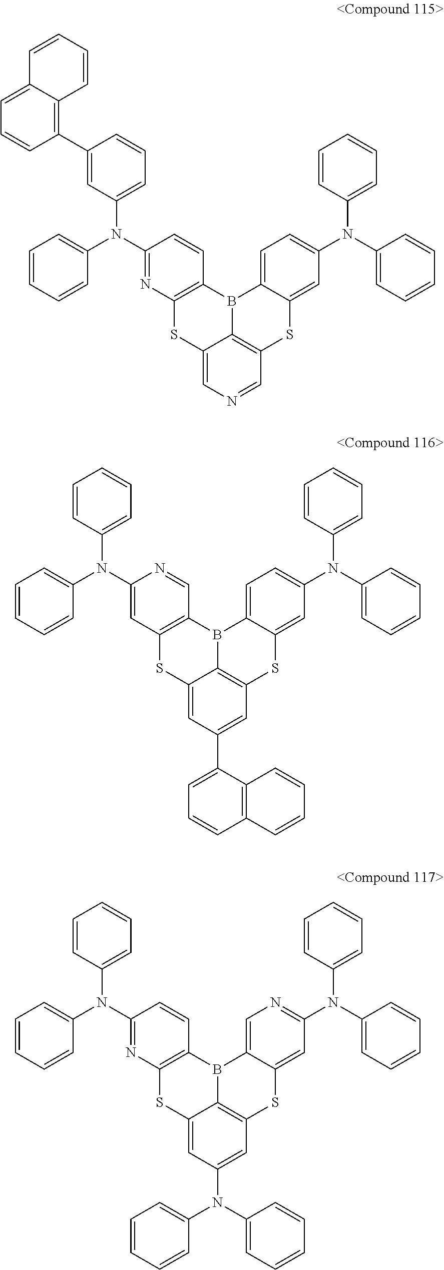 [SMILES: c1ccc(N(c2ccccc2)c2ccc3c(c2)Sc2cncc4c2B3c2ccc(N(c3ccccc3)c3cccc(-c5cccc6ccccc56)c3)nc2S4)cc1 ; c1ccc(N(c2ccccc2)c2ccc3c(c2)Sc2cc(-c4cccc5ccccc45)cc4c2B3c2cnc(N(c3ccccc3)c3ccccc3)cc2S4)cc1 ; c1ccc(N(c2ccccc2)c2cc3c4c(c2)Sc2nc(N(c5ccccc5)c5ccccc5)ccc2B4c2cnc(N(c4ccccc4)c4ccccc4)cc2S3)cc1]

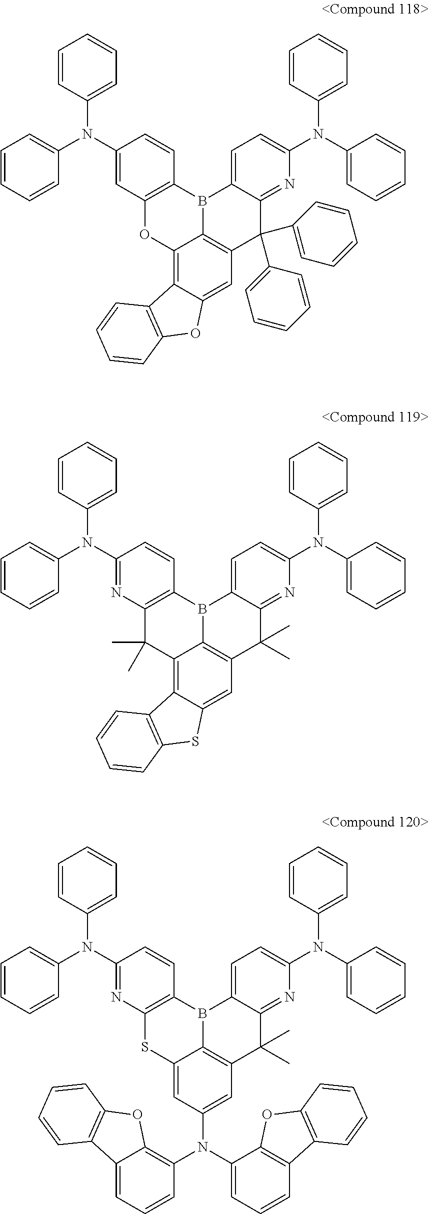 [SMILES: c1ccc(N(c2ccccc2)c2ccc3c(c2)Oc2c4c(cc5oc6ccccc6c25)C(c2ccccc2)(c2ccccc2)c2nc(N(c5ccccc5)c5ccccc5)ccc2B34)cc1 ; CC1(C)c2cc3sc4ccccc4c3c3c2B(c2ccc(N(c4ccccc4)c4ccccc4)nc21)c1ccc(N(c2ccccc2)c2ccccc2)nc1C3(C)C ; CC1(C)c2cc(N(c3cccc4c3oc3ccccc34)c3cccc4c3oc3ccccc34)cc3c2B(c2ccc(N(c4ccccc4)c4ccccc4)nc2S3)c2ccc(N(c3ccccc3)c3ccccc3)nc21]

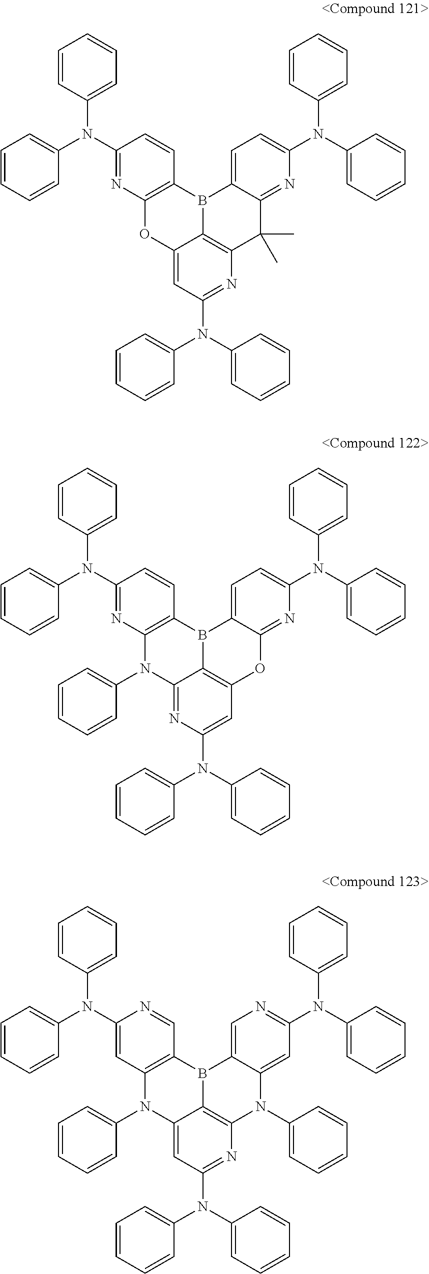 [SMILES: CC1(C)c2nc(N(c3ccccc3)c3ccccc3)ccc2B2c3ccc(N(c4ccccc4)c4ccccc4)nc3Oc3cc(N(c4ccccc4)c4ccccc4)nc1c32 ; c1ccc(N(c2ccccc2)c2ccc3c(n2)Oc2cc(N(c4ccccc4)c4ccccc4)nc4c2B3c2ccc(N(c3ccccc3)c3ccccc3)nc2N4c2ccccc2)cc1 ; c1ccc(N(c2ccccc2)c2cc3c(cn2)B2c4cnc(N(c5ccccc5)c5ccccc5)cc4N(c4ccccc4)c4nc(N(c5ccccc5)c5ccccc5)cc(c42)N3c2ccccc2)cc1]

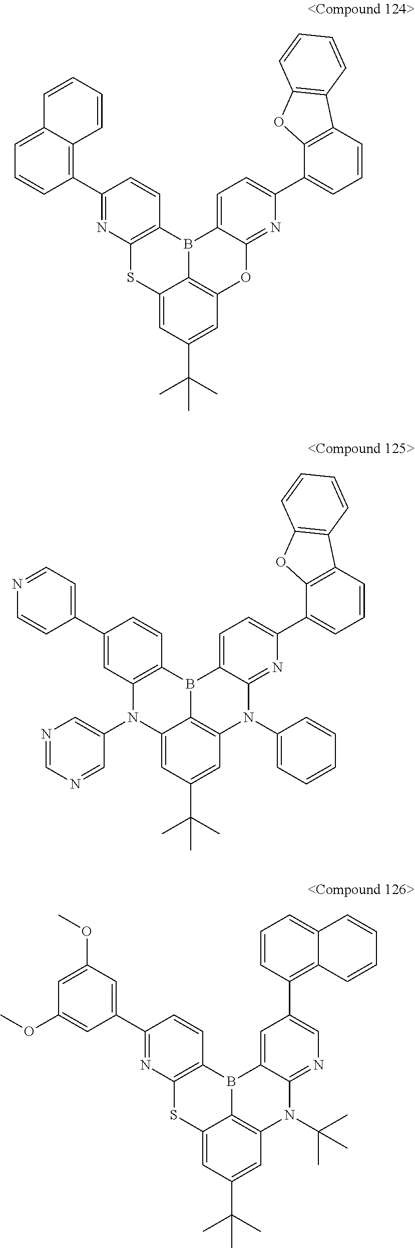 [SMILES: CC(C)(C)c1cc2c3c(c1)Sc1nc(-c4cccc5ccccc45)ccc1B3c1ccc(-c3cccc4c3oc3ccccc34)nc1O2 ; CC(C)(C)c1cc2c3c(c1)N(c1ccccc1)c1nc(-c4cccc5c4oc4ccccc45)ccc1B3c1ccc(-c3ccncc3)cc1N2c1cncnc1 ; COc1cc(OC)cc(-c2ccc3c(n2)Sc2cc(C(C)(C)C)cc4c2B3c2cc(-c3cccc5ccccc35)cnc2N4C(C)(C)C)c1]

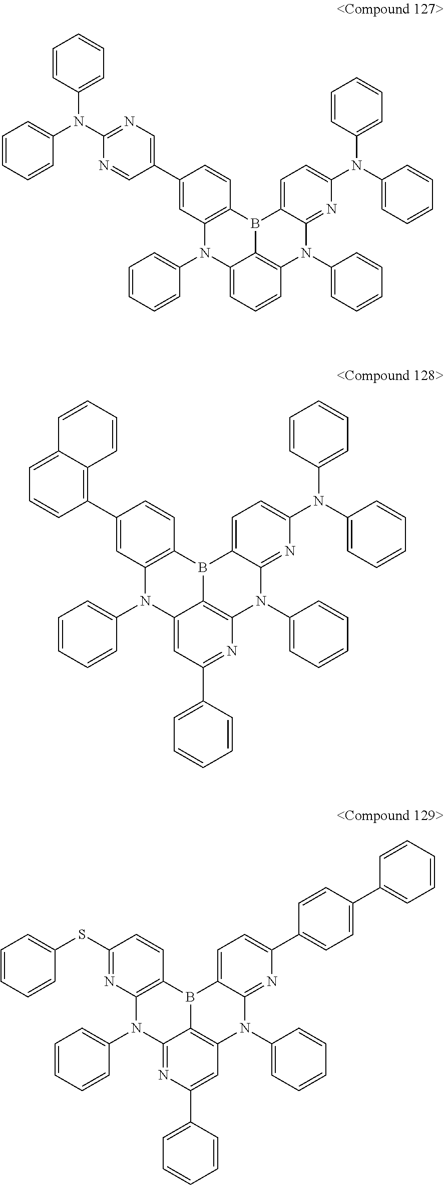 [SMILES: c1ccc(N(c2ccccc2)c2ccc3c(n2)N(c2ccccc2)c2cccc4c2B3c2ccc(-c3cnc(N(c5ccccc5)c5ccccc5)nc3)cc2N4c2ccccc2)cc1 ; c1ccc(-c2cc3c4c(n2)N(c2ccccc2)c2nc(N(c5ccccc5)c5ccccc5)ccc2B4c2ccc(-c4cccc5ccccc45)cc2N3c2ccccc2)cc1 ; c1ccc(Sc2ccc3c(n2)N(c2ccccc2)c2nc(-c4ccccc4)cc4c2B3c2ccc(-c3ccc(-c5ccccc5)cc3)nc2N4c2ccccc2)cc1]

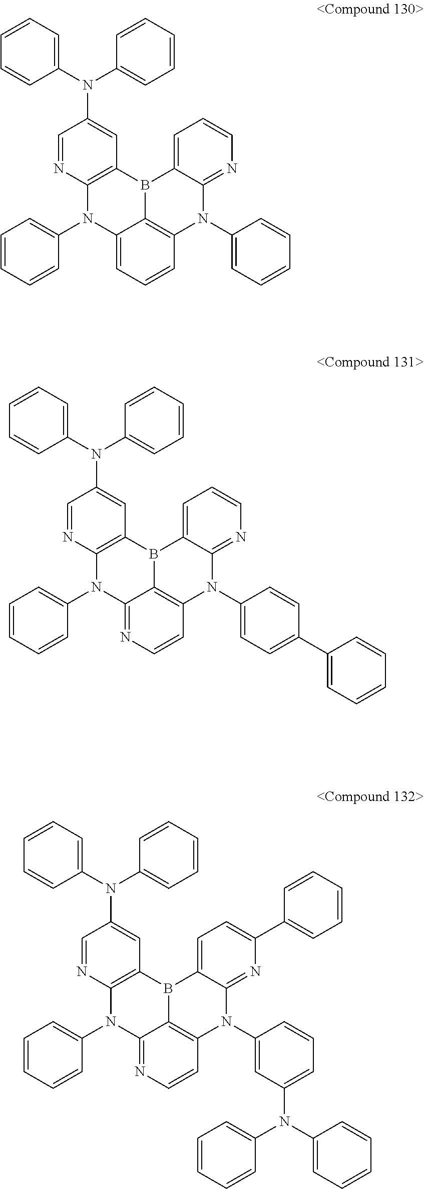 [SMILES: c1ccc(N(c2ccccc2)c2cnc3c(c2)B2c4cccnc4N(c4ccccc4)c4cccc(c42)N3c2ccccc2)cc1 ; c1ccc(-c2ccc(N3c4ccnc5c4B(c4cccnc43)c3cc(N(c4ccccc4)c4ccccc4)cnc3N5c3ccccc3)cc2)cc1 ; c1ccc(-c2ccc3c(n2)N(c2cccc(N(c4ccccc4)c4ccccc4)c2)c2ccnc4c2B3c2cc(N(c3ccccc3)c3ccccc3)cnc2N4c2ccccc2)cc1]

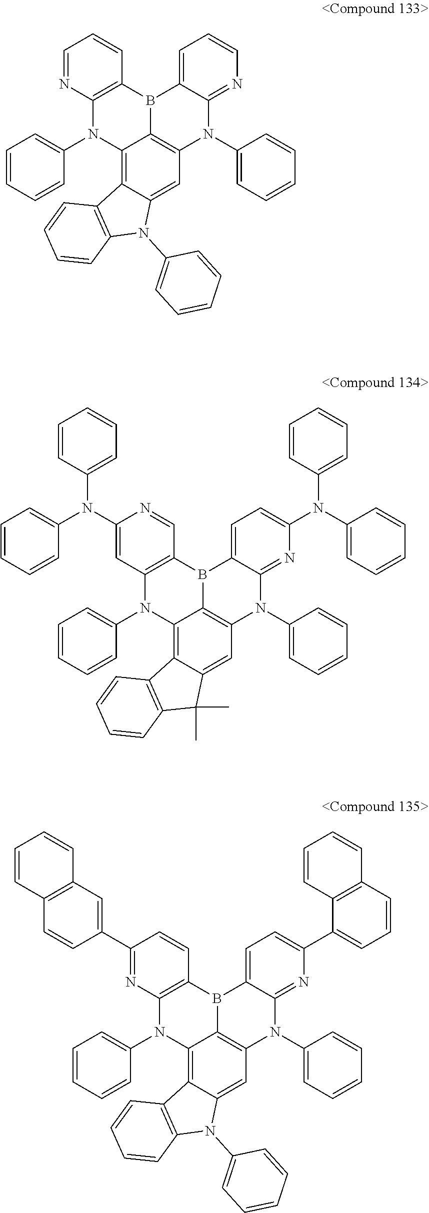 [SMILES: c1ccc(N2c3cc4c(c5c3B(c3cccnc32)c2cccnc2N5c2ccccc2)c2ccccc2n4-c2ccccc2)cc1 ; CC1(C)c2ccccc2-c2c1cc1c3c2N(c2ccccc2)c2cc(N(c4ccccc4)c4ccccc4)ncc2B3c2ccc(N(c3ccccc3)c3ccccc3)nc2N1c1ccccc1 ; c1ccc(N2c3cc4c(c5c3B(c3ccc(-c6cccc7ccccc67)nc32)c2ccc(-c3ccc6ccccc6c3)nc2N5c2ccccc2)c2ccccc2n4-c2ccccc2)cc1]

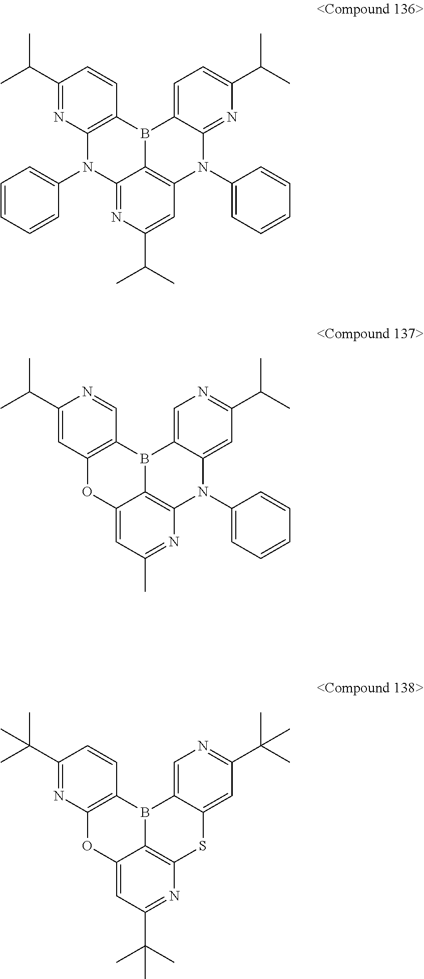

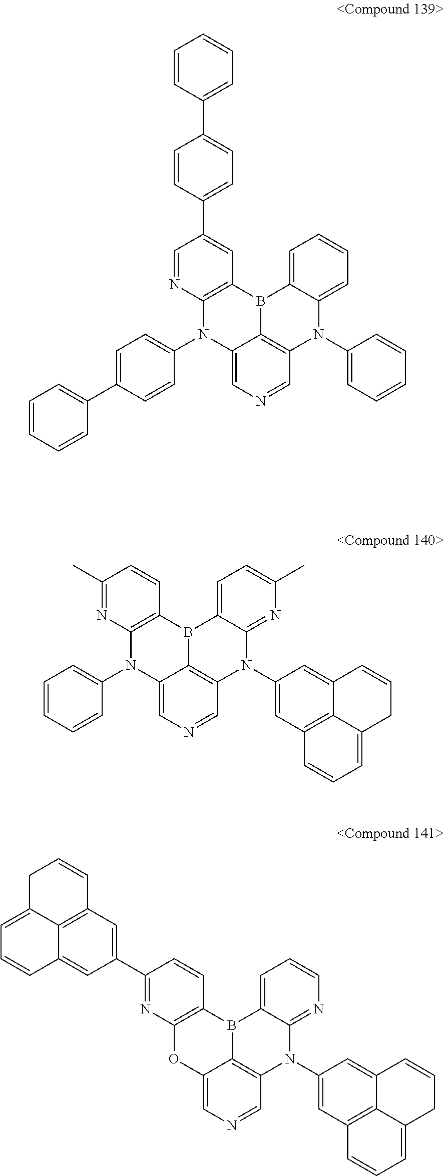 [SMILES: c1ccc(-c2ccc(-c3cnc4c(c3)B3c5ccccc5N(c5ccccc5)c5cncc(c53)N4c3ccc(-c4ccccc4)cc3)cc2)cc1 ; Cc1ccc2c(n1)N(c1ccccc1)c1cncc3c1B2c1ccc(C)nc1N3c1cc2c3c(cccc3c1)CC=C2 ; C1=Cc2cc(-c3ccc4c(n3)Oc3cncc5c3B4c3cccnc3N5c3cc4c5c(cccc5c3)CC=C4)cc3cccc(c23)C1]

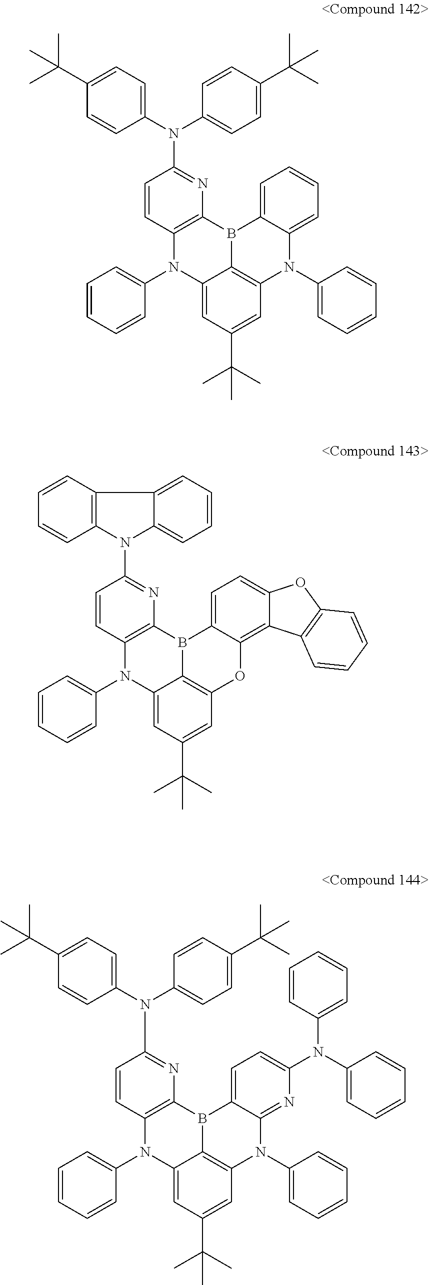 [SMILES: CC(C)(C)c1ccc(N(c2ccc(C(C)(C)C)cc2)c2ccc3c(n2)B2c4ccccc4N(c4ccccc4)c4cc(C(C)(C)C)cc(c42)N3c2ccccc2)cc1 ; CC(C)(C)c1cc2c3c(c1)N(c1ccccc1)c1ccc(-n4c5ccccc5c5ccccc54)nc1B3c1ccc3oc4ccccc4c3c1O2 ; CC(C)(C)c1ccc(N(c2ccc(C(C)(C)C)cc2)c2ccc3c(n2)B2c4ccc(N(c5ccccc5)c5ccccc5)nc4N(c4ccccc4)c4cc(C(C)(C)C)cc(c42)N3c2ccccc2)cc1]

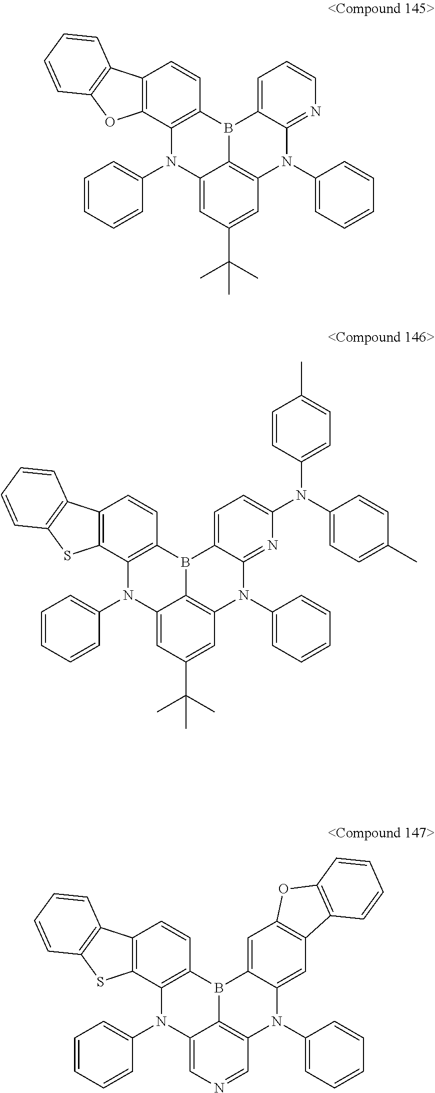 [SMILES: CC(C)(C)c1cc2c3c(c1)N(c1ccccc1)c1c(ccc4c1oc1ccccc14)B3c1cccnc1N2c1ccccc1 ; Cc1ccc(N(c2ccc(C)cc2)c2ccc3c(n2)N(c2ccccc2)c2cc(C(C)(C)C)cc4c2B3c2ccc3c(sc5ccccc53)c2N4c2ccccc2)cc1 ; c1ccc(N2c3cc4c(cc3B3c5ccc6c(sc7ccccc76)c5N(c5ccccc5)c5cncc2c53)oc2ccccc24)cc1]

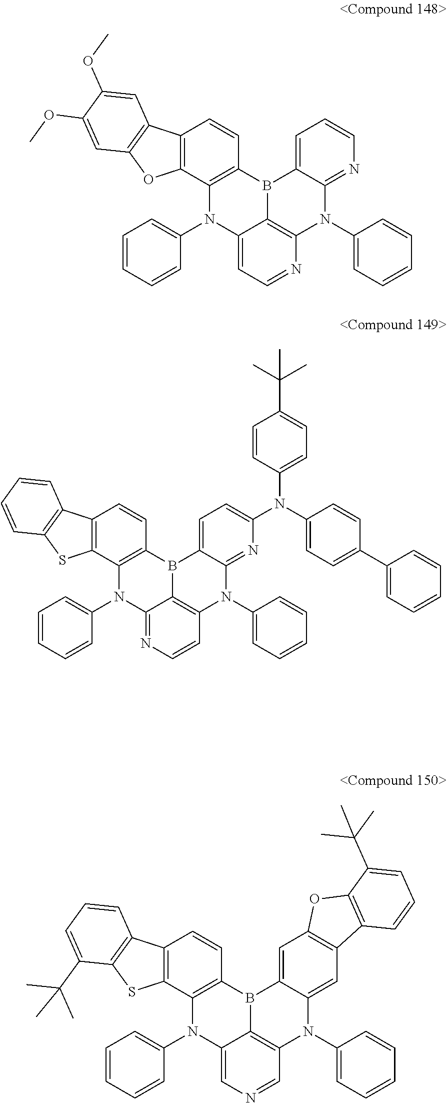 [SMILES: COc1cc2oc3c4c(ccc3c2cc1OC)B1c2cccnc2N(c2ccccc2)c2nccc(c21)N4c1ccccc1 ; CC(C)(C)c1ccc(N(c2ccc(-c3ccccc3)cc2)c2ccc3c(n2)N(c2ccccc2)c2ccnc4c2B3c2ccc3c(sc5ccccc53)c2N4c2ccccc2)cc1 ; CC(C)(C)c1cccc2c1oc1cc3c(cc12)N(c1ccccc1)c1cncc2c1B3c1ccc3c(sc4c(C(C)(C)C)cccc43)c1N2c1ccccc1]

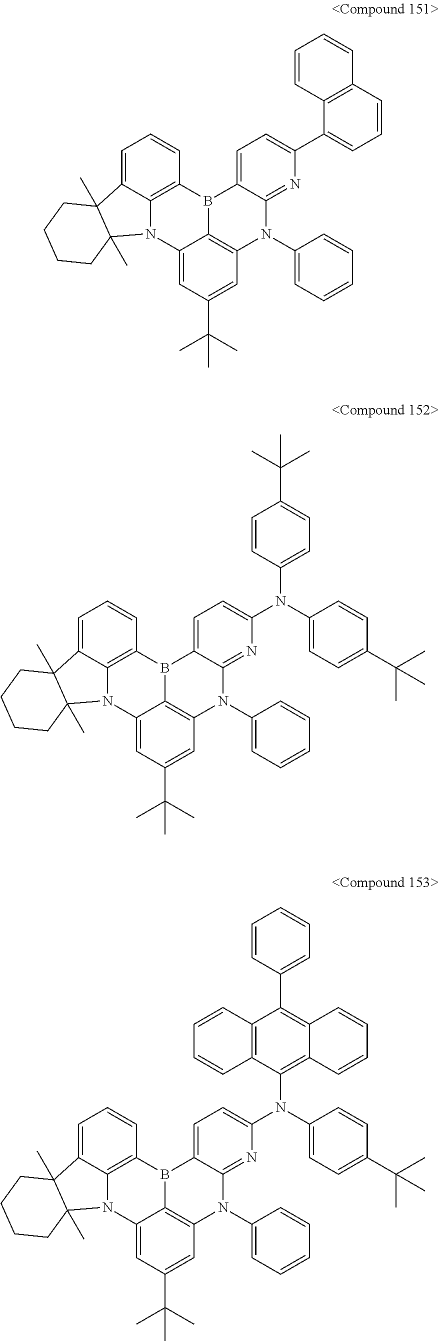 [SMILES: CC(C)(C)c1cc2c3c(c1)N1c4c(cccc4C4(C)CCCCC14C)B3c1ccc(-c3cccc4ccccc34)nc1N2c1ccccc1 ; CC(C)(C)c1ccc(N(c2ccc(C(C)(C)C)cc2)c2ccc3c(n2)N(c2ccccc2)c2cc(C(C)(C)C)cc4c2B3c2cccc3c2N4C2(C)CCCCC32C)cc1 ; CC(C)(C)c1ccc(N(c2ccc3c(n2)N(c2ccccc2)c2cc(C(C)(C)C)cc4c2B3c2cccc3c2N4C2(C)CCCCC32C)c2c3ccccc3c(-c3ccccc3)c3ccccc23)cc1]

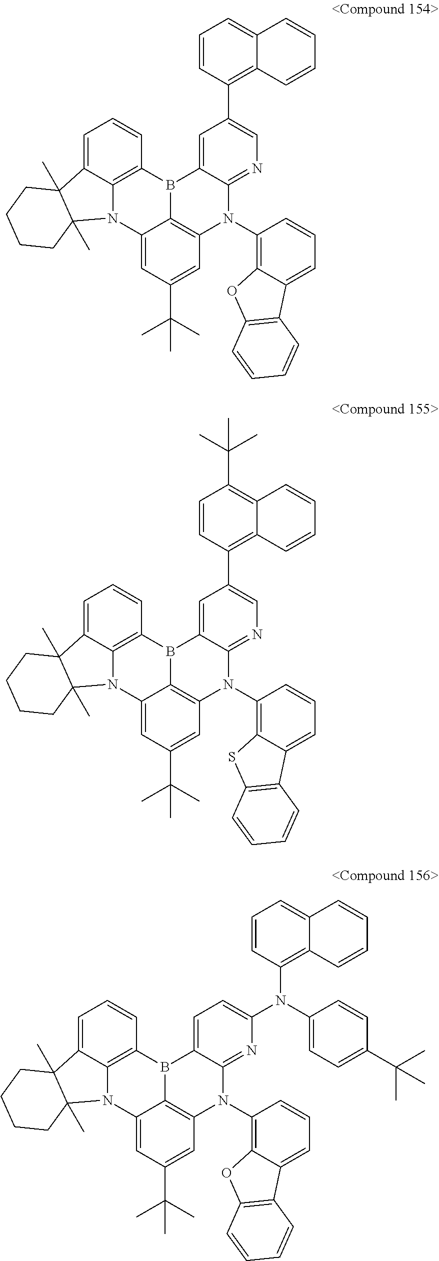

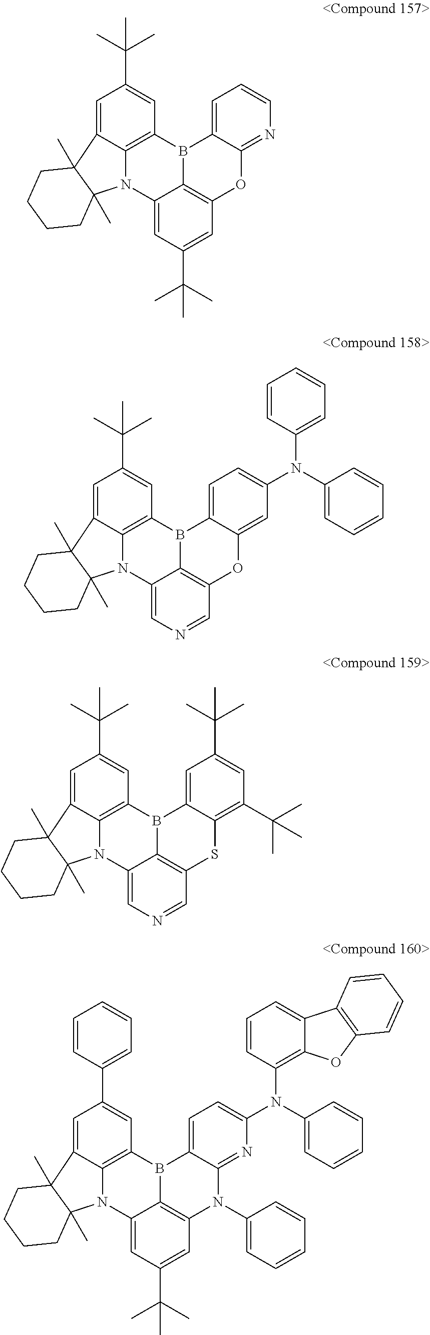 [SMILES: CC(C)(C)c1cc2c3c(c1)N1c4c(cc(C(C)(C)C)cc4C4(C)CCCCC14C)B3c1cccnc1O2 ; CC(C)(C)c1cc2c3c(c1)C1(C)CCCCC1(C)N3c1cncc3c1B2c1ccc(N(c2ccccc2)c2ccccc2)cc1O3 ; CC(C)(C)c1cc2c(c(C(C)(C)C)c1)Sc1cncc3c1B2c1cc(C(C)(C)C)cc2c1N3C1(C)CCCCC21C ; CC(C)(C)c1cc2c3c(c1)N1c4c(cc(-c5ccccc5)cc4C4(C)CCCCC14C)B3c1ccc(N(c3ccccc3)c3cccc4c3oc3ccccc34)nc1N2c1ccccc1]

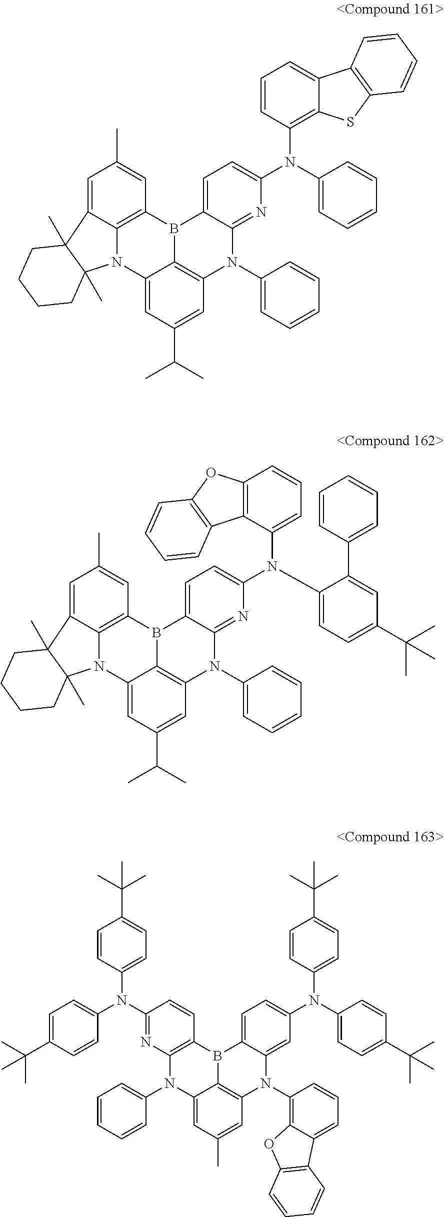

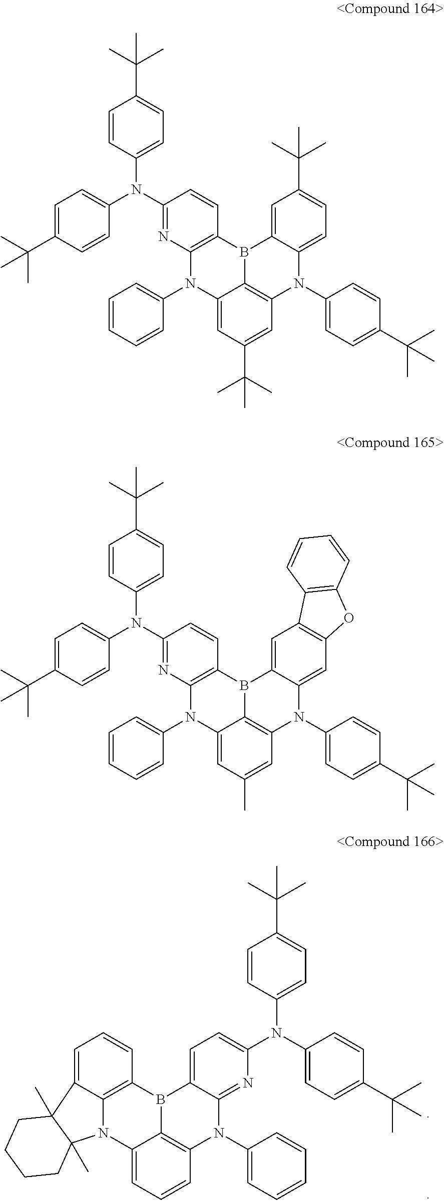

In particular some embodiments thereof, the present disclosure provides an organic light-emitting diode comprising: a first electrode; a second electrode facing the second electrode; and an organic layer interposed between the first electrode and the second electrode, wherein the organic layer includes a boron compound represented by Chemical Formula A.

Throughout the description of the present disclosure, the phrase “(an organic layer) includes at least one organic compound” may be construed to mean that “(an organic layer) may include a single organic compound species or two or more difference species of organic compounds falling within the scope of the present disclosure”.

In this regard, the organic light-emitting diode according to the present disclosure may include a light-emitting layer as an organic layer and may at least one of a hole injection layer, a hole transport layer, a functional layer capable of both hole injection and hole transport, an electron blocking layer, an electron transport layer, an electron injection layer, and a capping layer.

In more particular embodiments of the present disclosure, the organic layer disposed between the first electrode and the second electrode includes a light-emitting layer composed of a host and a dopant, wherein the boron compound represented by Chemical Formula A serves as the dopant while an anthracene derivative represented by Chemical Formula D may be used as the host:

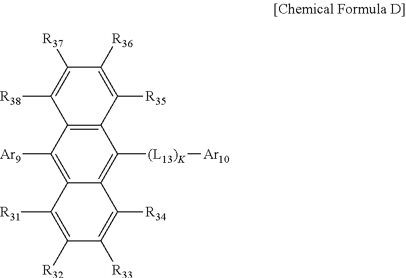

wherein,

R₃₁ to R₃₈, which are same or different, are each as defined for R₁ to R₁₁ in the boron compound;

Ar₉ and Ar₁₀, which are same or different, are each independently any one selected from a hydrogen atom, a deuterium atom, a substituted or unsubstituted alkyl of 1 to 30 carbon atoms, a substituted or unsubstituted aryl of 6 to 50 carbon atoms, a substituted or unsubstituted alkenyl of 2 to 30 carbon atoms, a substituted or unsubstituted alkynyl 2 to 20 carbon atoms, a substituted or unsubstituted cycloalkyl of 3 to 30 carbon atoms, a substituted or unsubstituted cycloalkenyl 5 to 30 carbon atoms, a substituted or unsubstituted heteroaryl of 2 to 50 carbon atoms, a substituted or unsubstituted heterocycloalkyl of 2 to 30 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted alkylamine of 1 to 30 carbon atoms, a substituted or unsubstituted arylamine of 6 to 30 carbon atoms, a substituted or unsubstituted alkylsilyl of 1 to 30 carbon atoms, and a substituted or unsubstituted arylsilyl of 6 to 30 carbon atoms;

L₁₃, which functions as a linker, is a single bond or is selected from a substituted or unsubstituted arylene of 6 to 20 carbon atoms, and a substituted or unsubstituted heteroarylene of 2 to 20 carbon atoms; and

k is an integer of 1 to 3, wherein when k is 2 or greater, the corresponding L₁₃'s are same or different,

wherein the term “substituted” in the expression “substituted or unsubstituted” is as defined above.

In this case, L₁₃ may be a single bond or a substituted or unsubstituted arylene of 6 to 20 carbon atoms, and k may be 1 or 2, with the proviso that when k is 2, corresponding L₁₃'s may be same or different.

For a more exemplary host, Ar₉ in Chemical Formula D may be a substituent represented by the following Chemical Formula D-1:

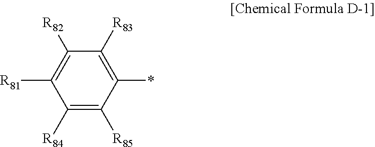

wherein, R₈₁ to R₈₅, which may be same or different, are as defined for R₁ to R₁₁, above; and may each be linked to an adjacent one to form a saturated or unsaturated cyclic ring.

According to one embodiment, the anthracene derivative may be any one selected from the compounds represented by the following [Chemical Formula D1] to [Chemical Formula D48]:

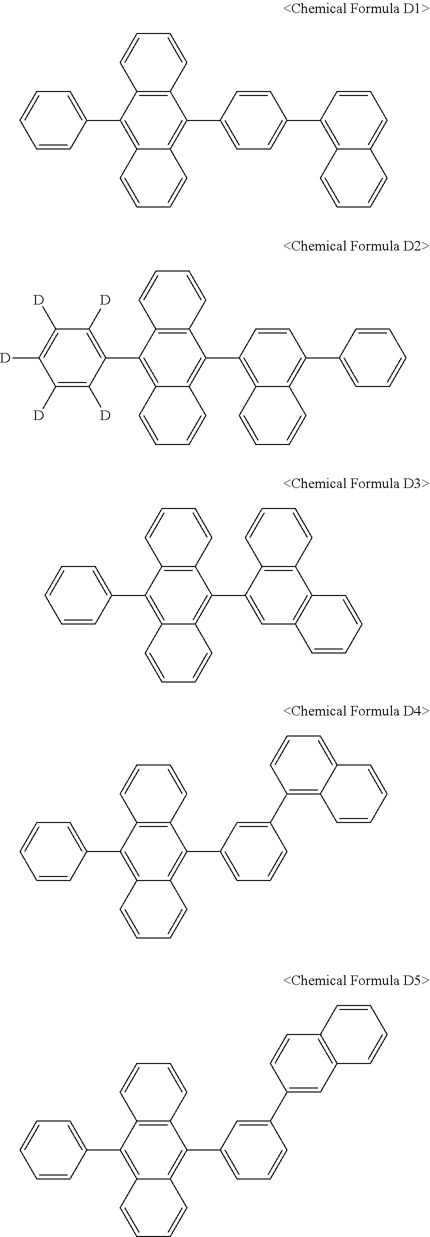

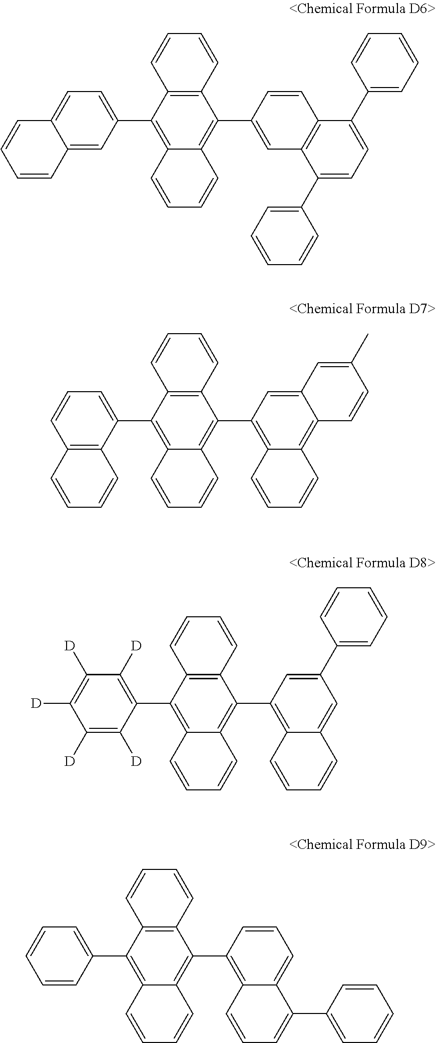

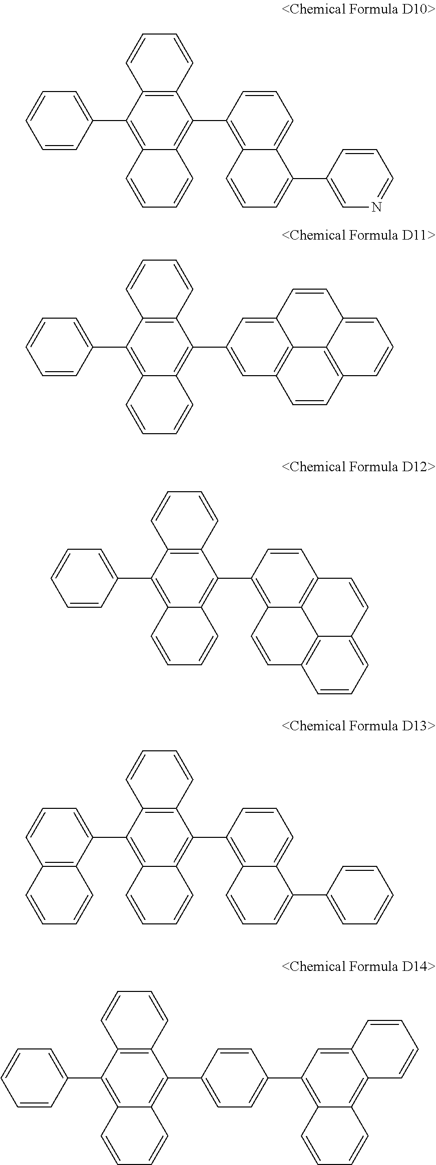

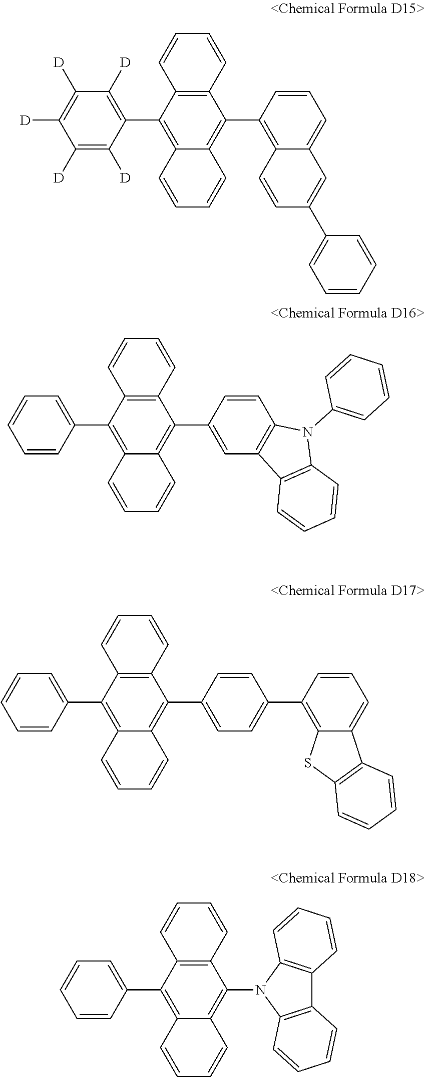 [SMILES: [2H]c1c([2H])c([2H])c(-c2c3ccccc3c(-c3cccc4cc(-c5ccccc5)ccc34)c3ccccc23)c([2H])c1[2H] ; c1ccc(-c2c3ccccc3c(-c3ccc4c(c3)c3ccccc3n4-c3ccccc3)c3ccccc23)cc1 ; c1ccc(-c2c3ccccc3c(-c3ccc(-c4cccc5c4sc4ccccc45)cc3)c3ccccc23)cc1 ; c1ccc(-c2c3ccccc3c(-n3c4ccccc4c4ccccc43)c3ccccc23)cc1]

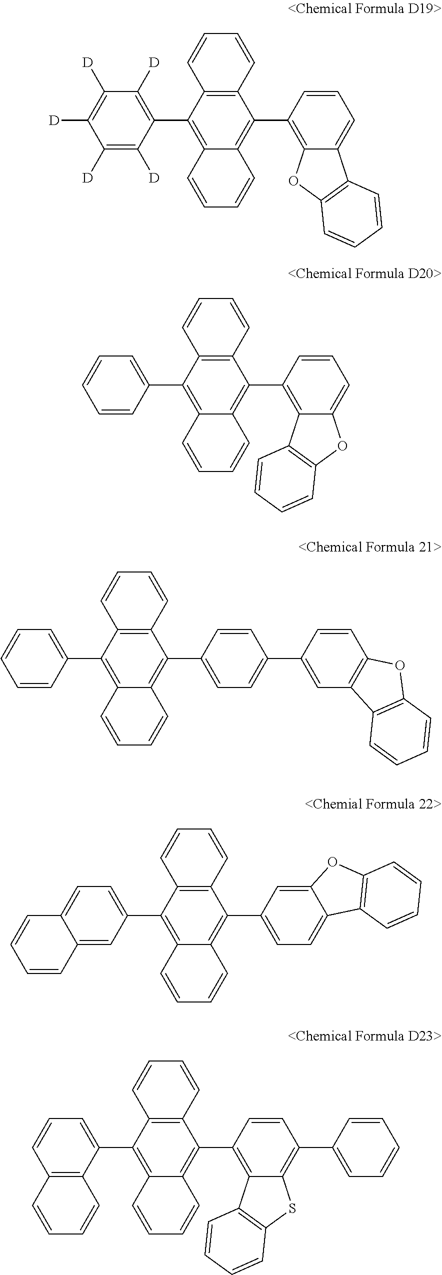 [SMILES: [2H]c1c([2H])c([2H])c(-c2c3ccccc3c(-c3cccc4c3oc3ccccc34)c3ccccc23)c([2H])c1[2H] ; c1ccc(-c2c3ccccc3c(-c3cccc4oc5ccccc5c34)c3ccccc23)cc1 ; c1ccc(-c2c3ccccc3c(-c3ccc(-c4ccc5oc6ccccc6c5c4)cc3)c3ccccc23)cc1 ; c1ccc2cc(-c3c4ccccc4c(-c4ccc5c(c4)oc4ccccc45)c4ccccc34)ccc2c1 ; c1ccc(-c2ccc(-c3c4ccccc4c(-c4cccc5ccccc45)c4ccccc34)c3c2sc2ccccc23)cc1]

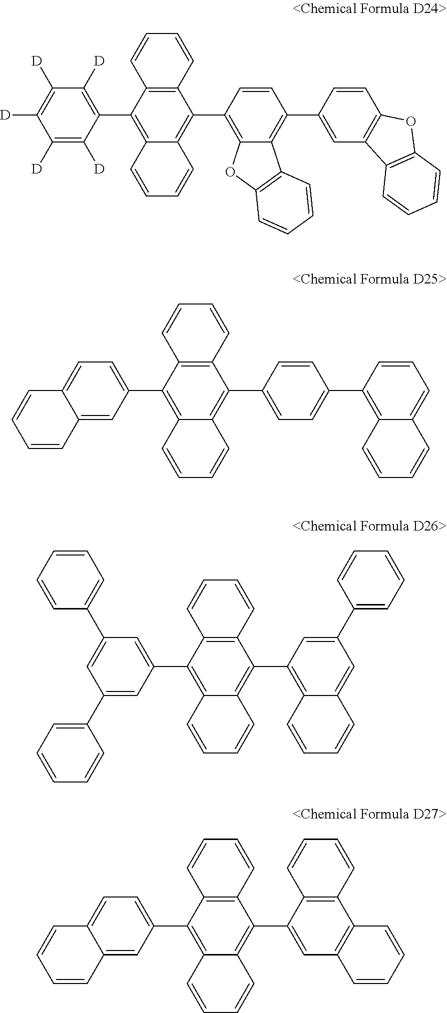

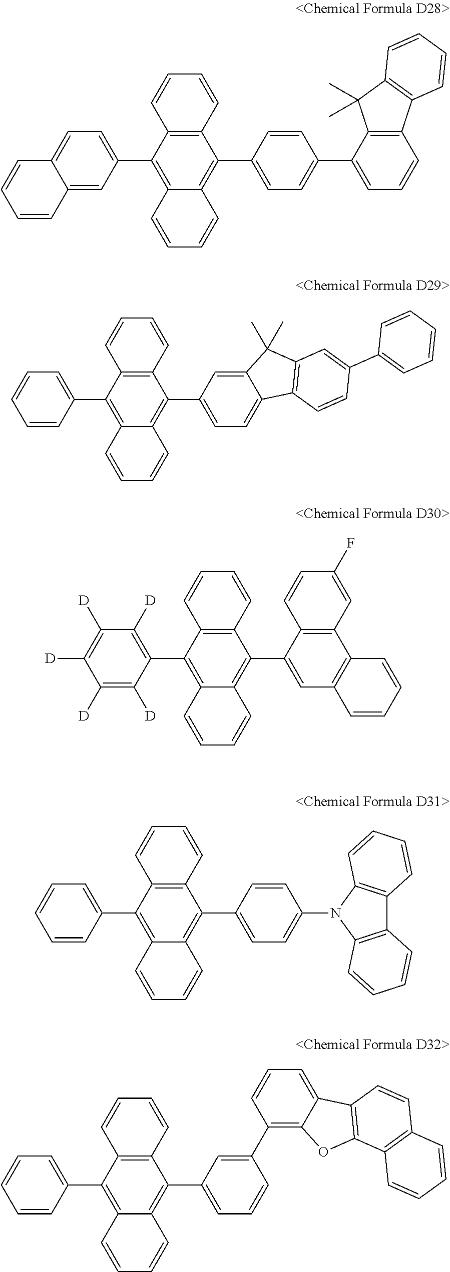

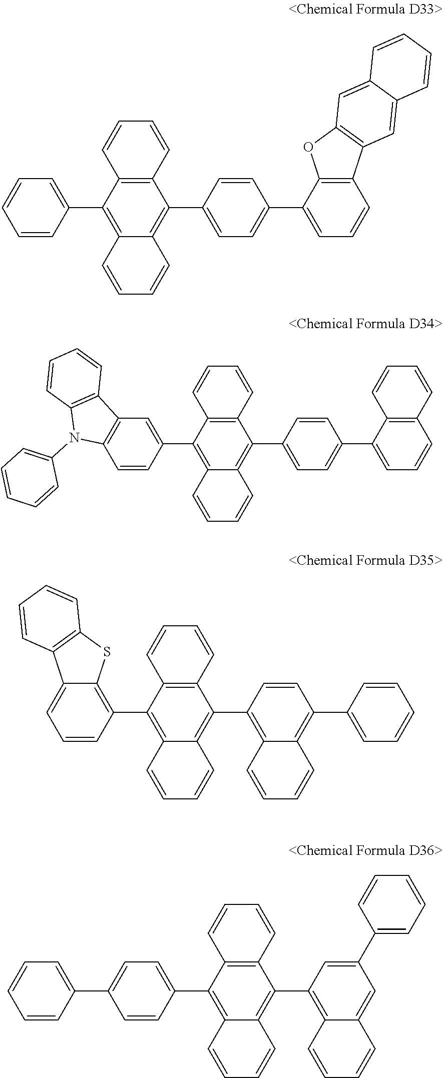

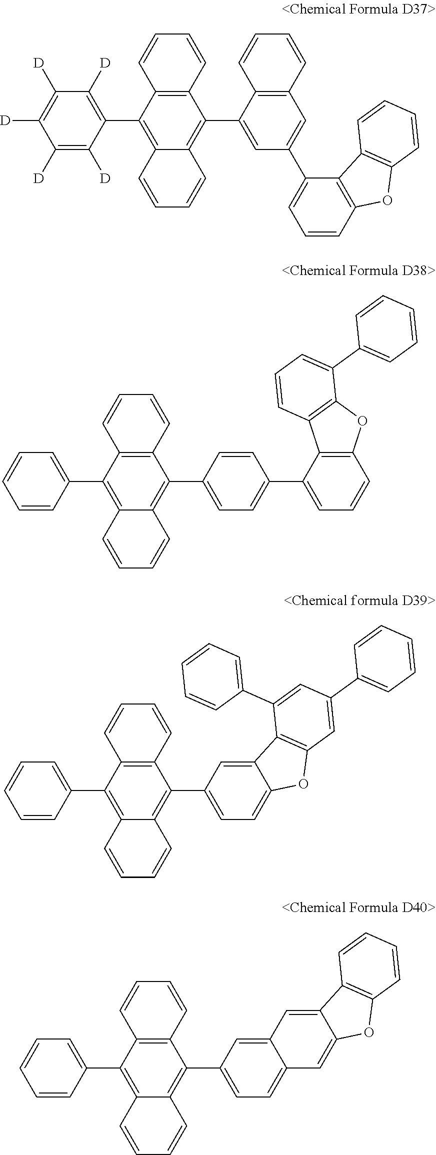 [SMILES: [2H]c1c([2H])c([2H])c(-c2c3ccccc3c(-c3cc(-c4cccc5oc6ccccc6c45)cc4ccccc34)c3ccccc23)c([2H])c1[2H] ; c1ccc(-c2c3ccccc3c(-c3ccc(-c4cccc5oc6c(-c7ccccc7)cccc6c45)cc3)c3ccccc23)cc1 ; c1ccc(-c2cc(-c3ccccc3)c3c(c2)oc2ccc(-c4c5ccccc5c(-c5ccccc5)c5ccccc45)cc23)cc1 ; c1ccc(-c2c3ccccc3c(-c3ccc4cc5oc6ccccc6c5cc4c3)c3ccccc23)cc1]

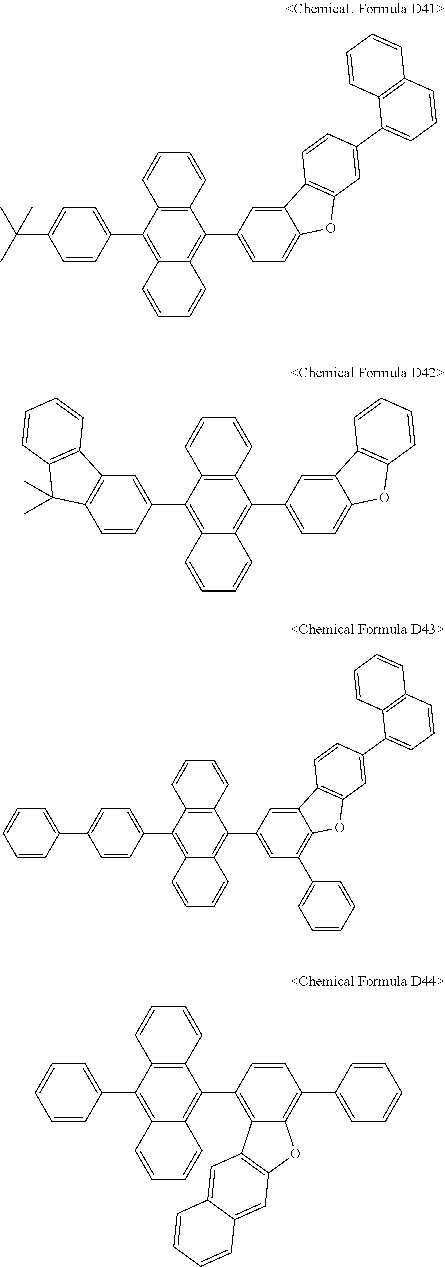 [SMILES: CC(C)(C)c1ccc(-c2c3ccccc3c(-c3ccc4oc5cc(-c6cccc7ccccc67)ccc5c4c3)c3ccccc23)cc1 ; CC1(C)c2ccccc2-c2cc(-c3c4ccccc4c(-c4ccc5oc6ccccc6c5c4)c4ccccc34)ccc21 ; c1ccc(-c2ccc(-c3c4ccccc4c(-c4cc(-c5ccccc5)c5oc6cc(-c7cccc8ccccc78)ccc6c5c4)c4ccccc34)cc2)cc1 ; c1ccc(-c2c3ccccc3c(-c3ccc(-c4ccccc4)c4oc5cc6ccccc6cc5c34)c3ccccc23)cc1]

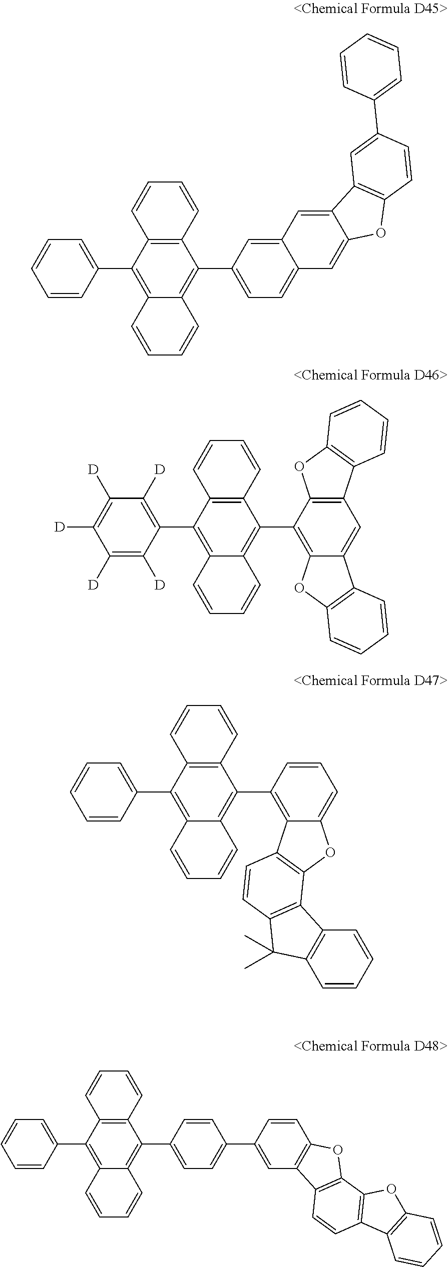 [SMILES: c1ccc(-c2ccc3oc4cc5ccc(-c6c7ccccc7c(-c7ccccc7)c7ccccc67)cc5cc4c3c2)cc1 ; [2H]c1c([2H])c([2H])c(-c2c3ccccc3c(-c3c4oc5ccccc5c4cc4c3oc3ccccc34)c3ccccc23)c([2H])c1[2H] ; CC1(C)c2ccccc2-c2c1ccc1c2oc2cccc(-c3c4ccccc4c(-c4ccccc4)c4ccccc34)c21 ; c1ccc(-c2c3ccccc3c(-c3ccc(-c4ccc5oc6c(ccc7c8ccccc8oc76)c5c4)cc3)c3ccccc23)cc1]

In a particular embodiment thereof, the present disclosure provides an organic light-emitting diode comprises: an anode as a first electrode; a cathode as a second electrode facing the first electrode; and an organic layer interposed between the anode and the cathode, wherein the organic layer comprises at least one of the boron compounds represented by Chemical Formula A as a dopant and at least one of the compounds represented by Chemical Formula D as a host. Having such structural characteristics, the organic light-emitting diode according to the present disclosure can be driven at a low voltage with high luminous efficiency.

The content of the dopant in the light-emitting layer may range from about 0.01 to 20 parts by weight, based on 100 parts by weight of the host, but is not limited thereto.

In addition to the dopant and the host, the light emitting layer may further include various host and dopant materials.

Hereinafter, an organic light emitting diode according to an embodiment of the present disclosure will be elucidated with reference to the drawing.

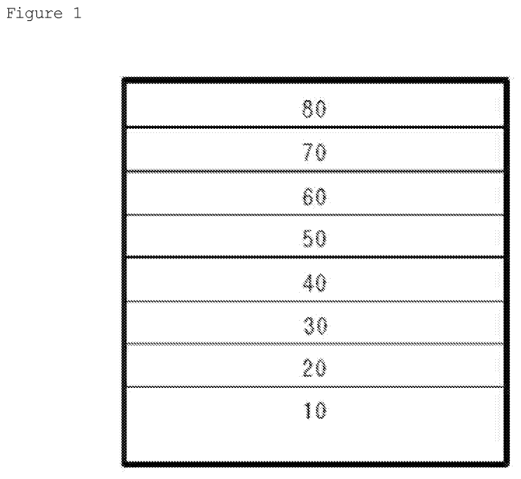

FIG. 1 is a schematic diagram of an organic light emitting diode according to an embodiment of the present disclosure.

As shown in FIG. 1, the organic light-emitting diode according to an embodiment of the present disclosure comprises an anode 20, a hole transport layer 40, an organic light-emitting layer 50 containing a host and a dopant, an electron transport layer 60, and a cathode 80, wherein the anode and the cathode serve as a first electrode and a second electrode, respectively, with the interposition of the hole transport layer 40 between the anode and the light-emitting layer, and the electron transport layer between the light-emitting layer and the cathode.

Furthermore, the organic light-emitting diode according to an embodiment of the present disclosure may comprise a hole injection layer between the anode 20 and the hole transport layer 40, and an electron injection layer 70 between the electron transport layer 60 and the cathode 80.

Reference is made to FIG. 1 with regard to the organic light emitting diode of the present disclosure and the fabrication thereof.

First, a substrate 10 is coated with an anode electrode material to form an anode 20. So long as it is used in a typical organic electroluminescence device, any substrate may be used as the substrate 10. Preferable is an organic substrate or transparent plastic substrate that exhibits excellent transparency, surface smoothness, ease of handling, and waterproofness. As the anode electrode material, indium tin oxide (ITO), indium zinc oxide (IZO), tin oxide (SnO₂), or zinc oxide (ZnO), which are transparent and superior in terms of conductivity, may be used.

A hole injection layer material is applied on the anode 20 by thermal deposition in a vacuum or by spin coating to form a hole injection layer 30. Subsequently, thermal deposition in a vacuum or by spin coating may also be conducted to form a hole transport layer 40 with a hole transport layer material on the hole injection layer 30.

So long as it is typically used in the art, any material may be selected for the hole injection layer without particular limitations thereto. Examples include, but are not limited to, 2-TNATA [4,4′,4″-tris (2-naphthylphenyl-phenylamino)-triphenylamine], NPD [N,N′-di (1-naphthyl)-N,N′-diphenylbenzidine)], TPD [N,N′-diphenyl-N,N′-bis(3-methylphenyl)-1,1′-biphenyl-4,4′-diamine], DNTPD [N,N′-diphenyl-N,N′-bis-[4-(phenyl-m-tolyl-amino)-phenyl]-biphenyl-4,4′-diamine], and HAT-CN (2,3,6,7,10,11-hexacyanohexaazatriphenylene).

Any material that is typically used in the art may be selected for the hole transport layer without particular limitations thereto. Examples include, but are not limited to, N,N′-bis(3-methylphenyl)-N,N′-diphenyl-[1,1-biphenyl]-4,4′-diamine (TPD) and N,N′-di(naphthalen-1-yl)-N,N′-diphenylbenzidine (a-NPD).

In an embodiment of the present disclosure, an electron blocking layer may be additionally disposed on the hole transport layer. Functioning to prevent the electrons injected from the electron injection layer from entering the hole transport layer from the light-emitting layer, the electron blocking layer is adapted to increase the life span and luminous efficiency of the diode. The electron blocking layer may be formed of a material known in the art or a combination of two well-known materials at a suitable position between the light emitting layer and the hole injection layer. Particularly, the electron blocking layer may be formed between the light emitting layer and the hole transport layer.

Next, the light-emitting layer 50 may be deposited on the hole transport layer 40 or the electron blocking layer by deposition in a vacuum or by spin coating.

Herein, the light-emitting layer may contain a host and a dopant and the materials are as described above.

In some embodiments of the present disclosure, the light-emitting layer particularly ranges in thickness from 50 to 2,000 Å.

Subsequently, the electron transport layer 60 is applied on the light-emitting layer by deposition in a vacuum and spin coating.

A material for use in the electron transport layer functions to stably carry the electrons injected from the electron injection electrode (cathode), and may be an electron transport material known in the art. Examples of the electron transport material known in the art include quinoline derivatives, particularly, tris(8-quinolinolate)aluminum (Alq₃), Liq, TAZ, BAlq, beryllium bis(benzoquinolin-10-olate) (Bebq₂), Compound 201, Compound 202, BCP, and oxadiazole derivatives such as PBD, BMD, and BND, but are not limited thereto:

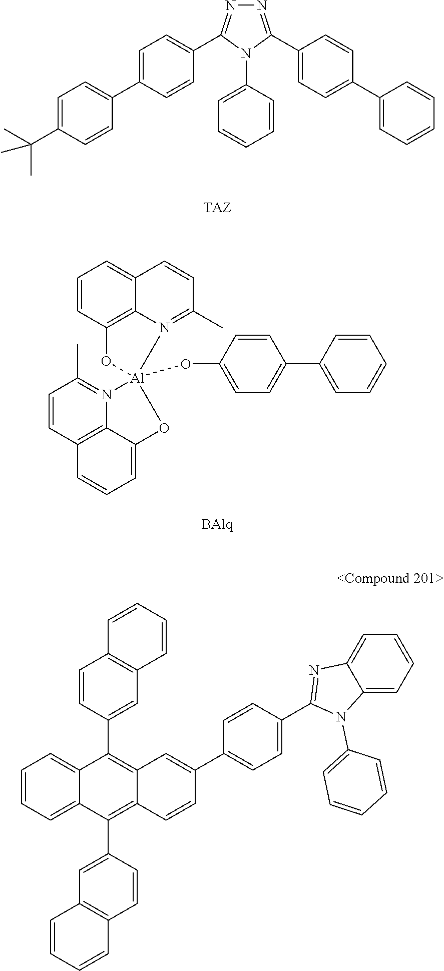

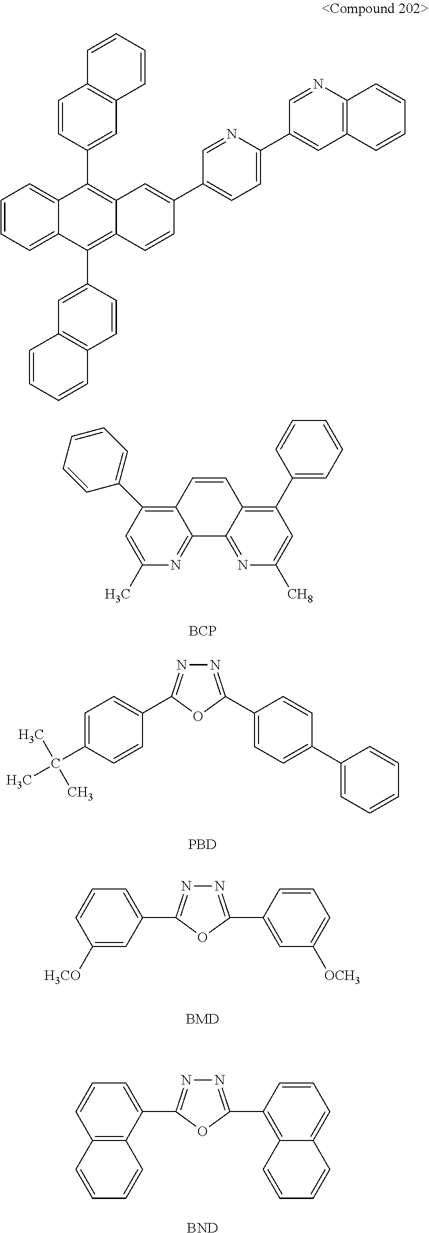

In the organic light emitting diode of the present disclosure, an electron injection layer (EIL) that functions to facilitate electron injection from the cathode may be deposited on the electron transport layer. The material for the EIL is not particularly limited.

Any material that is conventionally used in the art can be available for the electron injection layer without particular limitations. Examples include CsF, NaF, LiF, Li₂O, and BaO. Deposition conditions for the electron injection layer may vary, depending on compounds used, but may be generally selected from condition scopes that are almost the same as for the formation of hole injection layers.

The electron injection layer may range in thickness from about 1 Å to about 100 Å, and particularly from about 3 Å to about 90 Å. Given the thickness range for the electron injection layer, the diode can exhibit satisfactory electron injection properties without actually elevating a driving voltage.

In order to facilitate electron injection, the cathode may be made of a material having a small work function, such as metal or metal alloy such as lithium (Li), magnesium (Mg), calcium (Ca), an alloy aluminum (Al) thereof, aluminum-lithium (Al—Li), magnesium-indium (Mg—In), and magnesium-silver (Mg—Ag). Alternatively, ITO or IZO may be employed to form a transparent cathode for an organic light-emitting diode.

Moreover, the organic light-emitting diode of the present disclosure may further comprise a light-emitting layer containing a blue, green, or red luminescent material that emits radiations in the wavelength range of 380 nm to 800 nm. That is, the light-emitting layer in the present disclosure has a multi-layer structure wherein the blue, green, or red luminescent material may be a fluorescent material or a phosphorescent material.

Furthermore, at least one selected from among the layers may be deposited using a single-molecule deposition process or a solution process.

Here, the deposition process is a process by which a material is vaporized in a vacuum or at a low pressure and deposited to form a layer, and the solution process is a method in which a material is dissolved in a solvent and applied for the formation of a thin film by means of inkjet printing, roll-to-roll coating, screen printing, spray coating, dip coating, spin coating, etc.

Also, the organic light-emitting diode of the present disclosure may be applied to a device selected from among flat display devices, flexible display devices, monochrome or grayscale flat illumination devices, and monochrome or grayscale flexible illumination devices.

A better understanding of the present disclosure may be obtained through the following examples which are set forth to illustrate, but are not to be construed as limiting the present invention.

### EXAMPLES

### Synthesis Example 1: Synthesis of Compound 4

### Synthesis Example 1-(1): Synthesis of Intermediate 1-a

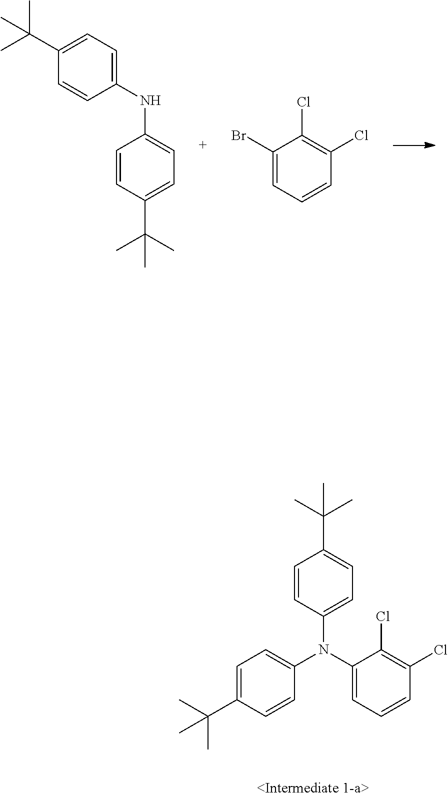 [SMILES: CC(C)(C)c1ccc(Nc2ccc(C(C)(C)C)cc2)cc1 ; Clc1cccc(Br)c1Cl ; CC(C)(C)c1ccc(N(c2ccc(C(C)(C)C)cc2)c2cccc(Cl)c2Cl)cc1]

In a round-bottom flask, bis(4-tert-butylphenyl)amine (50 g, 178 mmol), 1-bromo-2,3-dichlorobenzene (40.2 g, 178 mmol), tris(dibenzilideneacetaone)dipalladium (4.6 g, 3.6 mmol), sodium tert-butoxide (34.2 g, 356 mmol), tri-tert-butylphosphine (4.9 g, 10.0 mmol), and toluene (500 ml) were stirred together under reflux for 12 hours. After completion of the reaction, the reaction mixture was split into layers. The organic layer thus obtained was concentrated in a vacuum, separated with a column, and dried to afford Intermediate 1-a (42.5 g, yield 56%).

### Synthesis Example 1-(2): Synthesis of Intermediate 1-b

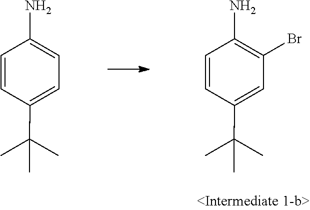

In a round-bottom flask, 4-tert-butylaniline (50 g, 335 mmol), N-bromosuccinimide (59.6 g, 335 mmol), and dimethylformamide (500 ml) were stirred together at room temperature for 12 hours under a nitrogen atmosphere. After completion of the reaction, the reaction mixture was split into layers. The organic layer thus obtained was concentrated in a vacuum, separated with a column, and dried to afford Intermediate 1-b (64.9 g, yield 85%).

### Synthesis Example 1-(3): Synthesis of Intermediate 1-c

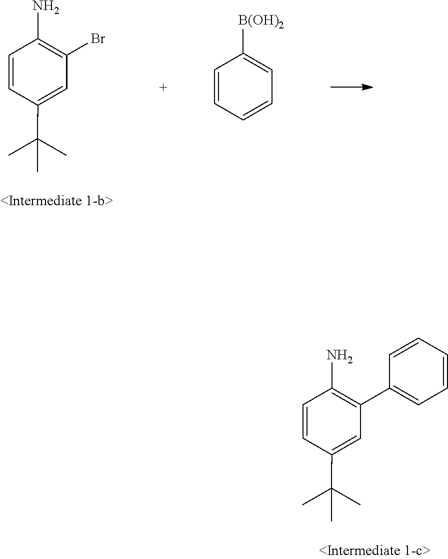 [SMILES: CC(C)(C)c1ccc(N)c(Br)c1 ; OB(O)c1ccccc1 ; CC(C)(C)c1ccc(N)c(-c2ccccc2)c1]

In a round-bottom flask, Intermediate 1-b (60 g, 262 mmol), phenyl boronic acid (38.4 g, 314 mmol), tetrakistriphenyl phosphine palladium (6.0 g, 5.2 mmol), potassium carbonate (54.4 g, 394 mmol), toluene (300 ml), 1,4-dioxane (300 ml), and water (180 ml) were stirred together under reflux for 12 hours. After completion of the reaction, the reaction mixture was split into layers. The organic layer thus obtained was concentrated in a vacuum, separated with a column, and dried to afford Intermediate 1-c (46.2 g, yield 78%).

### Synthesis Example 1-(4): Synthesis of Intermediate 1-d

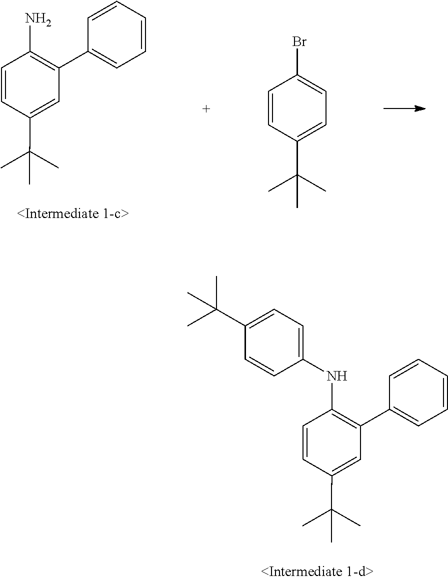 [SMILES: CC(C)(C)c1ccc(N)c(-c2ccccc2)c1 ; CC(C)(C)c1ccc(Br)cc1 ; CC(C)(C)c1ccc(Nc2ccc(C(C)(C)C)cc2-c2ccccc2)cc1]

In a round-bottom flask, Intermediate 1-c (46 g, 204 mmol), 1-bromo-4-tert-butylbenzene (44.8 g, 194 mmol), tris(dibenzilideneacetaone)dipalladium (3.7 g, 4 mmol), sodium tert-butoxide (408 mmol), 2, 2′-bis(diphenylphosphino)-1,1′-binaphthyl (5.1 g, 8 mmol), and toluene (500 ml) were stirred under reflux for 12 hours. After completion of the reaction, the reaction mixture was split into layers. The organic layer thus obtained was concentrated in a vacuum, separated with a column, and dried to afford Intermediate 1-d (55.4 g, yield 76%)

### Synthesis Example 1-(5): Synthesis of Intermediate 1-e

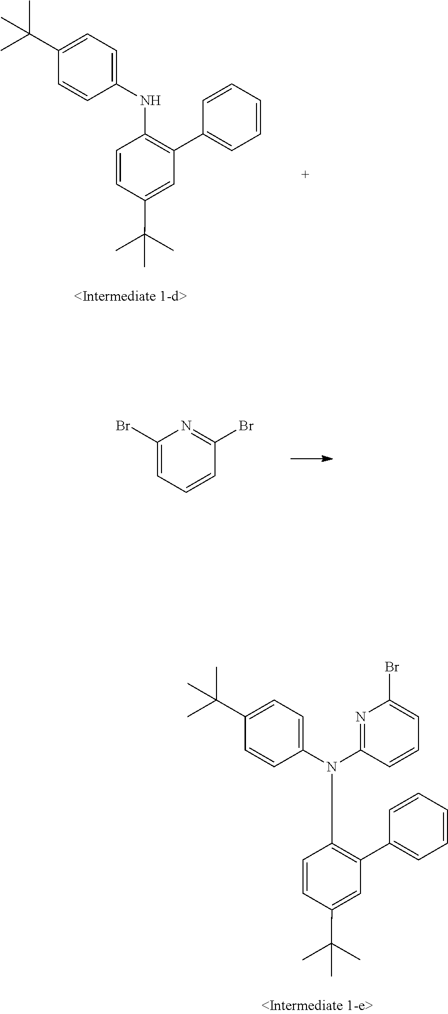 [SMILES: CC(C)(C)c1ccc(Nc2ccc(C(C)(C)C)cc2-c2ccccc2)cc1 ; Brc1cccc(Br)n1 ; CC(C)(C)c1ccc(N(c2cccc(Br)n2)c2ccc(C(C)(C)C)cc2-c2ccccc2)cc1]

The same procedure as in Synthesis Example 1-(4) was carried out, with the exception of using Intermediate 1-d and 2,6-dibromopyridine instead of Intermediate 1-c and 1-bromo-4-tert-butylbenzene, respectively, to afford <Intermediate 1-e>. (yield 72%) Synthesis Example 1-(6): Synthesis of Intermediate 1-f

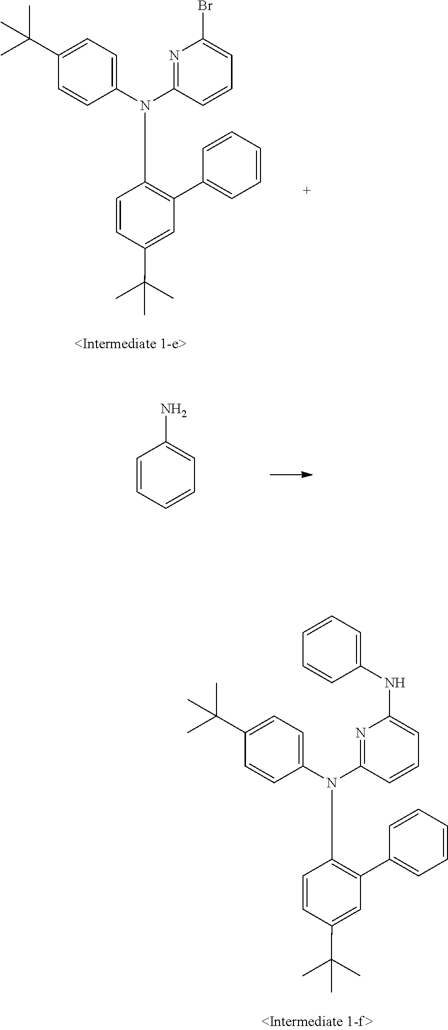 [SMILES: CC(C)(C)c1ccc(N(c2cccc(Br)n2)c2ccc(C(C)(C)C)cc2-c2ccccc2)cc1 ; Nc1ccccc1 ; CC(C)(C)c1ccc(N(c2cccc(Nc3ccccc3)n2)c2ccc(C(C)(C)C)cc2-c2ccccc2)cc1]

The same procedure as in Synthesis Example 1-(4) was carried out, with the exception of using Intermediate 1-e and aniline instead of 1-bromo-4-tert-butylbenzene and Intermediate 1-c, respectively, to afford <Intermediate 1-f>. (yield 73%)

### Synthesis Example 1-(7): Synthesis of Intermediate 1-g

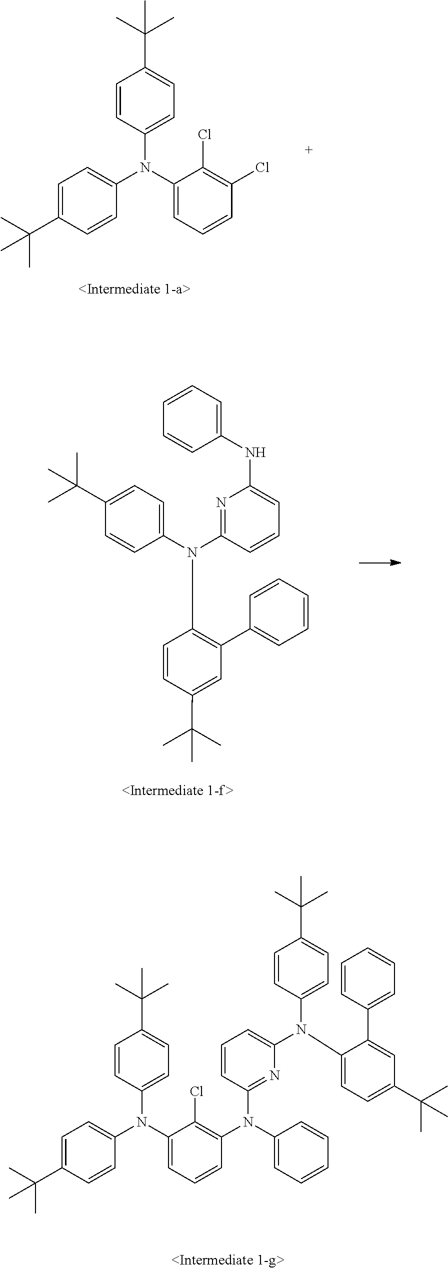 [SMILES: CC(C)(C)c1ccc(N(c2ccc(C(C)(C)C)cc2)c2cccc(Cl)c2Cl)cc1 ; CC(C)(C)c1ccc(N(c2cccc(Nc3ccccc3)n2)c2ccc(C(C)(C)C)cc2-c2ccccc2)cc1 ; CC(C)(C)c1ccc(N(c2ccc(C(C)(C)C)cc2)c2cccc(N(c3ccccc3)c3cccc(N(c4ccc(C(C)(C)C)cc4)c4ccc(C(C)(C)C)cc4-c4ccccc4)n3)c2Cl)cc1]

The same procedure as in Synthesis Example 1-(1) was carried out, with the exception of using Intermediate 1-a and Intermediate 1-f instead of 1-bromo-2,3-dichlorobenzene and bis(4-tert-butylphenyl)amine, respectively, to afford <Intermediate 1-g>. (yield 66%)

### Synthesis Example 1-(8): Synthesis of Compound 4

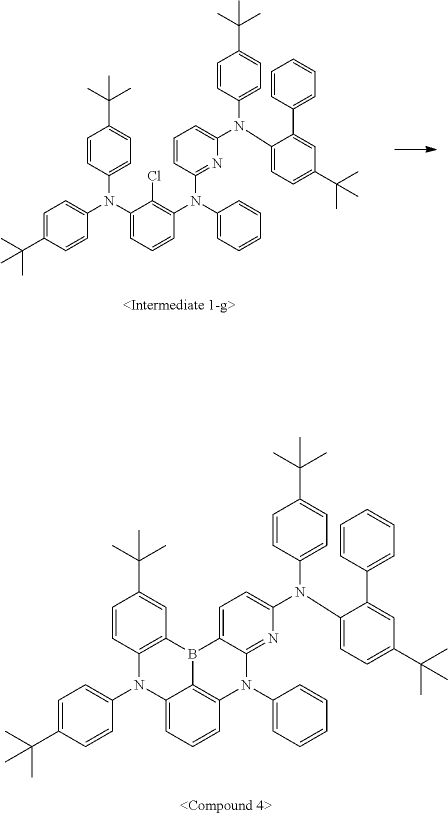

In a round-bottom flask, Intermediate 1-g (30 g, 32.8 mmol) was stirred together with tert-butylbenzene (300 ml) under a nitrogen atmosphere. The mixture was cooled to 0° C. and added with drops of 1.7 M tert-butyl lithium (48.2 ml, 81.9 mmol) before stirring at 60° C. for 3 hours. Then, the temperature was lowered to −30° C. and boron tribromide (16.4 g, 65.5 mmol) was added and stirred at room temperature for 1 hour. Subsequently, diisopropylethylamine (8.5 g, 65.5 mmol) was added and stirred at 120° C. for 3 hours. After completion of the reaction, the reaction mixture was split to layers. The organic layer thus obtained was concentrated in a vacuum, separated with a column, and dried to afford Compound 4 (4.4 g, yield 15%). (MS:889.05)

### Synthesis Example 2: Synthesis of Compound 9

### Synthesis Example 2-(1): Synthesis of Intermediate 2-a

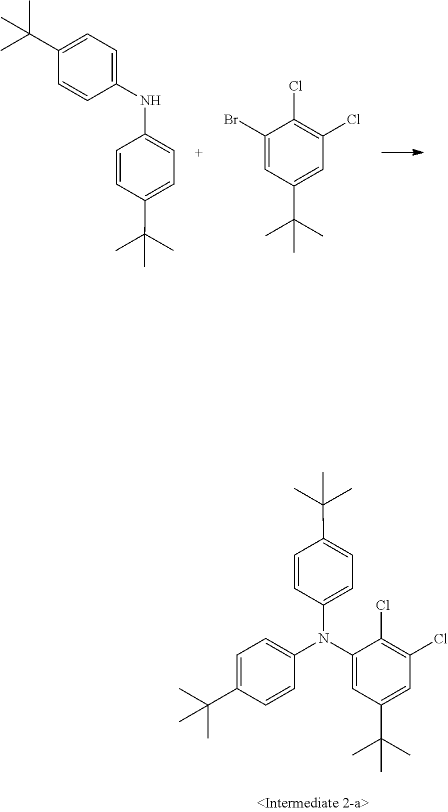 [SMILES: CC(C)(C)c1ccc(Nc2ccc(C(C)(C)C)cc2)cc1 ; CC(C)(C)c1cc(Cl)c(Cl)c(Br)c1 ; CC(C)(C)c1ccc(N(c2ccc(C(C)(C)C)cc2)c2cc(C(C)(C)C)cc(Cl)c2Cl)cc1]

The same procedure as in Synthesis Example 1-(1) was carried out, with the exception of using 1-bromo-2,3-dichloro-5-tert-butylbenzene instead of 1-bromo-2,3-dichlorobenzene to afford <Intermediate 2-a>. (yield 60%)

### Synthesis Example 2-(2): Synthesis of Intermediate 2-b

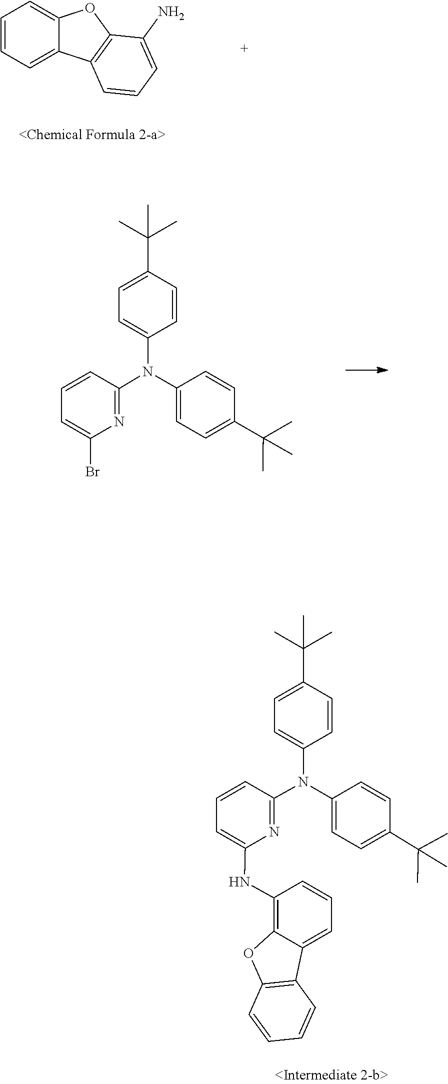 [SMILES: Nc1cccc2c1oc1ccccc12 ; CC(C)(C)c1ccc(N(c2ccc(C(C)(C)C)cc2)c2cccc(Br)n2)cc1 ; CC(C)(C)c1ccc(N(c2ccc(C(C)(C)C)cc2)c2cccc(Nc3cccc4c3oc3ccccc34)n2)cc1]

The same procedure as in Synthesis Example 1-(6) was carried out, with the exception of using the compound of Chemical Formula 2-a and 4-aminodibenzofuran instead of Intermediate 1-e and aniline, respectively, to afford <Intermediate 2-b>. (yield 70%)

### Synthesis Example 2-(3): Synthesis of Intermediate 2-c

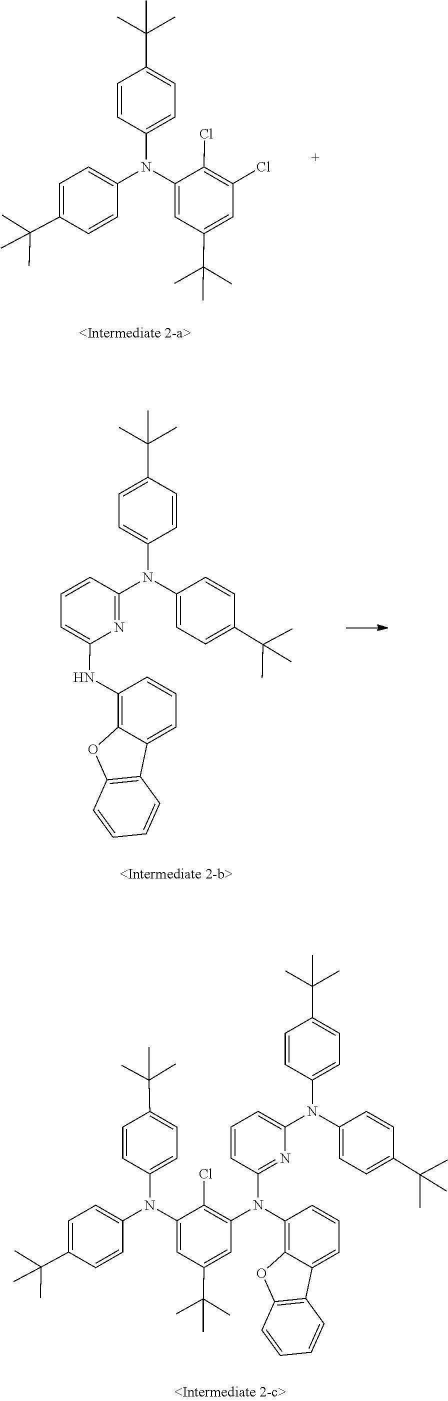 [SMILES: CC(C)(C)c1ccc(N(c2ccc(C(C)(C)C)cc2)c2cc(C(C)(C)C)cc(Cl)c2Cl)cc1 ; CC(C)(C)c1ccc(N(c2ccc(C(C)(C)C)cc2)c2cccc(Nc3cccc4c3oc3ccccc34)n2)cc1 ; CC(C)(C)c1ccc(N(c2ccc(C(C)(C)C)cc2)c2cccc(N(c3cc(C(C)(C)C)cc(N(c4ccc(C(C)(C)C)cc4)c4ccc(C(C)(C)C)cc4)c3Cl)c3cccc4c3oc3ccccc34)n2)cc1]

The same procedure as in Synthesis Example 1-(7) was carried out, with the exception of using Intermediate 2-a and Intermediate 2-b instead of Intermediate 1-a and Intermediate 1-f, respectively, to afford <Intermediate 2-c>. (yield 55%)

### Synthesis Example 2-(4): Synthesis of Compound 9

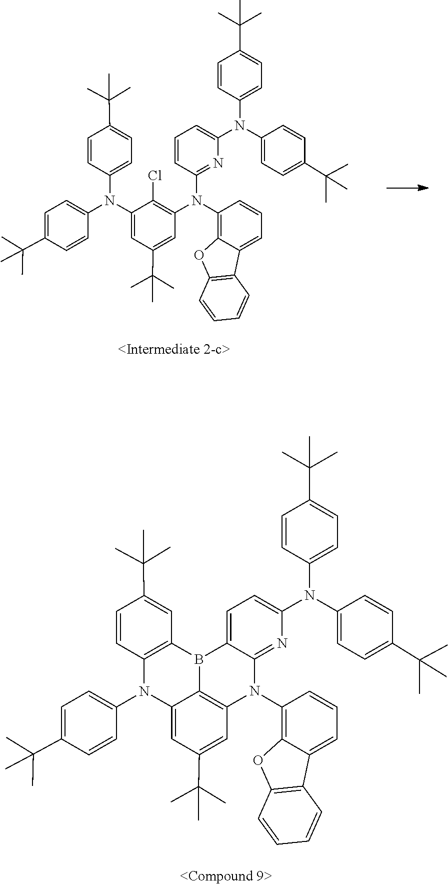

The same procedure as in Synthesis Example 1-(8) was carried out, with the exception of using Intermediate 2-c instead of Intermediate 1-g to afford <Compound 9>. (yield 11%) (MS:959.14)

### Synthesis Example 3: Synthesis of Compound 13

### Synthesis Example 3-(1): Synthesis of Intermediate 3-a

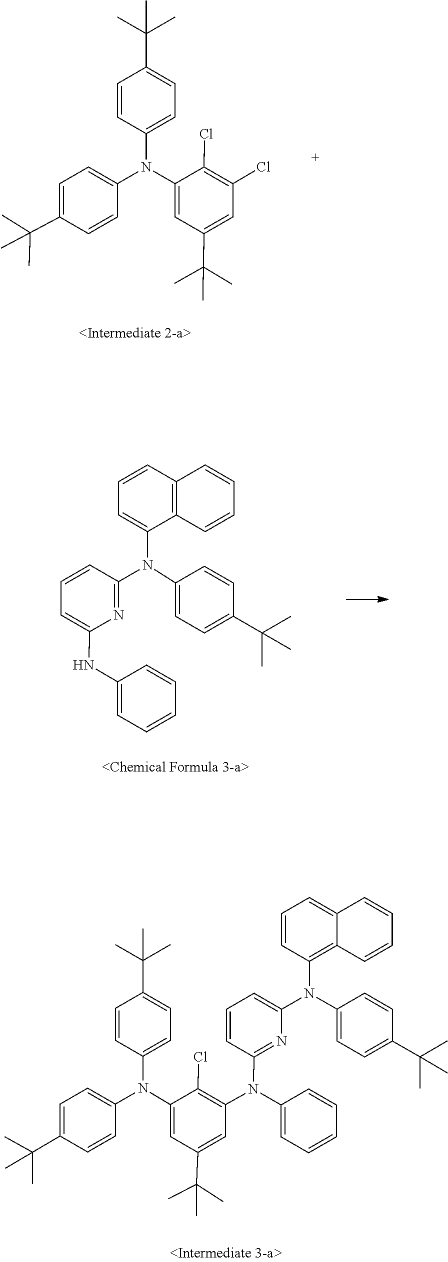 [SMILES: CC(C)(C)c1ccc(N(c2ccc(C(C)(C)C)cc2)c2cc(C(C)(C)C)cc(Cl)c2Cl)cc1 ; CC(C)(C)c1ccc(N(c2cccc(Nc3ccccc3)n2)c2cccc3ccccc23)cc1 ; CC(C)(C)c1ccc(N(c2ccc(C(C)(C)C)cc2)c2cc(C(C)(C)C)cc(N(c3ccccc3)c3cccc(N(c4ccc(C(C)(C)C)cc4)c4cccc5ccccc45)n3)c2Cl)cc1]

The same procedure as in Synthesis Example 1-(7) was carried out, with the exception of using Intermediate 2-a and the compound of Chemical Formula 3-a instead of Intermediate 1-a and Intermediate 1-f, respectively, to afford <Intermediate 3-a>. (yield 58%)

### Synthesis Example 3-(2): Synthesis of Compound 13

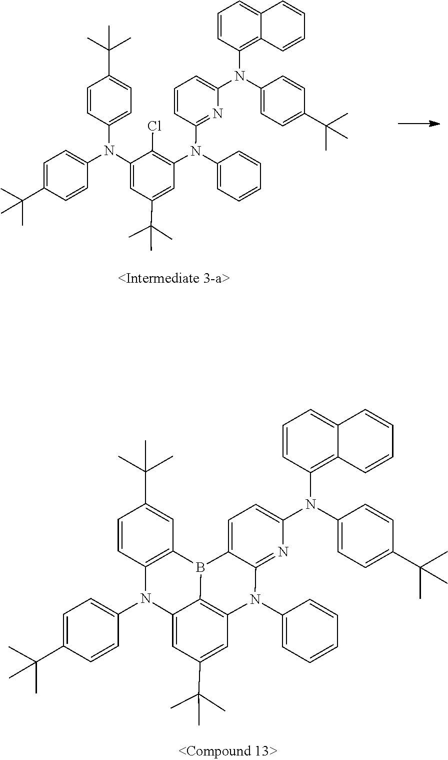

The same procedure as in Synthesis Example 1-(8) was carried out, with the exception of using Intermediate 3-a instead of Intermediate 1-g to afford <Compound 13>. (yield 13%) (MS:863.01)

### Synthesis Example 4: Synthesis of Compound 22

### Synthesis Example 4-(1): Synthesis of Intermediate 4-a

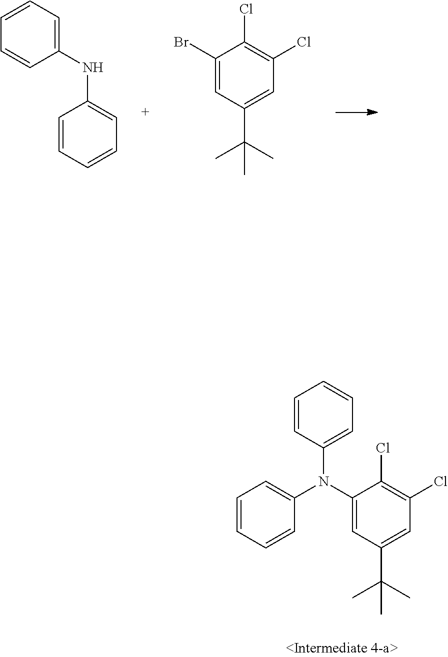 [SMILES: c1ccc(Nc2ccccc2)cc1 ; CC(C)(C)c1cc(Cl)c(Cl)c(Br)c1 ; CC(C)(C)c1cc(Cl)c(Cl)c(N(c2ccccc2)c2ccccc2)c1]

The same procedure as in Synthesis Example 2-(1) was carried out, with the exception of using diphenylamine instead of bis(4-tert-butylphenyl)amine to afford <Intermediate 4-a>. (yield 64%)

### Synthesis Example 4-(2): Synthesis of Intermediate 4-b

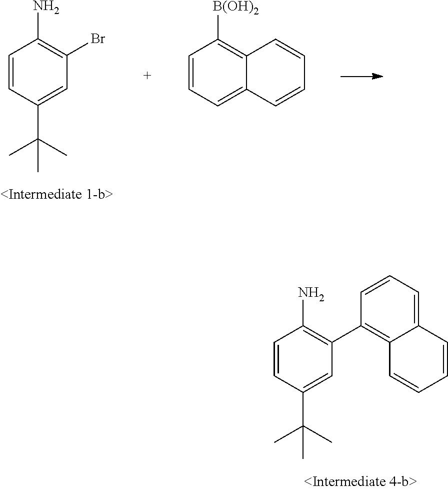 [SMILES: CC(C)(C)c1ccc(N)c(Br)c1 ; OB(O)c1cccc2ccccc12 ; CC(C)(C)c1ccc(N)c(-c2cccc3ccccc23)c1]

The same procedure as in Synthesis Example 1-(3) was carried out, with the exception of using 1-naphthalene boronic acid instead of phenyl boronic acid to afford <Intermediate 4-b>. (yield 66%) Synthesis Example 4-(3): Synthesis of Intermediate 4-c

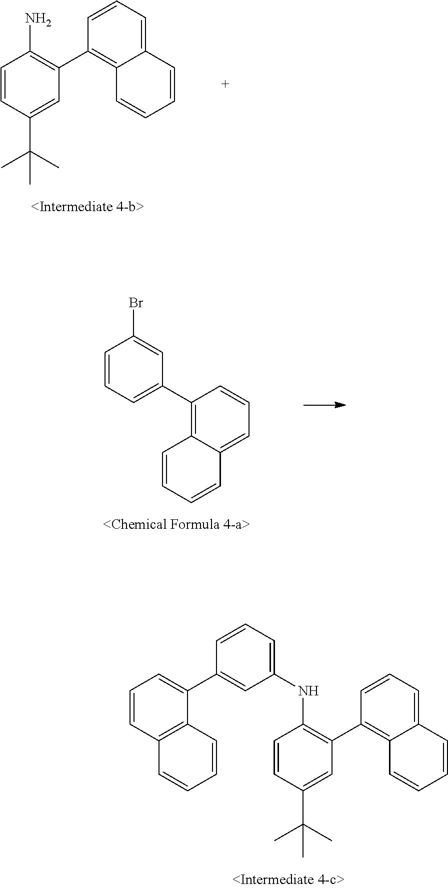 [SMILES: CC(C)(C)c1ccc(N)c(-c2cccc3ccccc23)c1 ; Brc1cccc(-c2cccc3ccccc23)c1 ; CC(C)(C)c1ccc(Nc2cccc(-c3cccc4ccccc34)c2)c(-c2cccc3ccccc23)c1]

The same procedure as in Synthesis Example 1-(4) was carried out, with the exception of using <Intermediate 4-b> and the compound of Chemical Formula 4-a instead of Intermediate 1-c and 1-bromo-4-tert-butylbenzene, respectively, to afford <Intermediate 4-c>. (yield 65%) Synthesis Example 4-(4): Synthesis of Intermediate 4-d

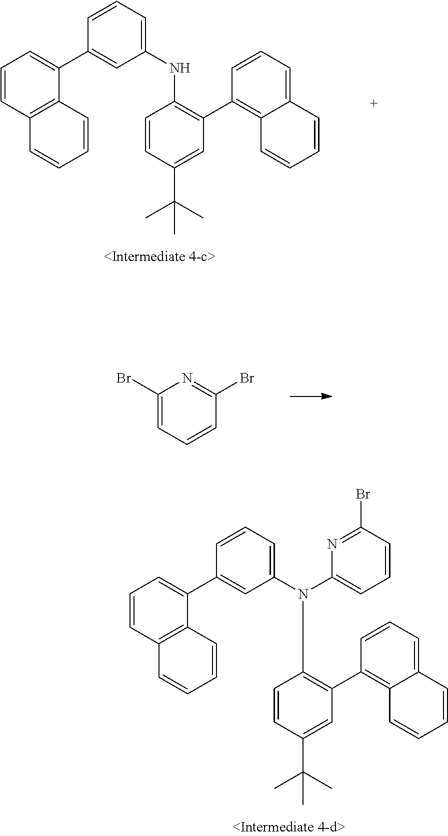 [SMILES: CC(C)(C)c1ccc(Nc2cccc(-c3cccc4ccccc34)c2)c(-c2cccc3ccccc23)c1 ; Brc1cccc(Br)n1 ; CC(C)(C)c1ccc(N(c2cccc(-c3cccc4ccccc34)c2)c2cccc(Br)n2)c(-c2cccc3ccccc23)c1]

The same procedure as in Synthesis Example 1-(5) was carried out, with the exception of using Intermediate 4-c instead of Intermediate 1-d to afford <Intermediate 4-d>. (yield 34%)

### Synthesis Example 4-(5): Synthesis of Intermediate 4-e

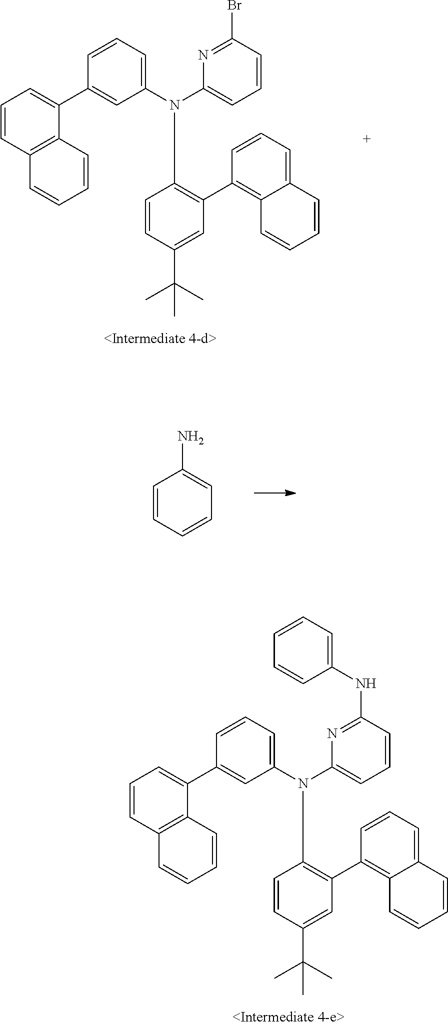 [SMILES: CC(C)(C)c1ccc(N(c2cccc(-c3cccc4ccccc34)c2)c2cccc(Br)n2)c(-c2cccc3ccccc23)c1 ; Nc1ccccc1 ; CC(C)(C)c1ccc(N(c2cccc(-c3cccc4ccccc34)c2)c2cccc(Nc3ccccc3)n2)c(-c2cccc3ccccc23)c1]

The same procedure as in Synthesis Example 1-(6) was carried out, with the exception of using Intermediate 4-d instead of Intermediate 1-e to afford <Intermediate 4-e>. (yield 63%)

### Synthesis Example 4-(6): Synthesis of Intermediate 4-f

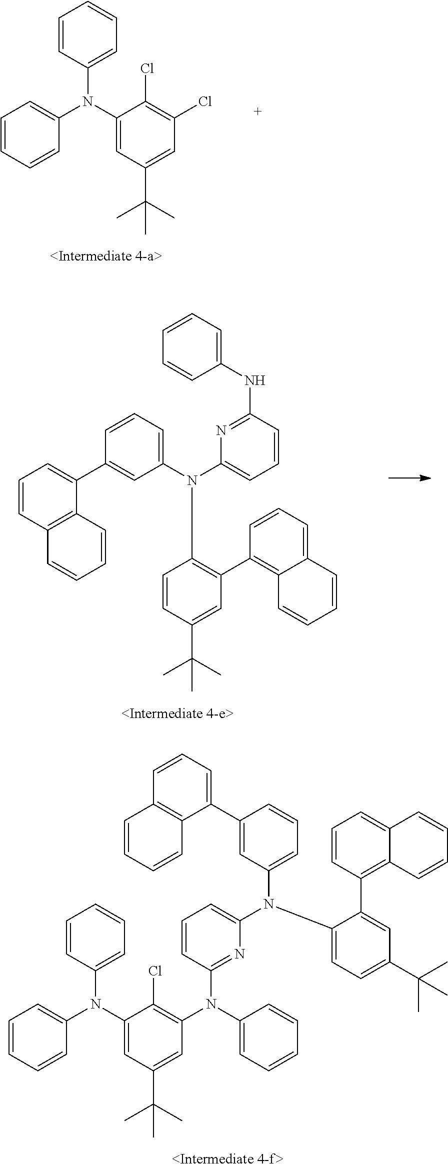 [SMILES: CC(C)(C)c1cc(Cl)c(Cl)c(N(c2ccccc2)c2ccccc2)c1 ; CC(C)(C)c1ccc(N(c2cccc(-c3cccc4ccccc34)c2)c2cccc(Nc3ccccc3)n2)c(-c2cccc3ccccc23)c1 ; CC(C)(C)c1ccc(N(c2cccc(-c3cccc4ccccc34)c2)c2cccc(N(c3ccccc3)c3cc(C(C)(C)C)cc(N(c4ccccc4)c4ccccc4)c3Cl)n2)c(-c2cccc3ccccc23)c1]

The same procedure as in Synthesis Example 1-(7) was carried out, with the exception of using Intermediate 4-e instead of Intermediate 1-e to afford <Intermediate 4-f>. (yield 57%)

### Synthesis Example 4-(7): Synthesis of Compound 22

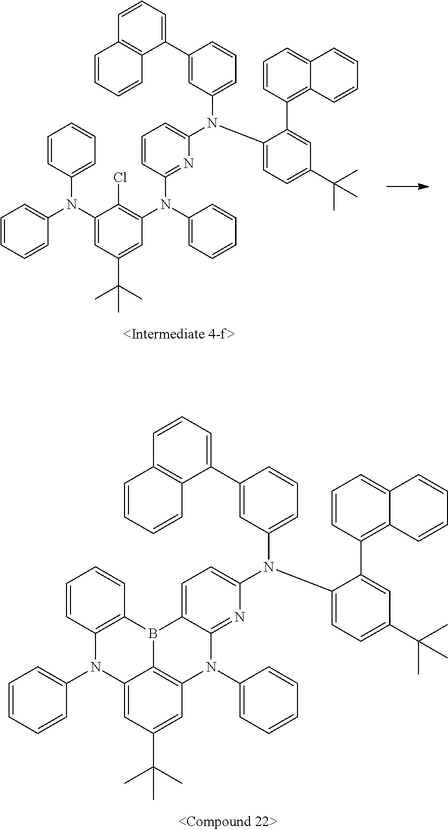 [SMILES: CC(C)(C)c1ccc(N(c2cccc(-c3cccc4ccccc34)c2)c2cccc(N(c3ccccc3)c3cc(C(C)(C)C)cc(N(c4ccccc4)c4ccccc4)c3Cl)n2)c(-c2cccc3ccccc23)c1 ; CC(C)(C)c1ccc(N(c2cccc(-c3cccc4ccccc34)c2)c2ccc3c(n2)N(c2ccccc2)c2cc(C(C)(C)C)cc4c2B3c2ccccc2N4c2ccccc2)c(-c2cccc3ccccc23)c1]

The same procedure as in Synthesis Example 1-(8) was carried out, with the exception of using Intermediate 4-f instead of Intermediate 1-g to afford <Compound 22>. (yield 11%) (MS:953.05)

### Synthesis Example 5: Synthesis of Compound 49

### Synthesis Example 5-(1): Synthesis of Intermediate 5-a

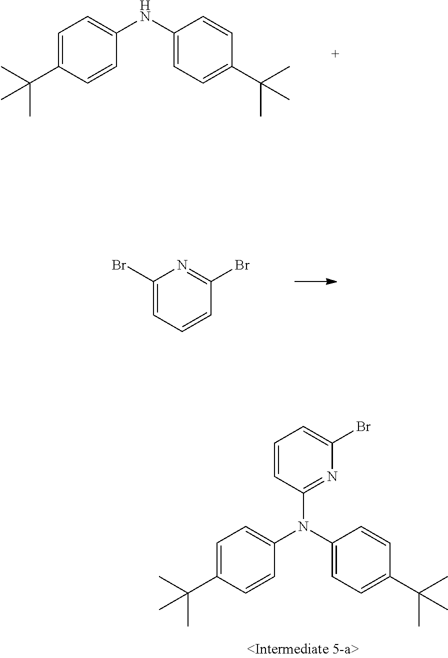

The same procedure as in Synthesis Example 1-(5) was carried out, with the exception of using bis(4-tert-butylphenyl)amine instead of Intermediate 1-d to afford <Intermediate 5-a>. (yield 31%) Synthesis Example 5-(2): Synthesis of Intermediate 5-b

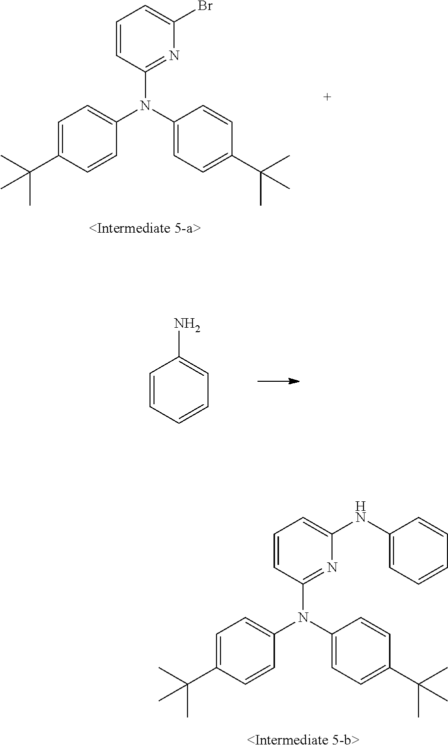

The same procedure as in Synthesis Example 1-(6) was carried out, with the exception of using Intermediate 5-a instead of Intermediate 1-e to afford <Intermediate 5-b>. (yield 60%)

### Synthesis Example 5-(3): Synthesis of Intermediate 5-c

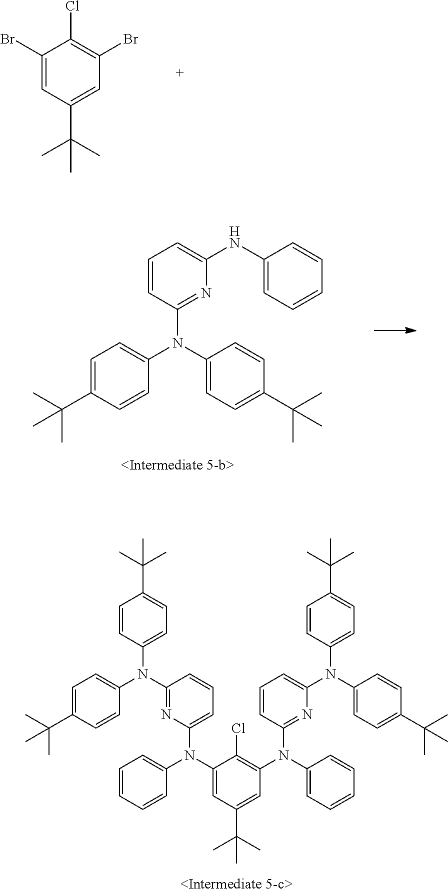 [SMILES: CC(C)(C)c1cc(Br)c(Cl)c(Br)c1 ; CC(C)(C)c1ccc(N(c2ccc(C(C)(C)C)cc2)c2cccc(Nc3ccccc3)n2)cc1 ; CC(C)(C)c1ccc(N(c2ccc(C(C)(C)C)cc2)c2cccc(N(c3ccccc3)c3cc(C(C)(C)C)cc(N(c4ccccc4)c4cccc(N(c5ccc(C(C)(C)C)cc5)c5ccc(C(C)(C)C)cc5)n4)c3Cl)n2)cc1]

In a round-bottom flask, 1,3-dibromo-5-tert-butyl-2-chlorobenzene (10 g, 30.6 mmol), <Intermediate 5-b> (30.3 g, 67.4 mmol), tris (dibenzilideneacetaone)dipalladium (0.6 g, 0.6 mmol), sodium tert-butoxide (8.8 g, 91.9 mmol), tri-tert-butylphosphine (0.3 g, 1.2 mmol), and toluene (300 ml) were stirred together under reflux for 12 hours. After completion of the reaction, the reaction mixture was split into layers. The organic layer thus obtained was concentrated in a vacuum, separated with a column, and dried to afford Intermediate 5-c (40.9 g, yield 57%).

### Synthesis Example 5-(4): Synthesis of Compound 49

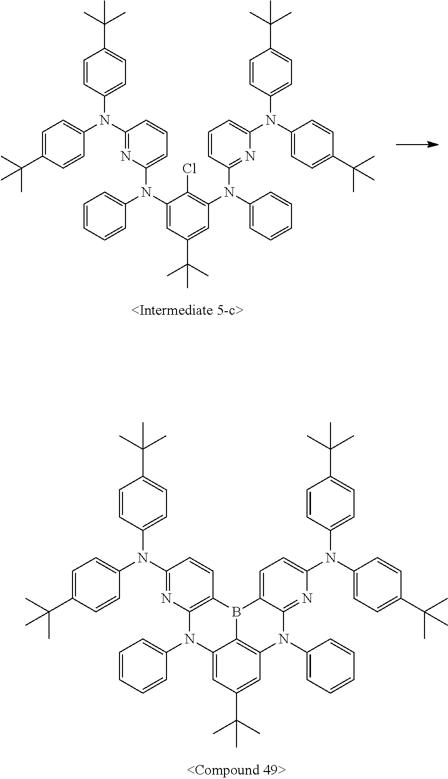

The same procedure as in Synthesis Example 1-(8) was carried out, with the exception of using Intermediate 5-c instead of Intermediate 1-g to afford <Compound 49>. (yield 12%) (MS:1037.26)

### Synthesis Example 6: Synthesis of Compound 61

### Synthesis Example 6-(1): Synthesis of Intermediate 6-a

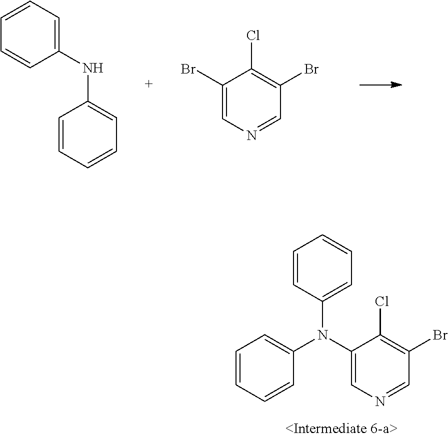 [SMILES: c1ccc(Nc2ccccc2)cc1 ; Clc1c(Br)cncc1Br ; Clc1c(Br)cncc1N(c1ccccc1)c1ccccc1]

The same procedure as in Synthesis Example 4-(1) was carried out, with the exception of using 3,5-dibromo-4-chloropyridine instead of 1-bromo-2,3-dichloro-5-tert-butylbenzene to afford <Intermediate 6-a>. (yield 43%)

### Synthesis Example 6-(2): Synthesis of Intermediate 6-b

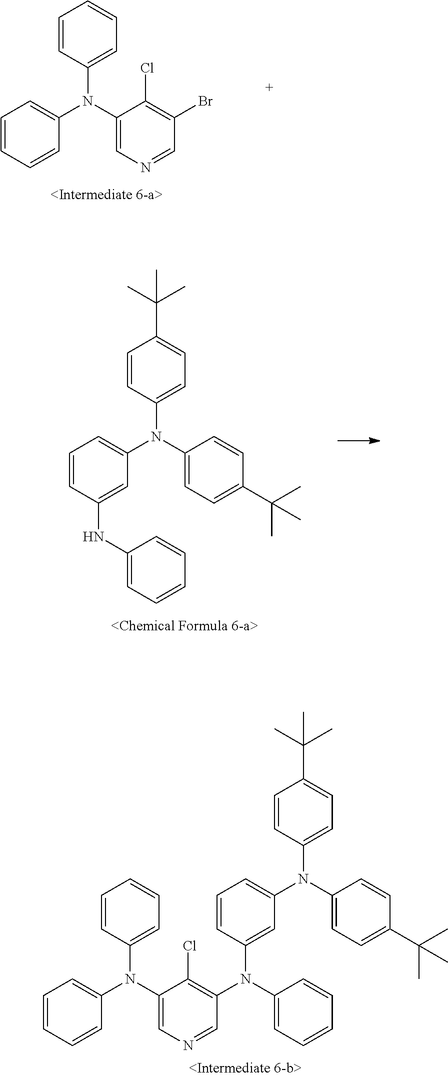 [SMILES: Clc1c(Br)cncc1N(c1ccccc1)c1ccccc1 ; CC(C)(C)c1ccc(N(c2ccc(C(C)(C)C)cc2)c2cccc(Nc3ccccc3)c2)cc1 ; CC(C)(C)c1ccc(N(c2ccc(C(C)(C)C)cc2)c2cccc(N(c3ccccc3)c3cncc(N(c4ccccc4)c4ccccc4)c3Cl)c2)cc1]

The same procedure as in Synthesis Example 1-(7) was carried out, with the exception of using Intermediate 6-a and the compound of Chemical Formula 6-a instead of Intermediate 1-a and Intermediate 1-f, respectively, to afford <Intermediate 6-b>. (yield 62%)

### Synthesis Example 6-(3): Synthesis of Compound 61

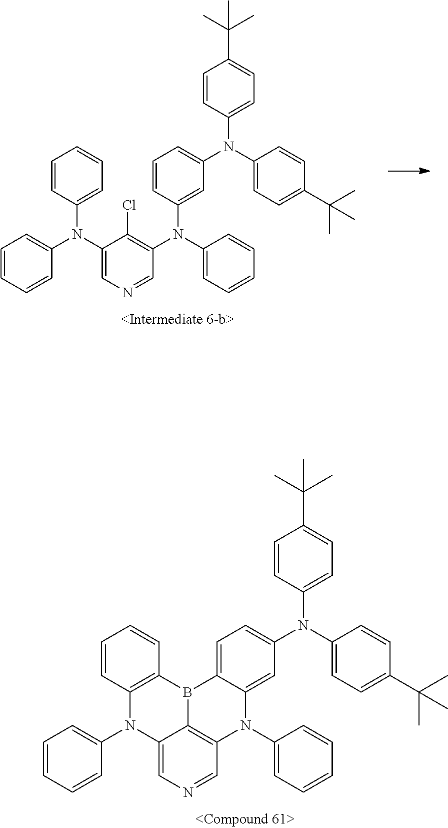 [SMILES: CC(C)(C)c1ccc(N(c2ccc(C(C)(C)C)cc2)c2cccc(N(c3ccccc3)c3cncc(N(c4ccccc4)c4ccccc4)c3Cl)c2)cc1 ; CC(C)(C)c1ccc(N(c2ccc(C(C)(C)C)cc2)c2ccc3c(c2)N(c2ccccc2)c2cncc4c2B3c2ccccc2N4c2ccccc2)cc1]

The same procedure as in Synthesis Example 1-(8) was carried out, with the exception of using Intermediate 6-b instead of Intermediate 1-g to afford <Compound 61>. (yield 11%) (MS:700.74)

### Synthesis Example 7: Synthesis of Compound 82

### Synthesis Example 7-(1): Synthesis of Intermediate 7-a

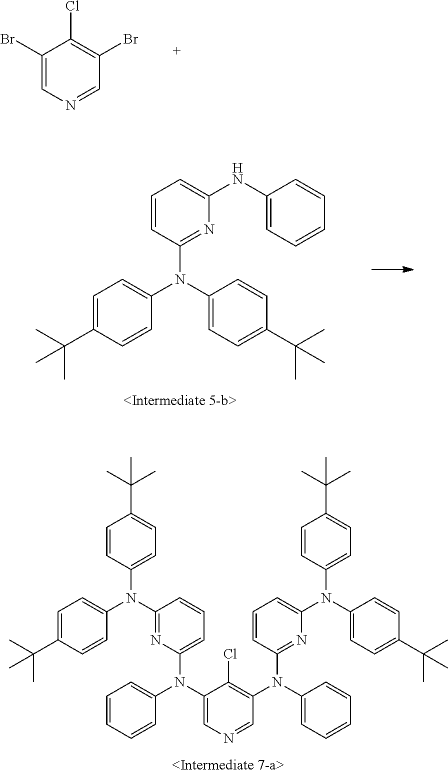

The same procedure as in Synthesis Example 5-(3) was carried out, with the exception of using 3,5-dibromo-4-chloropyridine instead of 1,3-dibromo-5-tert-butyl-2-chlorobenzene to afford <Intermediate 7-a>. (yield 45%)

### Synthesis Example 7-(2): Synthesis of Compound 82

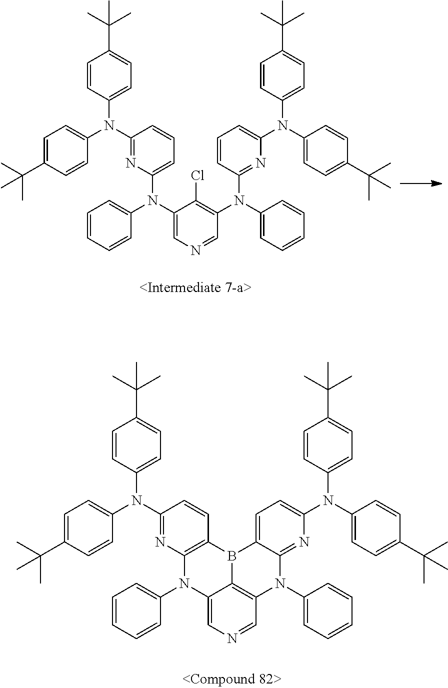

The same procedure as in Synthesis Example 1-(8) was carried out, with the exception of using Intermediate 7-a instead of Intermediate 1-g to afford <Compound 82>. (yield 10%) (MS:982.14)

### Synthesis Example 8: Synthesis of Compound 106

### Synthesis Example 8-(1): Synthesis of Intermediate 8-a

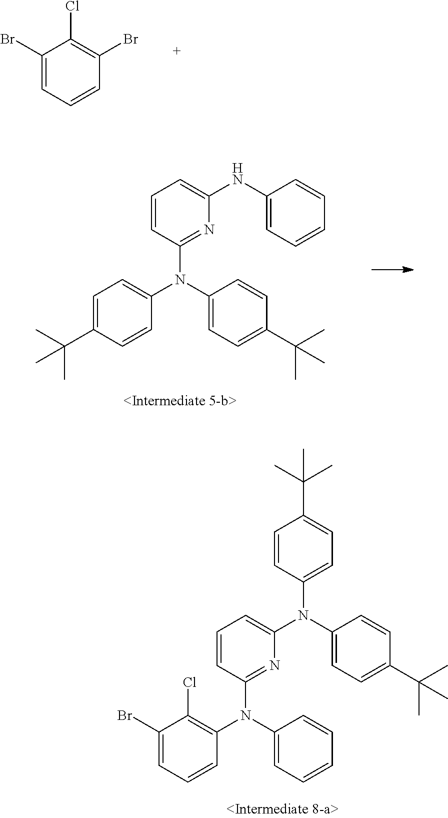 [SMILES: Clc1c(Br)cccc1Br ; CC(C)(C)c1ccc(N(c2ccc(C(C)(C)C)cc2)c2cccc(Nc3ccccc3)n2)cc1 ; CC(C)(C)c1ccc(N(c2ccc(C(C)(C)C)cc2)c2cccc(N(c3ccccc3)c3cccc(Br)c3Cl)n2)cc1]

The same procedure as in Synthesis Example 1-(4) was carried out, with the exception of using Intermediate 5-b and 1,3-dibromo-2-chlorobenzene instead of Intermediate 1-c and 1-bromo-4-tert-butylbenzene, respectively, to afford <Intermediate 8-a>. (yield 56%) Synthesis Example 8-(2): Synthesis of Intermediate 8-b

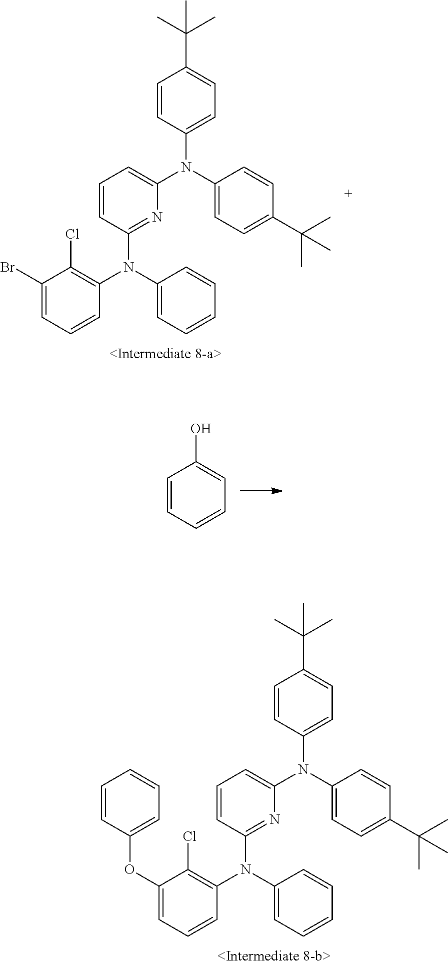 [SMILES: CC(C)(C)c1ccc(N(c2ccc(C(C)(C)C)cc2)c2cccc(N(c3ccccc3)c3cccc(Br)c3Cl)n2)cc1 ; Oc1ccccc1 ; CC(C)(C)c1ccc(N(c2ccc(C(C)(C)C)cc2)c2cccc(N(c3ccccc3)c3cccc(Oc4ccccc4)c3Cl)n2)cc1]

In a round-bottom flask, <Intermediate 8-a> (30 g, 47 mmol), phenol (4.4 g, 47 mmol), potassium carbonate (9.7 g, 70 mmol), copper iodide (0.18 g, 0.94 mmol), and N,N-dimethyl formamide (300 ml) were stirred together under reflux for 24 hours. After completion of the reaction, the reaction mixture was split into layers. The organic layer thus obtained was concentrated in a vacuum, separated with a column, and dried to afford Intermediate 8-b (13.8 g, yield 43%).

### Synthesis Example 8-(3): Synthesis of Compound 106

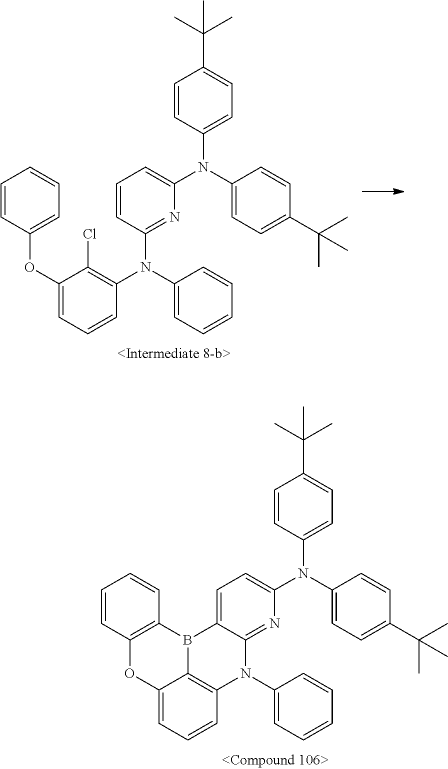 [SMILES: CC(C)(C)c1ccc(N(c2ccc(C(C)(C)C)cc2)c2cccc(N(c3ccccc3)c3cccc(Oc4ccccc4)c3Cl)n2)cc1 ; CC(C)(C)c1ccc(N(c2ccc(C(C)(C)C)cc2)c2ccc3c(n2)N(c2ccccc2)c2cccc4c2B3c2ccccc2O4)cc1]

The same procedure as in Synthesis Example 1-(8) was carried out, with the exception of using Intermediate 8-b instead of Intermediate 1-g to afford <Compound 106>. (yield 9%) (MS:625.62)

### Synthesis Example 9: Synthesis of Compound 163

### Synthesis Example 9-(1): Synthesis of Intermediate 9-a

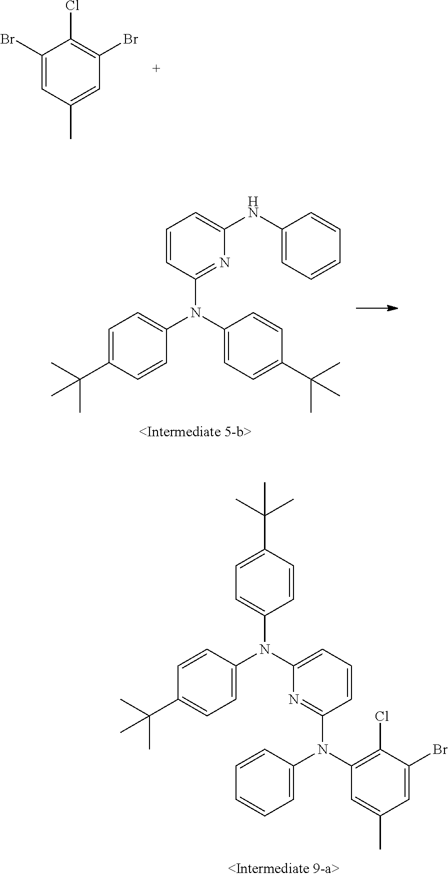

The same procedure as in Synthesis Example 1-(4) was carried out, with the exception of using Intermediate 5-b and 1,3-dibromo-2-chloro-5-methylbenzene instead of Intermediate 1-c and 1-bromo-4-tert-butylbenzene, respectively, to afford <Intermediate 9-a>. (yield 58%)

### Synthesis Example 9-(2): Synthesis of Intermediate 9-b

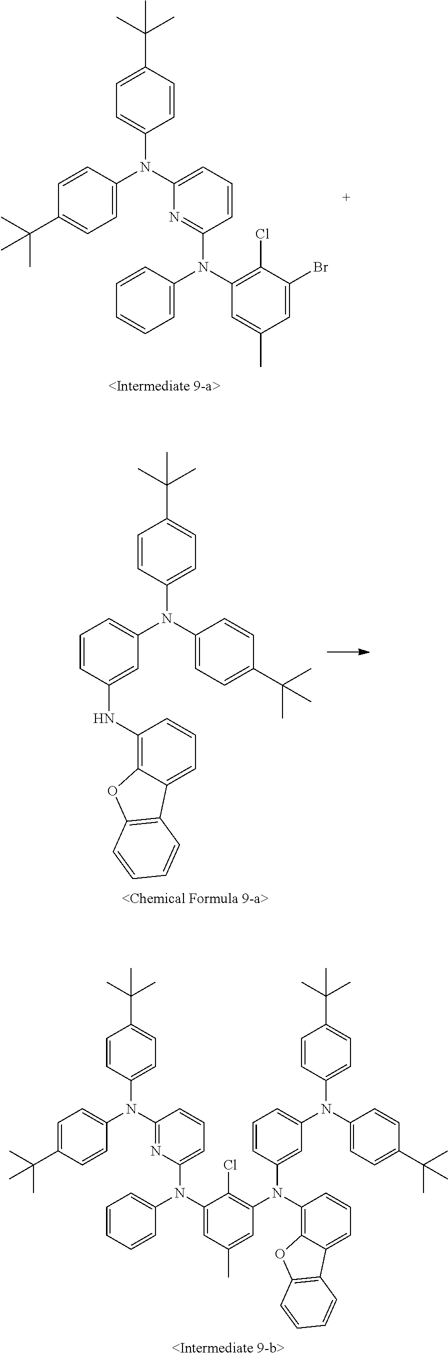 [SMILES: Cc1cc(Br)c(Cl)c(N(c2ccccc2)c2cccc(N(c3ccc(C(C)(C)C)cc3)c3ccc(C(C)(C)C)cc3)n2)c1 ; CC(C)(C)c1ccc(N(c2ccc(C(C)(C)C)cc2)c2cccc(Nc3cccc4c3oc3ccccc34)c2)cc1 ; Cc1cc(N(c2ccccc2)c2cccc(N(c3ccc(C(C)(C)C)cc3)c3ccc(C(C)(C)C)cc3)n2)c(Cl)c(N(c2cccc(N(c3ccc(C(C)(C)C)cc3)c3ccc(C(C)(C)C)cc3)c2)c2cccc3c2oc2ccccc23)c1]

The same procedure as in Synthesis Example 1-(4) was carried out, with the exception of using the compound of Chemical Formula 9-a and Intermediate 9-a instead of Intermediate 1-c and 1-bromo-4-tert-butylbenzene, respectively, to afford <Intermediate 9-b>. (yield 47%)

### Synthesis Example 9-(3): Synthesis of Compound 163

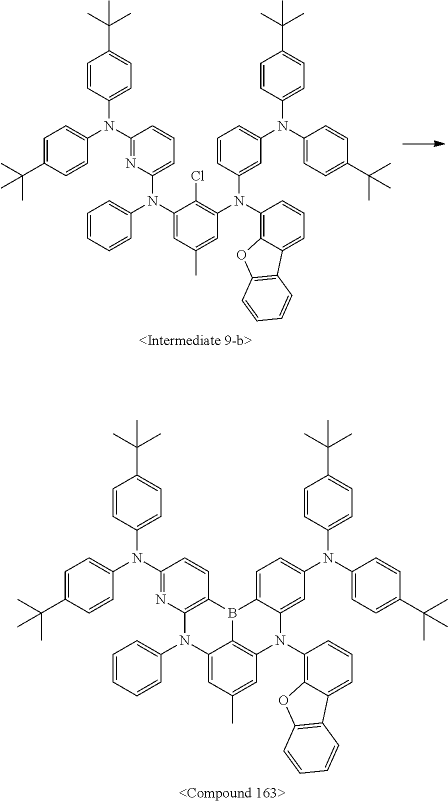

The same procedure as in Synthesis Example 1-(8) was carried out, with the exception of using Intermediate 9-b instead of Intermediate 1-g to afford <Compound 163>. (yield 7%) (MS:1084.27)

### Synthesis Example 10: Synthesis of Compound 164

### Synthesis Example 10-(1): Synthesis of Intermediate 10-a

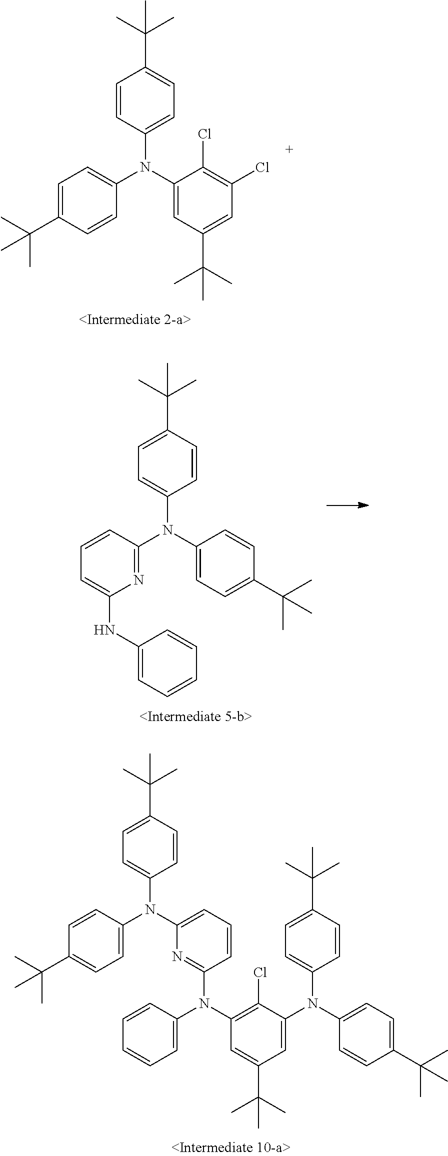 [SMILES: CC(C)(C)c1ccc(N(c2ccc(C(C)(C)C)cc2)c2cc(C(C)(C)C)cc(Cl)c2Cl)cc1 ; CC(C)(C)c1ccc(N(c2ccc(C(C)(C)C)cc2)c2cccc(Nc3ccccc3)n2)cc1 ; CC(C)(C)c1ccc(N(c2ccc(C(C)(C)C)cc2)c2cccc(N(c3ccccc3)c3cc(C(C)(C)C)cc(N(c4ccc(C(C)(C)C)cc4)c4ccc(C(C)(C)C)cc4)c3Cl)n2)cc1]

The same procedure as in Synthesis Example 1-(7) was carried out, with the exception of using Intermediate 2-a and Intermediate 5-b instead of Intermediate 1-a and Intermediate 1-f, respectively, to afford <Intermediate 10-a>. (yield 57%)

### Synthesis Example 10-(2): Synthesis of Compound 164

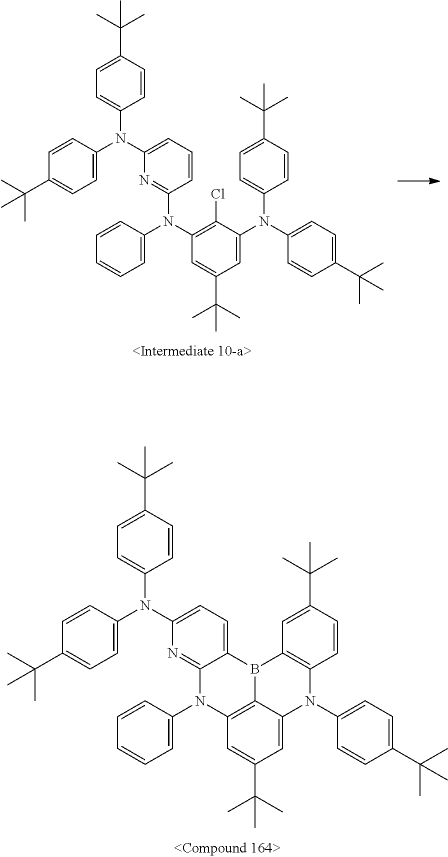

The same procedure as in Synthesis Example 1-(8) was carried out, with the exception of using Intermediate 10-a instead of Intermediate 1-g to afford <Compound 164>. (yield 7%) (MS:869.06)

### Synthesis Example 11: Synthesis of Compound 165

### Synthesis Example 11-(1): Synthesis of Intermediate 11-a

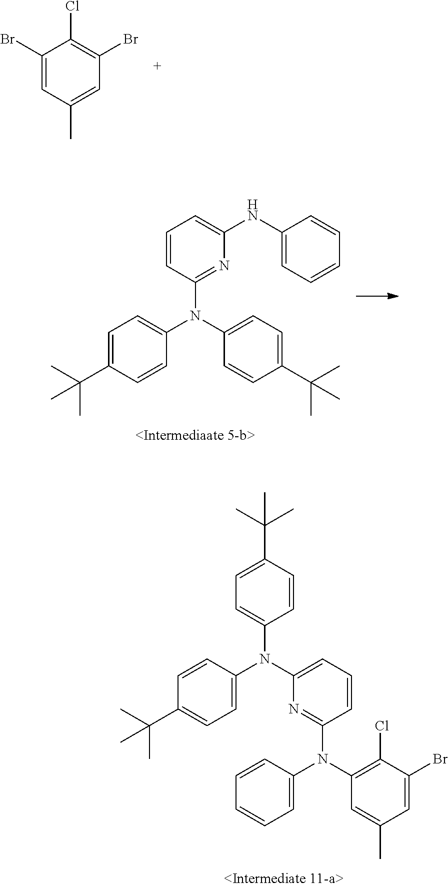

The same procedure as in Synthesis Example 1-(4) was carried out, with the exception of using Intermediate 5-b and 1,3-dibromo-2-chloro-5-methylbenzene instead of Intermediate 1-c and 1-bromo-4-tert-butylbenzene, respectively, to afford <Intermediate 11-a>. (yield 58%)

### Synthesis Example 11-(2): Synthesis of Intermediate 11-b

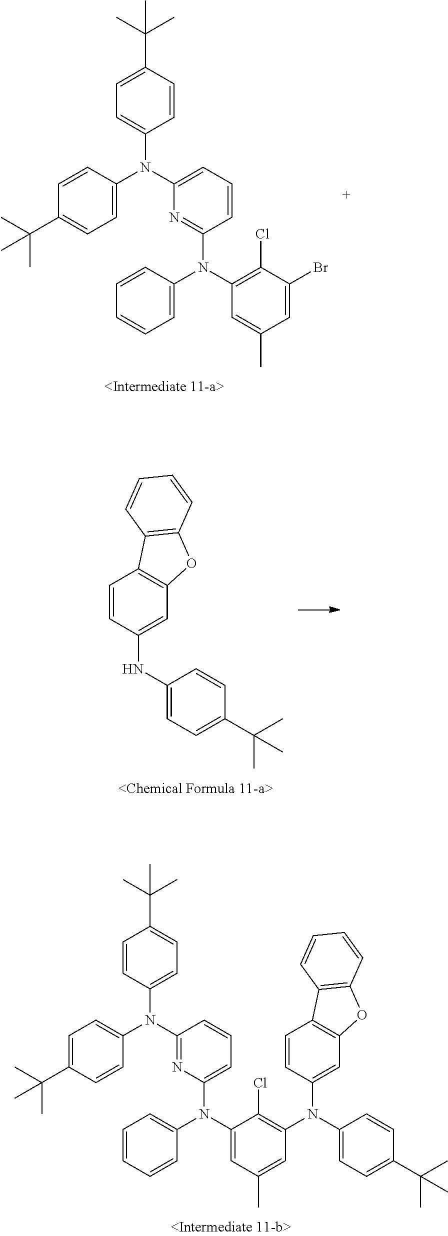 [SMILES: Cc1cc(Br)c(Cl)c(N(c2ccccc2)c2cccc(N(c3ccc(C(C)(C)C)cc3)c3ccc(C(C)(C)C)cc3)n2)c1 ; CC(C)(C)c1ccc(Nc2ccc3c(c2)oc2ccccc23)cc1 ; Cc1cc(N(c2ccc(C(C)(C)C)cc2)c2ccc3c(c2)oc2ccccc23)c(Cl)c(N(c2ccccc2)c2cccc(N(c3ccc(C(C)(C)C)cc3)c3ccc(C(C)(C)C)cc3)n2)c1]

The same procedure as in Synthesis Example 1-(4) was carried out, with the exception of using Chemical Formula 11-a and Intermediate 11-a instead of Intermediate 1-c and 1-bromo-4-tert-butylbenzene, respectively, to afford <Intermediate 11-b>. (yield 45%)

### Synthesis Example 11-(3): Synthesis of Compound 165

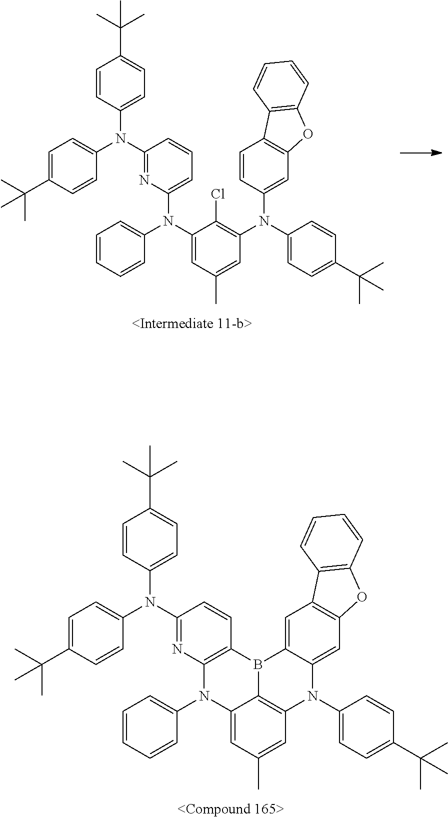

The same procedure as in Synthesis Example 1-(8) was carried out, with the exception of using Intermediate 11-b instead of Intermediate 1-g to afford <Compound 165>. (yield 11%) (MS:860.95)

### Synthesis Example 12: Synthesis of Compound 166

### Synthesis Example 12-(1): Synthesis of Intermediate 12-a

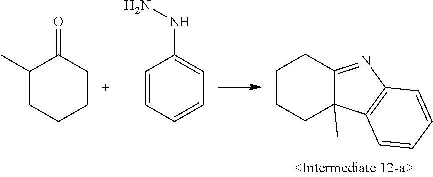

In a round-bottom flask, phenylhydrazine (100 g, 0.924 mol) was stirred together with acetic acid (500 ml) and then the mixture was heated to 60° C. and stirred under reflux while 2-methyl cyclohexanone (103.6 g, 0.924 mol) was dropwise added slowly over 8 hours. After completion of the reaction, extraction and concentration was made with water and ethyl acetate. The concentrate was isolated by column chromatography to afford <Intermediate 12-a> (130 g, 76%)

### Synthesis Example 12-(2): Synthesis of Intermediate 12-b

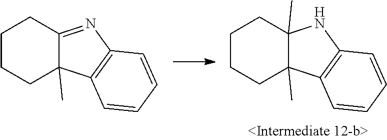

In a round-bottom flask containing toluene (750 ml), 1.6M methyl lithium (380 ml, 608 mmol) chilled to −10° C. was dropwise added slowly to Intermediate 12-a (75 g, 405 mmol) under a nitrogen atmosphere and stirred at −10° C. for 3 hours. After completion of the reaction, extraction and concentration was made with water and ethyl acetate. The concentrate was isolated by column chromatography to afford <Intermediate 12-b> (50.5 g, yield 62%).

### Synthesis Example 12-(3): Synthesis of Intermediate 12-c

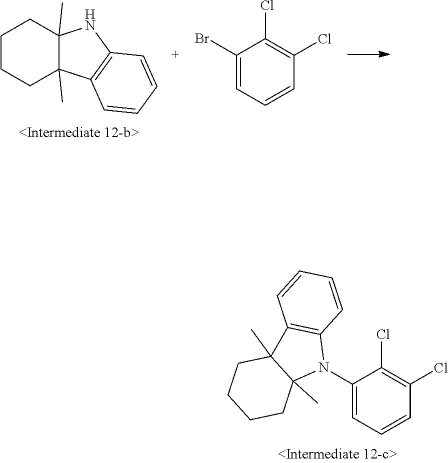 [SMILES: CC12CCCCC1(C)c1ccccc1N2 ; Clc1cccc(Br)c1Cl ; CC12CCCCC1(C)N(c1cccc(Cl)c1Cl)c1ccccc12]

In a round-bottom flask, <Intermediate 12-b> (50 g, 251 mmol) 1-bromo-2,3-dichlorobenzene (56.7 g, 251 mmol), tris-dibenzylideneacetone dipalladium (4.5 g, 5 mmol), tri-tert-butyl phosphine (2 g, 10 mmol), sodium tert-butoxide (35.8 g, 373 mmol), and toluene (500 ml) were stirred under a nitrogen atmosphere under reflux for 24 hours. After completion of the reaction, the organic layer was concentrated in a vacuum and isolated by to afford <Intermediate 12-c> (35.6 g, yield 41%).

### Synthesis Example 12-(4) Synthesis of Intermediate 12-d

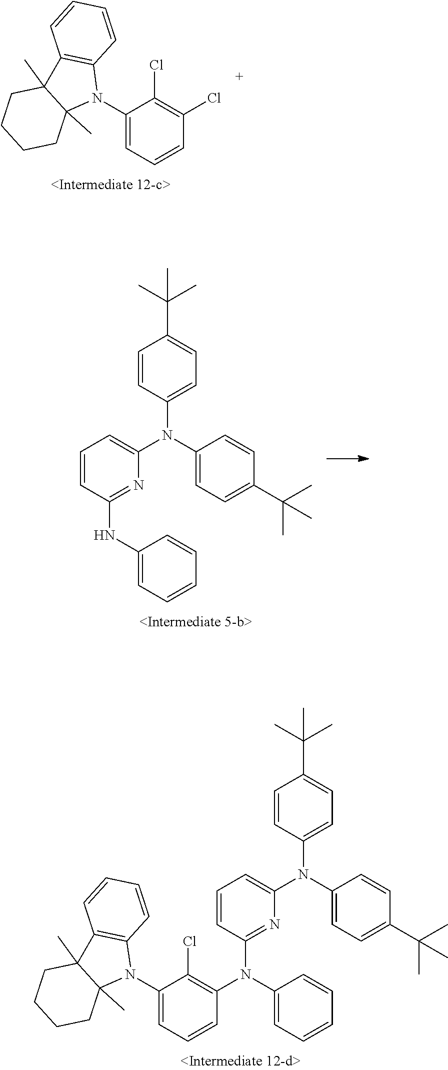 [SMILES: CC12CCCCC1(C)N(c1cccc(Cl)c1Cl)c1ccccc12 ; CC(C)(C)c1ccc(N(c2ccc(C(C)(C)C)cc2)c2cccc(Nc3ccccc3)n2)cc1 ; CC(C)(C)c1ccc(N(c2ccc(C(C)(C)C)cc2)c2cccc(N(c3ccccc3)c3cccc(N4c5ccccc5C5(C)CCCCC45C)c3Cl)n2)cc1]

The same procedure as in Synthesis Example 1-(4) was carried out, with the exception of using Intermediate 5-b and Intermediate 12-c instead of Intermediate 1-c and 1-bromo-4-tert-butylbenzene, respectively, to afford <Intermediate 12-d>. (yield 55%) Synthesis Example 12-(5): Synthesis of Compound 166

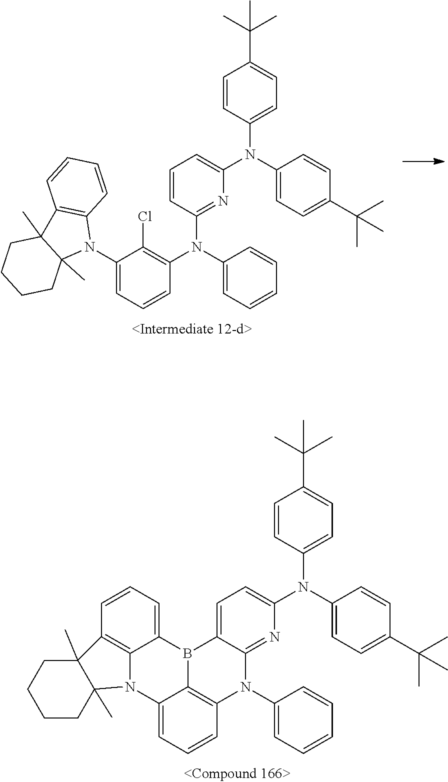 [SMILES: CC(C)(C)c1ccc(N(c2ccc(C(C)(C)C)cc2)c2cccc(N(c3ccccc3)c3cccc(N4c5ccccc5C5(C)CCCCC45C)c3Cl)n2)cc1 ; CC(C)(C)c1ccc(N(c2ccc(C(C)(C)C)cc2)c2ccc3c(n2)N(c2ccccc2)c2cccc4c2B3c2cccc3c2N4C2(C)CCCCC32C)cc1]

The same procedure as in Synthesis Example 1-(8) was carried out, with the exception of using Intermediate 12-d instead of Intermediate 1-g to afford <Compound 166>. (yield 9%) (MS:732.82)

### Examples 1-12: Fabrication of Organic Light-Emitting Diodes

An ITO glass substrate was patterned to have a translucent area of 2 mm×2 mm and cleansed. The ITO glass was mounted in a vacuum chamber that was then set to have a base pressure of 1×10⁻⁷ torr. On the ITO glass substrate, films were sequentially formed of DNTPD (700 Å) and α-NPD (300 Å). Subsequently, a light-emitting layer (250 Å) was formed of a combination of the host (BH1) and the compound (3 wt %) of the present disclosure. Then, [Chemical Formula E-1] and [Chemical Formula E-2] was deposited at a weight ratio of 1:1 to form an electron transport layer (300 Å) on which an electron injection layer of [Chemical Formula E-1](5 Å) was formed and then covered with an Al layer (1000 Å) to fabricate an organic light-emitting diode. The organic light-emitting diodes thus obtained were measured at 0.4 mA for luminescence properties:

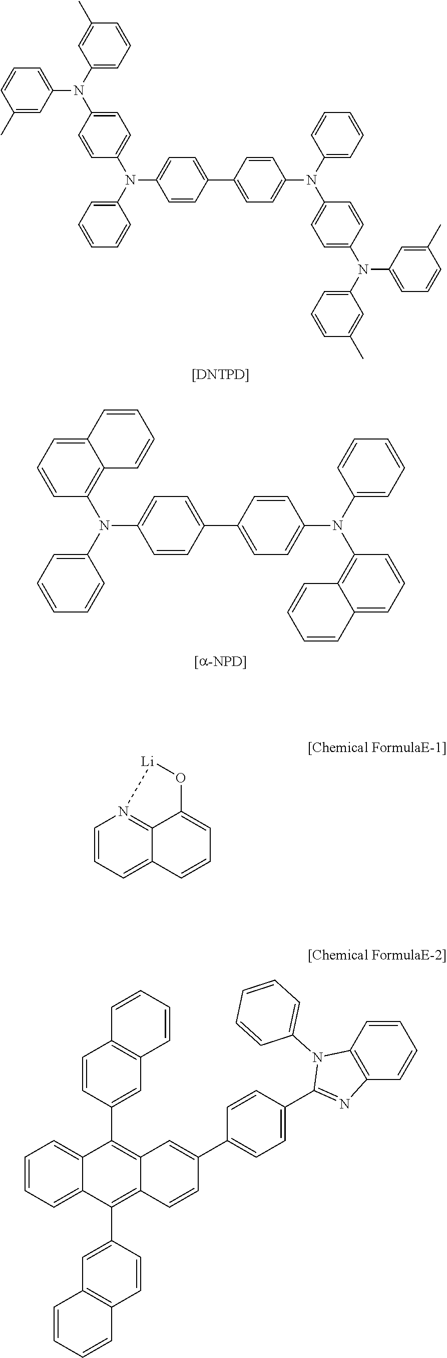

### Comparative Examples 1-3

Organic light emitting diodes were fabricated in the same manner as in the Example 1, with the exception of using [BD1] to [BD3] instead of the compounds according to the present disclosure. The luminescence of the organic light-emitting diodes thus obtained was measured at 0.4 mA. Structures of compounds [BD1] and [BH1] are as follows:

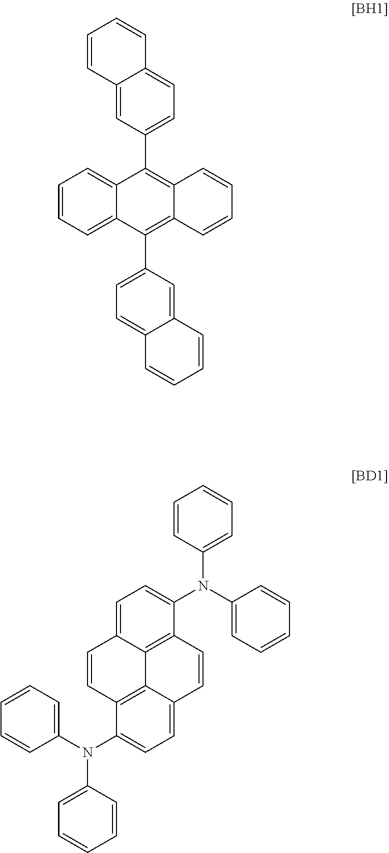

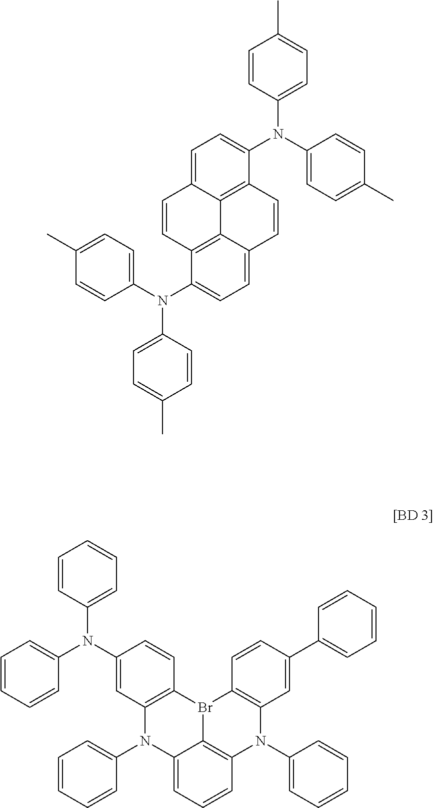

The organic light emitting diodes fabricated in Examples 1 to 12 and Comparative Examples 1 to 3 were measured for current density, driving voltage and external quantum efficiency, and the results are summarized in Table 1, below.

TABLE 1

| | | Current | | External |
|---|---|---|---|---|
| | | Density | Volt. | Quantum |
| Example # | Dopant | (mA/cm₂) | (V) | Efficiency (%) |
| 1 | Chemical Formula 4 | 10 | 3.88 | 9.0 |
| 2 | Chemical Formula 9 | 10 | 3.91 | 8.7 |
| 3 | Chemical Formula 13 | 10 | 3.92 | 8.8 |
| 4 | Chemical Formula 22 | 10 | 3.91 | 9.2 |
| 5 | Chemical Formula 49 | 10 | 3.93 | 9.1 |
| 6 | Chemical Formula 61 | 10 | 3.91 | 8.8 |
| 7 | Chemical Formula 82 | 10 | 3.92 | 9.0 |
| 8 | Chemical Formula 106 | 10 | 3.90 | 8.6 |
| 9 | Chemical Formula 163 | 10 | 3.91 | 9.5 |
| 10 | Chemical Formula 164 | 10 | 3.90 | 9.1 |
| 11 | Chemical Formula 165 | 10 | 3.89 | 9.3 |
| 12 | Chemical Formula 166 | 10 | 3.90 | 9.2 |
| C. 1 | BD1 | 10 | 4.10 | 7.3 |
| C. 2 | BD2 | 10 | 4.07 | 7.2 |
| C. 3 | BD3 | 10 | 3.93 | 7.3 |

As is understood from the data of Table 1, the organic light-emitting diodes according to Examples 1 to 12 using the boron compounds of the present disclosure exhibited higher quantum efficiencies than those according to Comparative Examples 1 to 3 and thus are industrially applicable.

It will be appreciated by those having ordinary knowledge in the art to which the present invention belongs that the present invention may be practiced in other specific forms without changing the technical spirit and essential features of the present invention. Therefore, it should be understood that the above-described embodiments are illustrative but not restrictive in all aspects.

What is claimed is:

1. A boron compound represented by the following Chemical Formula A: 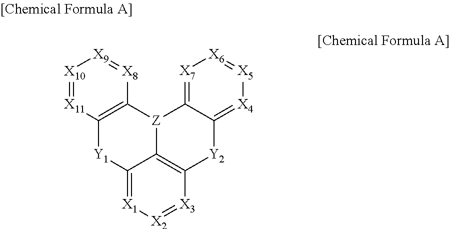
wherein,
X₁ is C—R₁ or a nitrogen atom (N),
X₂ is C—R₂ or a nitrogen atom (N),
X₃ is C—R₃ or a nitrogen atom (N),
X₄ is C—R₄ or a nitrogen atom (N),
X₅ is C—R₅ or a nitrogen atom (N),
X₆ is C—R₆ or a nitrogen atom (N),
X₇ is C—R₇ or a nitrogen atom (N),
X₈ is C—R₈ or a nitrogen atom (N),
X₉ is C—R₉ or a nitrogen atom (N),
X₁₀ is C—R₁₀ or a nitrogen atom (N),
X₁₁ is C—R₁₁ or a nitrogen atom (N),
with a proviso that only one of X₁ to X₃ is a nitrogen atom (N) such that the aromatic ring moiety bearing X₁ to X₃ is a pyridine ring, only one of X₄ to X₇ is a nitrogen atom (N) such that the aromatic ring moiety bearing X₄ to X₇ is a pyridine ring; and/or only one of X₈ to X₁₁ is a nitrogen atom (N) such that the aromatic ring moiety bearing X₈ to X₁₁ is a pyridine ring, whereby one to three pyridine rings exist in Chemical Formula A,
Z is any one selected from B, P, P═O, and P═S,
Y₁ is any one selected from CR₂₁R₂₂, NR₂₃, O, and S,
Y₂ is any one selected from CR₂₄R₂₅, NR₂₆, O, and S,
R₁ to R₁₁ and R₂₁ to R₂₆, which are same or different, are each independently any one selected from a hydrogen atom, a deuterium, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, a substituted or unsubstituted heteroaryl of 2 to 50 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted alkylsilyl of 1 to 30 carbon atoms, a substituted or unsubstituted arylsilyl of 6 to 30 carbon atoms, a nitro, a cyano, a halogen, and —N(R₂₇) (R₂₈),
R₂₇ and R₂₈, which are same or different, are each independently selected from a hydrogen atom, a deuterium atom, a substituted or unsubstituted alkyl of 1 to 30 carbon atoms, a substituted or unsubstituted aryl of 6 to 50 carbon atoms, a substituted or unsubstituted cycloalkyl of 3 to 30 carbon atoms, and a substituted or unsubstituted heteroaryl of 2 to 50 carbon atoms, and can be connected to each other to additionally form an aliphatic or aromatic mono- or polycyclic ring,
adjacent any two of R₁ to R₁₁ can be connected to each other to additionally form an aliphatic or aromatic mono- or polycyclic ring,
R₂₁ and R₂₂ can be connected to each other to additionally form an aliphatic or aromatic mono- or polycyclic ring,
R₂₄ and R₂₅ can be connected to each other to additionally form an aliphatic or aromatic mono- or polycyclic ring,
one of R₂₁ to R₂₃ can be connected to R₁ or CR₁₁ to additionally form an aliphatic or aromatic mono- or polycyclic ring, and
one of R₂₄ to R₂₆ can be connected to R₃ or R₄ to additionally form an aliphatic or aromatic mono- or polycyclic ring,
wherein, the term “substituted” in the expression “substituted or unsubstituted” used for compounds of Chemical Formula A means having at least one substituent selected from the group consisting of a deuterium atom, a cyano, a halogen, a hydroxy, a thiol, a nitro, an alkyl of 1 to 24 carbon atoms, a halogenated alkyl of 1 to 24 carbon atoms, an alkenyl of 2 to 24 carbon atoms, an alkynyl of 2 to 24 carbon atoms, a heteroalkyl of 1 to 24 carbon atoms, a cycloalkyl of 3 to 24 carbon atoms, an aryl of 6 to 24 carbon atoms, an arylalkyl of 7 to 24 carbon atoms, an alkylaryl of 7 to 24 carbon atoms, a heteroaryl of 2 to 24 carbon atoms, a heteroarylalkyl of 2 to 24 carbon atoms, an alkoxy of 1 to 24 carbon atoms, an alkylamino of 1 to 24 carbon atoms, a diarylamino of 12 to 24 carbon atoms, a diheteroarylamino of 2 to 24 carbon atoms, an aryl(heteroaryl)amino of 7 to 24 carbon atoms, an alkylsilyl of 1 to 24 carbon atoms, an arylsilyl of 6 to 24 carbon atoms, an aryloxy of 6 to 24 carbon atoms, and an arylthionyl group of 6 to 24 carbon atoms.

2. The boron compound of claim 1, wherein Y₁ is NR₂₃, or Y₂ is NR₂₆, R₂₃ and R₂₆ being as defined in claim 1.

3. The boron compound of claim 2, wherein Y₁ is NR₂₃ and Y₂ is NR₂₆.

4. The boron compound of claim 1, wherein Z is a boron atom (B).

5. The boron compound of claim 2, wherein R₂₃ and R₂₆ are same or different and each independently a substituted or unsubstituted aryl of 6 to 18 carbon atoms, or a substituted or unsubstituted heteroaryl of 2 to 18 carbon atoms.

6. The boron compound of claim 5, wherein R₂₃ and R₂₆ are same or different and each independently a substituent selected from a substituted or unsubstituted phenyl, a substituted or unsubstituted naphthylyl, a substituted or unsubstituted biphenyl, a substituted or unsubstituted anthracenyl, a substituted or unsubstituted phenanthrenyl, a substituted or unsubstituted fluorenyl, and a substituted or unsubstituted dibenzofuran.

7. The boron compound of claim 1, wherein only one of: X₁ to X₁₁ is a nitrogen atom (N) such that only one of the aromatic ring moiety bearing X₁ to X₃; the aromatic ring moiety bearing X₄ to X₇; and the aromatic ring moiety bearing X₈ to X₁₁ is a pyridine ring while the other two aromatic rings are aromatic hydrocarbon rings bearing no nitrogen atoms (N).

8. The boron compound of claim 1, wherein two of: the aromatic ring moiety bearing X₁ to X₃; the aromatic ring moiety bearing X₄ to X₇; and the aromatic ring moiety bearing X₈ to X₁₁ are each a pyridine ring while the other one aromatic ring is an aromatic hydrocarbon ring bearing no nitrogen atoms (N).

9. The boron compound of claim 1, wherein at least one of: the substituents R₁ to R₃ which each bond to an aromatic carbon atom in the aromatic ring moiety bearing X₁ to X₃; the substituents R₄ to R₇ which each bond to an aromatic carbon atom in the aromatic ring moiety bearing X₄ to X₇; and the substituents R₈ to R₁₁ which each bond to an aromatic carbon atom in the aromatic ring moiety bearing X₈ to X₁₁ is an amine represented by —N(R₂₇) (R₂₈), wherein when two of R₁ to R₁₁ each are an amine represented by —N(R₂₇) (R₂₈), the corresponding amines are same or different.

10. The boron compound of claim 9, wherein one or two of: the substituents R₁ to R₃ which each bond to an aromatic carbon atom in the aromatic ring moiety bearing X₁ to X₃; the substituents R₄ to R₇ which each bond to an aromatic carbon atom in the aromatic ring moiety bearing X₄ to X₇; and the substituents R₈ to R₁₁ which each bond to an aromatic carbon atom in the aromatic ring moiety bearing X₈ to X₁₁ each are an amine represented by —N(R₂₇) (R₂₈).

11. The boron compound of claim 10, wherein when only one of R₁ to R₁₁ is an amine substituent represented by —N(R₂₇) (R₂₈), the amine substituent is connected to the aromatic ring moiety bearing X₄ to X₇, or the aromatic ring moiety bearing X₈ to X₁₁.

12. The boron compound of claim 1, wherein the substituent —N(R₂₇) (R₂₈) is represented by the following Structural Formula A: 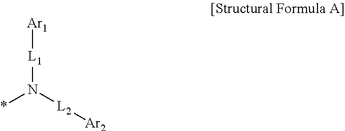
wherein,
L₁ and L₂ are same or different and each independently a single bond or a substituted or unsubstituted arylene of 6 to 18 carbon atoms,
Ar₁ and Ar₂ are same or different and each independently a substituent selected from a substituted or unsubstituted alkyl of 1 to carbon atoms a substituted or unsubstituted aryl of 6 to 18 carbon atoms, a substituted or unsubstituted cycloalkyl of 3 to 15 carbon atoms, and a substituted or unsubstituted heteroaryl of 2 to 18 carbon atoms and may be connected to each other to additionally form an aliphatic or aromatic mono- or polycyclic ring.

13. The boron compound of claim 1, wherein the compound represented by Chemical Formula A is any one selected from the following Compounds 1 to 166:

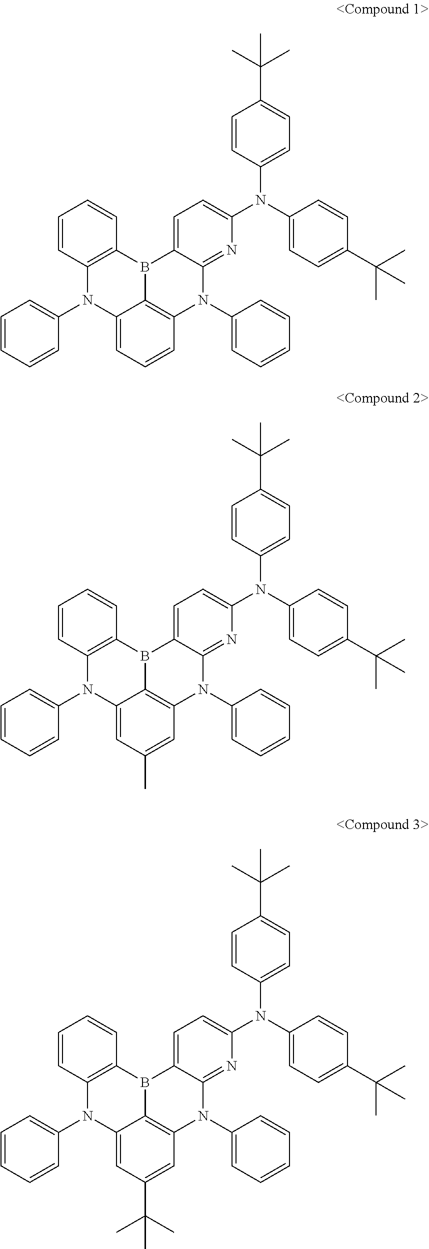 [SMILES: CC(C)(C)c1ccc(N(c2ccc(C(C)(C)C)cc2)c2ccc3c(n2)N(c2ccccc2)c2cccc4c2B3c2ccccc2N4c2ccccc2)cc1 ; Cc1cc2c3c(c1)N(c1ccccc1)c1nc(N(c4ccc(C(C)(C)C)cc4)c4ccc(C(C)(C)C)cc4)ccc1B3c1ccccc1N2c1ccccc1 ; CC(C)(C)c1ccc(N(c2ccc(C(C)(C)C)cc2)c2ccc3c(n2)N(c2ccccc2)c2cc(C(C)(C)C)cc4c2B3c2ccccc2N4c2ccccc2)cc1]

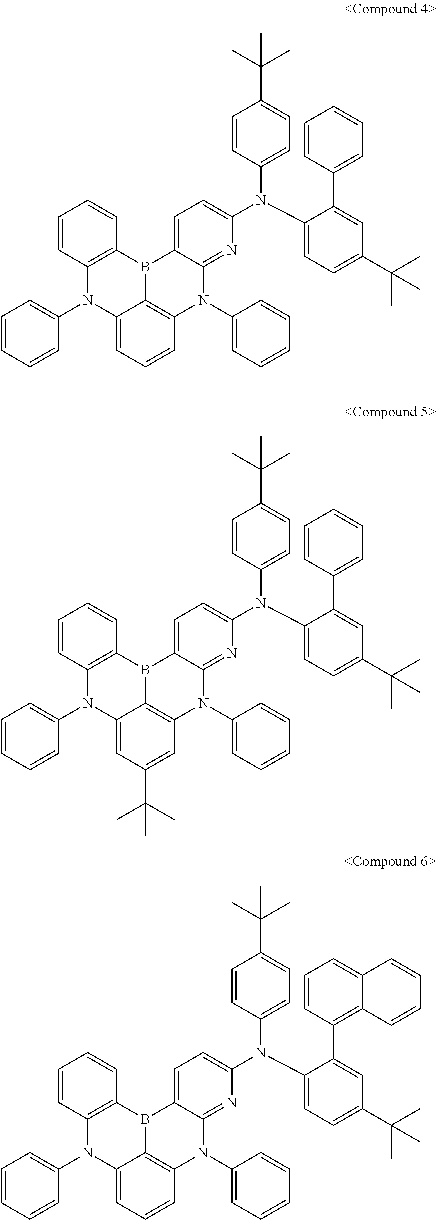 [SMILES: CC(C)(C)c1ccc(N(c2ccc3c(n2)N(c2ccccc2)c2cccc4c2B3c2ccccc2N4c2ccccc2)c2ccc(C(C)(C)C)cc2-c2ccccc2)cc1 ; CC(C)(C)c1ccc(N(c2ccc3c(n2)N(c2ccccc2)c2cc(C(C)(C)C)cc4c2B3c2ccccc2N4c2ccccc2)c2ccc(C(C)(C)C)cc2-c2ccccc2)cc1 ; CC(C)(C)c1ccc(N(c2ccc3c(n2)N(c2ccccc2)c2cccc4c2B3c2ccccc2N4c2ccccc2)c2ccc(C(C)(C)C)cc2-c2cccc3ccccc23)cc1]

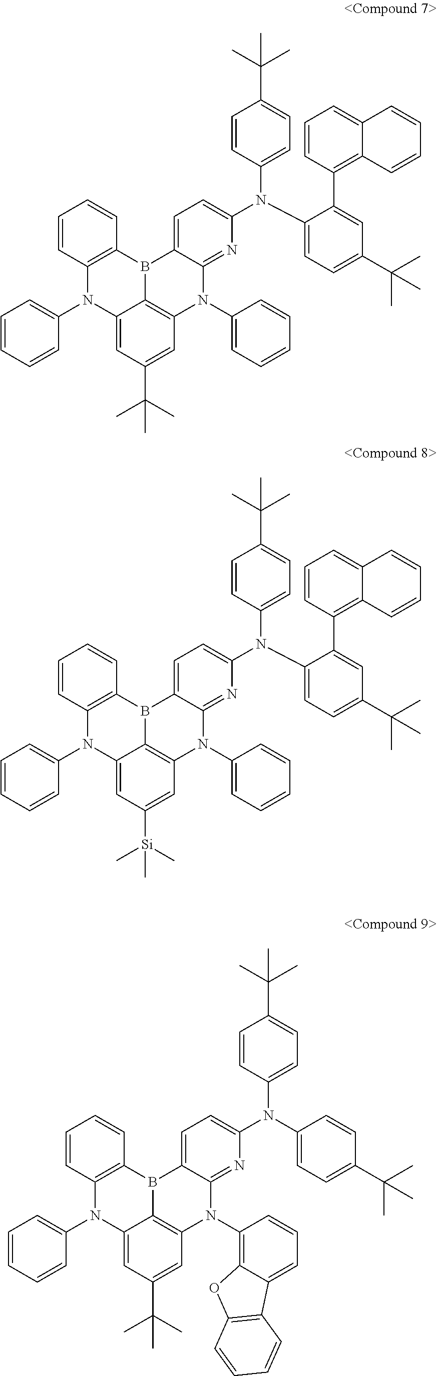 [SMILES: CC(C)(C)c1ccc(N(c2ccc3c(n2)N(c2ccccc2)c2cc(C(C)(C)C)cc4c2B3c2ccccc2N4c2ccccc2)c2ccc(C(C)(C)C)cc2-c2cccc3ccccc23)cc1 ; CC(C)(C)c1ccc(N(c2ccc3c(n2)N(c2ccccc2)c2cc([Si](C)(C)C)cc4c2B3c2ccccc2N4c2ccccc2)c2ccc(C(C)(C)C)cc2-c2cccc3ccccc23)cc1 ; CC(C)(C)c1ccc(N(c2ccc(C(C)(C)C)cc2)c2ccc3c(n2)N(c2cccc4c2oc2ccccc24)c2cc(C(C)(C)C)cc4c2B3c2ccccc2N4c2ccccc2)cc1]

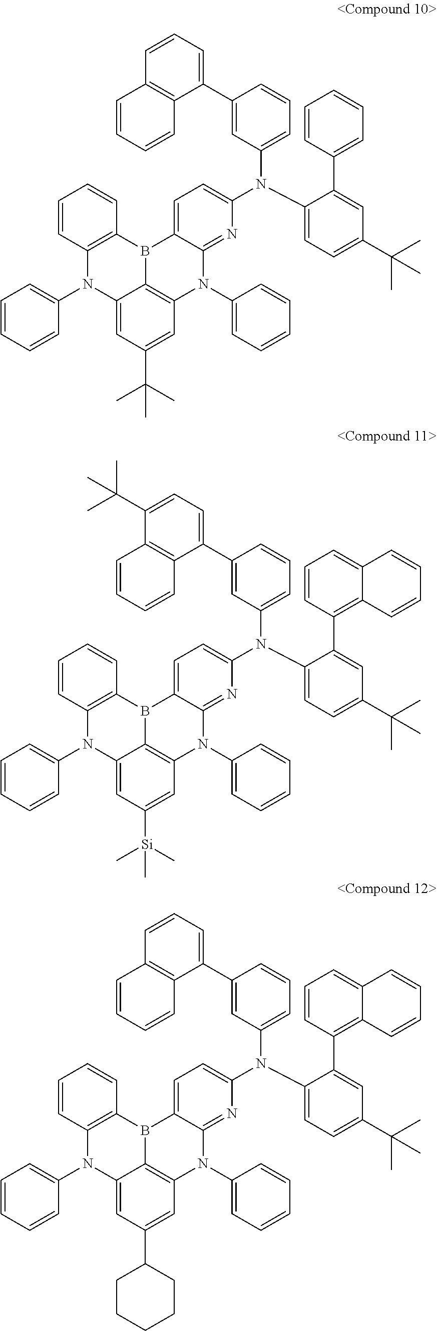

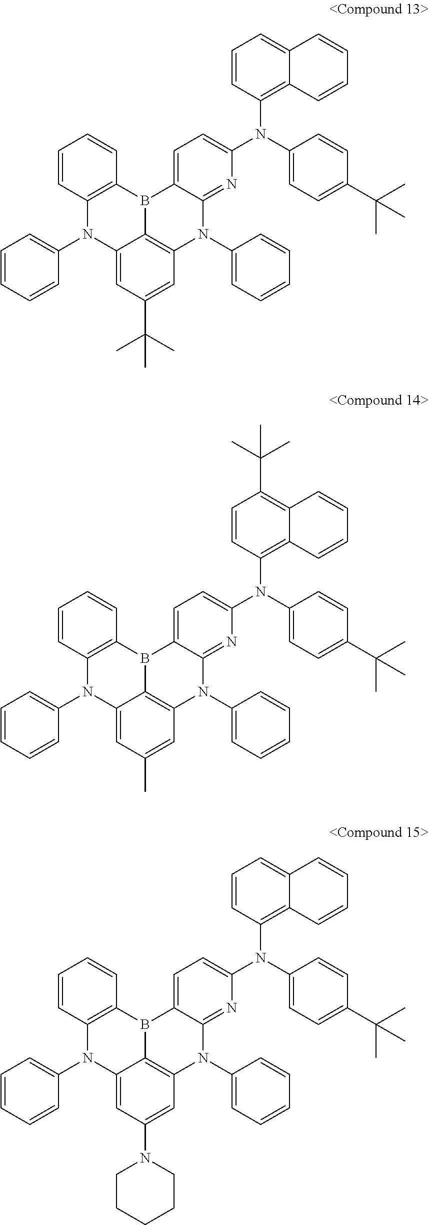 [SMILES: CC(C)(C)c1ccc(N(c2ccc3c(n2)N(c2ccccc2)c2cc(C(C)(C)C)cc4c2B3c2ccccc2N4c2ccccc2)c2cccc3ccccc23)cc1 ; Cc1cc2c3c(c1)N(c1ccccc1)c1nc(N(c4ccc(C(C)(C)C)cc4)c4ccc(C(C)(C)C)c5ccccc45)ccc1B3c1ccccc1N2c1ccccc1 ; CC(C)(C)c1ccc(N(c2ccc3c(n2)N(c2ccccc2)c2cc(N4CCCCC4)cc4c2B3c2ccccc2N4c2ccccc2)c2cccc3ccccc23)cc1]

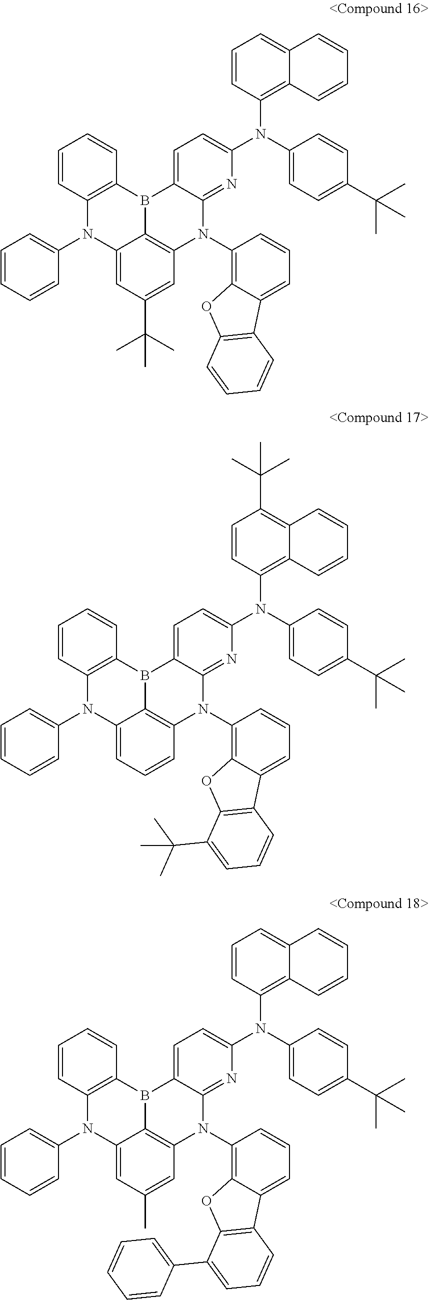 [SMILES: CC(C)(C)c1ccc(N(c2ccc3c(n2)N(c2cccc4c2oc2ccccc24)c2cc(C(C)(C)C)cc4c2B3c2ccccc2N4c2ccccc2)c2cccc3ccccc23)cc1 ; CC(C)(C)c1ccc(N(c2ccc3c(n2)N(c2cccc4c2oc2c(C(C)(C)C)cccc24)c2cccc4c2B3c2ccccc2N4c2ccccc2)c2ccc(C(C)(C)C)c3ccccc23)cc1 ; Cc1cc2c3c(c1)N(c1cccc4c1oc1c(-c5ccccc5)cccc14)c1nc(N(c4ccc(C(C)(C)C)cc4)c4cccc5ccccc45)ccc1B3c1ccccc1N2c1ccccc1]

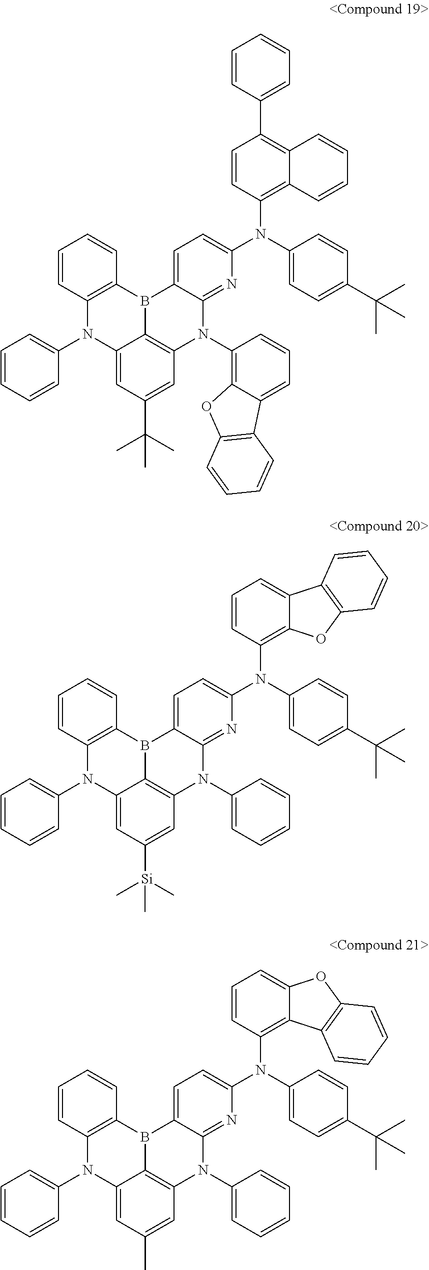 [SMILES: CC(C)(C)c1ccc(N(c2ccc3c(n2)N(c2cccc4c2oc2ccccc24)c2cc(C(C)(C)C)cc4c2B3c2ccccc2N4c2ccccc2)c2ccc(-c3ccccc3)c3ccccc23)cc1 ; CC(C)(C)c1ccc(N(c2ccc3c(n2)N(c2ccccc2)c2cc([Si](C)(C)C)cc4c2B3c2ccccc2N4c2ccccc2)c2cccc3c2oc2ccccc23)cc1 ; Cc1cc2c3c(c1)N(c1ccccc1)c1nc(N(c4ccc(C(C)(C)C)cc4)c4cccc5oc6ccccc6c45)ccc1B3c1ccccc1N2c1ccccc1]

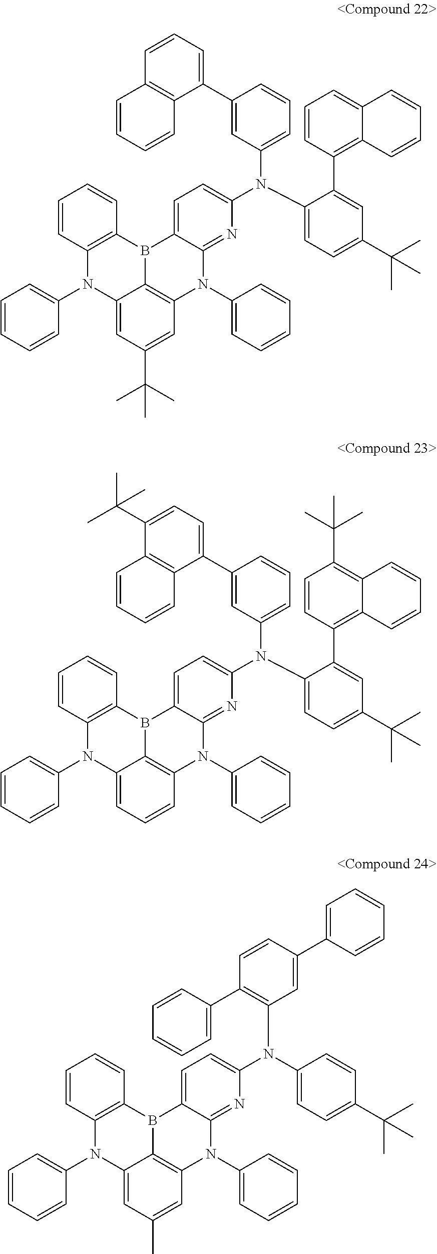 [SMILES: CC(C)(C)c1ccc(N(c2cccc(-c3cccc4ccccc34)c2)c2ccc3c(n2)N(c2ccccc2)c2cc(C(C)(C)C)cc4c2B3c2ccccc2N4c2ccccc2)c(-c2cccc3ccccc23)c1 ; CC(C)(C)c1ccc(N(c2cccc(-c3ccc(C(C)(C)C)c4ccccc34)c2)c2ccc3c(n2)N(c2ccccc2)c2cccc4c2B3c2ccccc2N4c2ccccc2)c(-c2ccc(C(C)(C)C)c3ccccc23)c1 ; Cc1cc2c3c(c1)N(c1ccccc1)c1nc(N(c4ccc(C(C)(C)C)cc4)c4cc(-c5ccccc5)ccc4-c4ccccc4)ccc1B3c1ccccc1N2c1ccccc1]

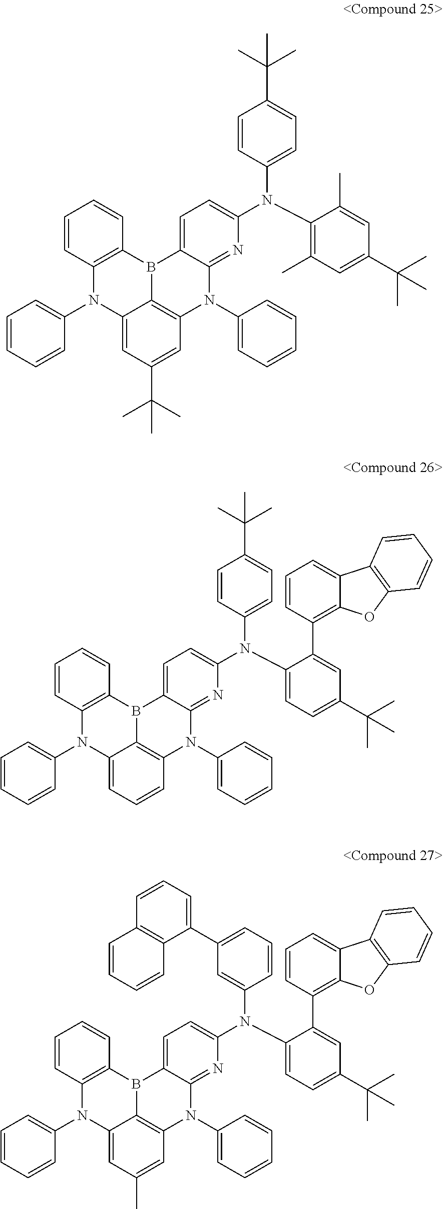 [SMILES: Cc1cc(C(C)(C)C)cc(C)c1N(c1ccc(C(C)(C)C)cc1)c1ccc2c(n1)N(c1ccccc1)c1cc(C(C)(C)C)cc3c1B2c1ccccc1N3c1ccccc1 ; CC(C)(C)c1ccc(N(c2ccc3c(n2)N(c2ccccc2)c2cccc4c2B3c2ccccc2N4c2ccccc2)c2ccc(C(C)(C)C)cc2-c2cccc3c2oc2ccccc23)cc1 ; Cc1cc2c3c(c1)N(c1ccccc1)c1nc(N(c4cccc(-c5cccc6ccccc56)c4)c4ccc(C(C)(C)C)cc4-c4cccc5c4oc4ccccc45)ccc1B3c1ccccc1N2c1ccccc1]

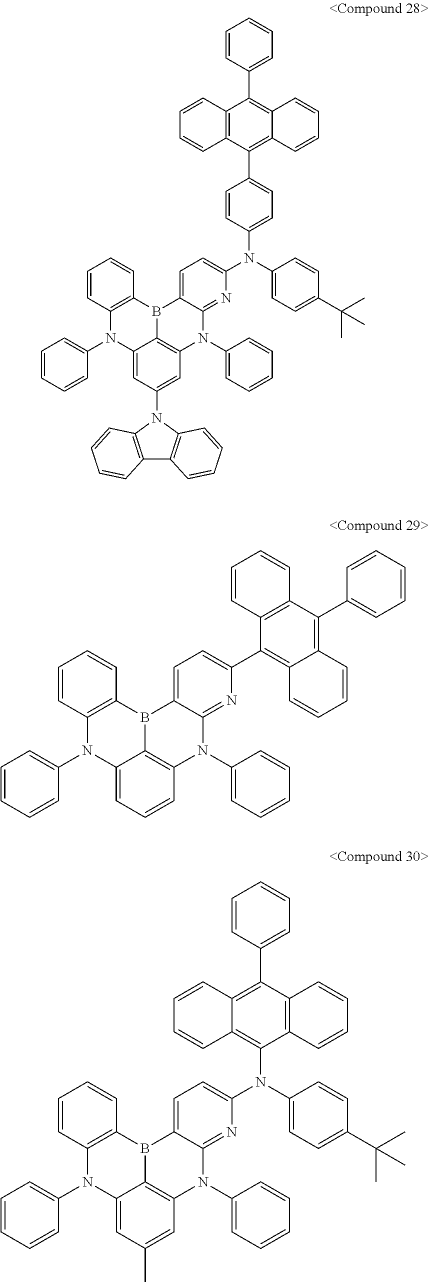 [SMILES: CC(C)(C)c1ccc(N(c2ccc(-c3c4ccccc4c(-c4ccccc4)c4ccccc34)cc2)c2ccc3c(n2)N(c2ccccc2)c2cc(-n4c5ccccc5c5ccccc54)cc4c2B3c2ccccc2N4c2ccccc2)cc1 ; c1ccc(-c2c3ccccc3c(-c3ccc4c(n3)N(c3ccccc3)c3cccc5c3B4c3ccccc3N5c3ccccc3)c3ccccc23)cc1 ; Cc1cc2c3c(c1)N(c1ccccc1)c1nc(N(c4ccc(C(C)(C)C)cc4)c4c5ccccc5c(-c5ccccc5)c5ccccc45)ccc1B3c1ccccc1N2c1ccccc1]

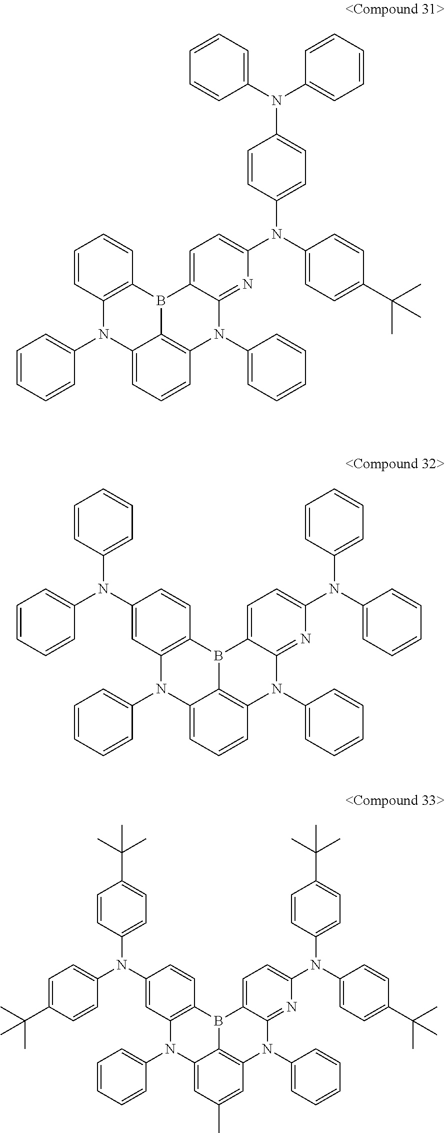

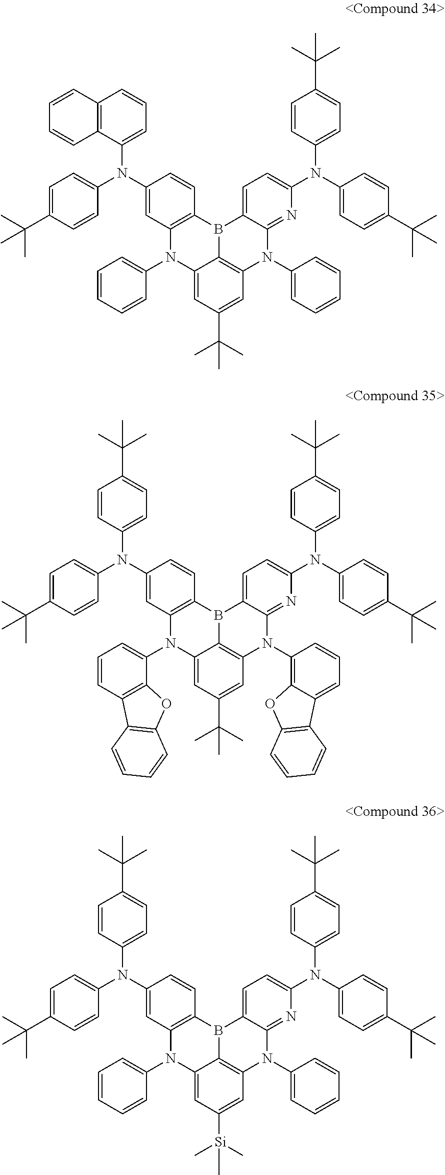

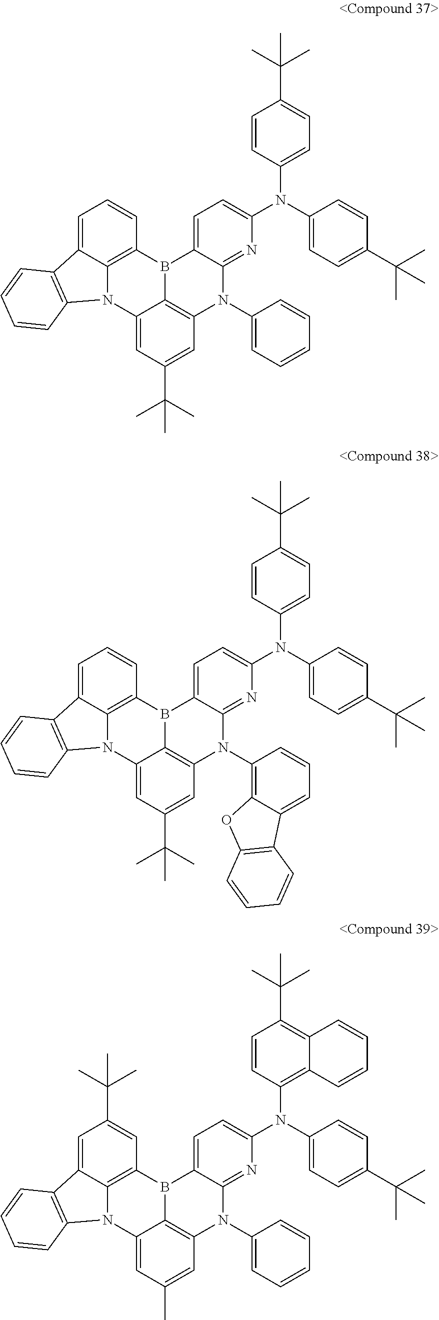 [SMILES: CC(C)(C)c1ccc(N(c2ccc(C(C)(C)C)cc2)c2ccc3c(n2)N(c2ccccc2)c2cc(C(C)(C)C)cc4c2B3c2cccc3c5ccccc5n-4c23)cc1 ; CC(C)(C)c1ccc(N(c2ccc(C(C)(C)C)cc2)c2ccc3c(n2)N(c2cccc4c2oc2ccccc24)c2cc(C(C)(C)C)cc4c2B3c2cccc3c5ccccc5n-4c23)cc1 ; Cc1cc2c3c(c1)-n1c4ccccc4c4cc(C(C)(C)C)cc(c41)B3c1ccc(N(c3ccc(C(C)(C)C)cc3)c3ccc(C(C)(C)C)c4ccccc34)nc1N2c1ccccc1]

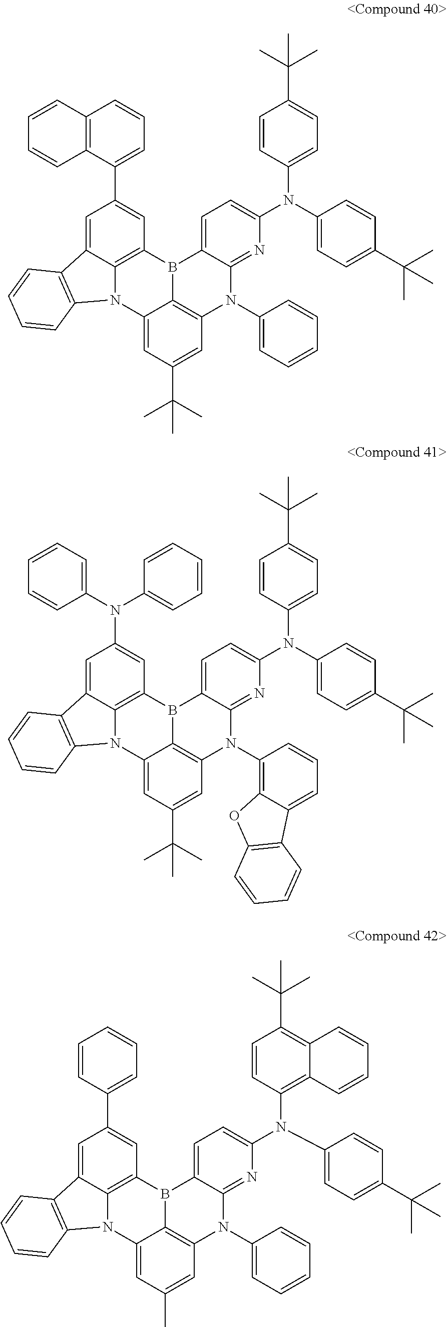 [SMILES: CC(C)(C)c1ccc(N(c2ccc(C(C)(C)C)cc2)c2ccc3c(n2)N(c2ccccc2)c2cc(C(C)(C)C)cc4c2B3c2cc(-c3cccc5ccccc35)cc3c5ccccc5n-4c23)cc1 ; CC(C)(C)c1ccc(N(c2ccc(C(C)(C)C)cc2)c2ccc3c(n2)N(c2cccc4c2oc2ccccc24)c2cc(C(C)(C)C)cc4c2B3c2cc(N(c3ccccc3)c3ccccc3)cc3c5ccccc5n-4c23)cc1 ; Cc1cc2c3c(c1)-n1c4ccccc4c4cc(-c5ccccc5)cc(c41)B3c1ccc(N(c3ccc(C(C)(C)C)cc3)c3ccc(C(C)(C)C)c4ccccc34)nc1N2c1ccccc1]

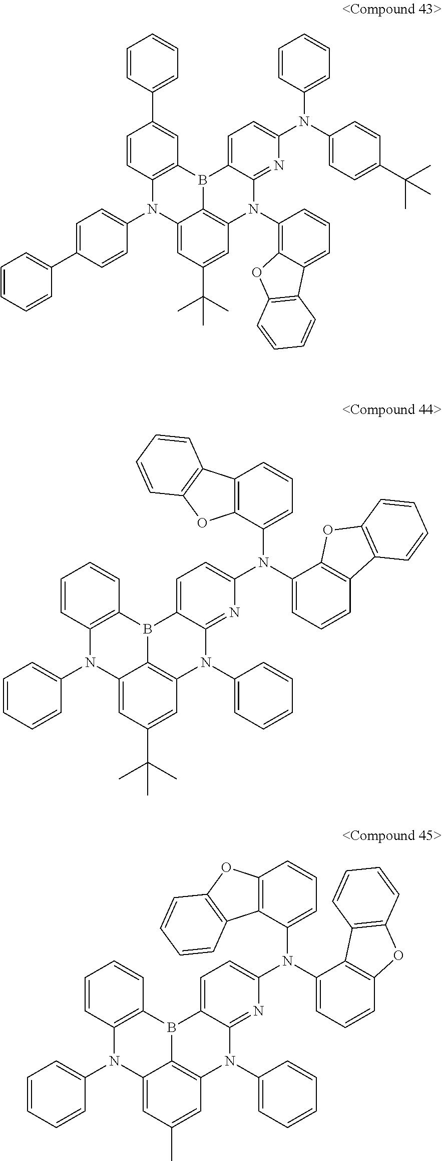 [SMILES: CC(C)(C)c1ccc(N(c2ccccc2)c2ccc3c(n2)N(c2cccc4c2oc2ccccc24)c2cc(C(C)(C)C)cc4c2B3c2cc(-c3ccccc3)ccc2N4c2ccc(-c3ccccc3)cc2)cc1 ; CC(C)(C)c1cc2c3c(c1)N(c1ccccc1)c1nc(N(c4cccc5c4oc4ccccc45)c4cccc5c4oc4ccccc45)ccc1B3c1ccccc1N2c1ccccc1 ; Cc1cc2c3c(c1)N(c1ccccc1)c1nc(N(c4cccc5oc6ccccc6c45)c4cccc5oc6ccccc6c45)ccc1B3c1ccccc1N2c1ccccc1]

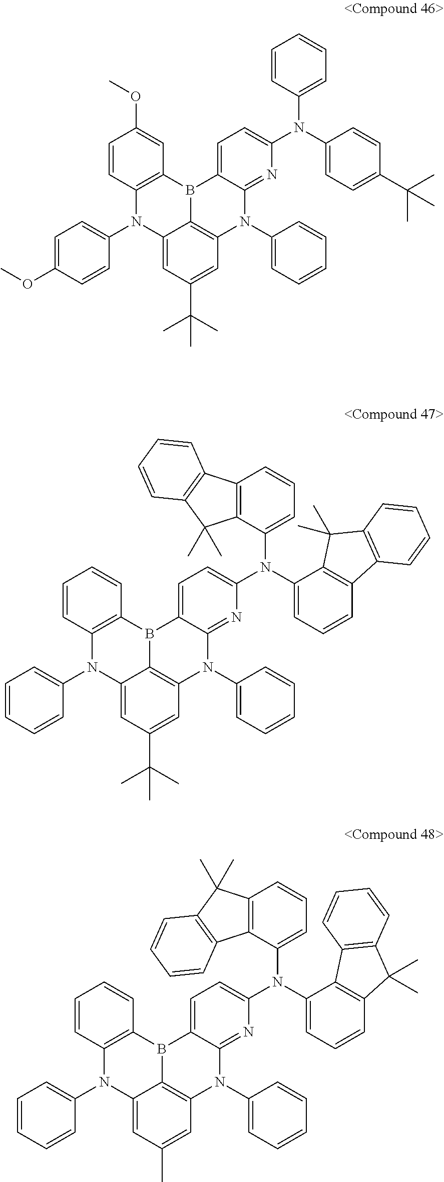 [SMILES: COc1ccc(N2c3ccc(OC)cc3B3c4ccc(N(c5ccccc5)c5ccc(C(C)(C)C)cc5)nc4N(c4ccccc4)c4cc(C(C)(C)C)cc2c43)cc1 ; CC(C)(C)c1cc2c3c(c1)N(c1ccccc1)c1nc(N(c4cccc5c4C(C)(C)c4ccccc4-5)c4cccc5c4C(C)(C)c4ccccc4-5)ccc1B3c1ccccc1N2c1ccccc1 ; Cc1cc2c3c(c1)N(c1ccccc1)c1nc(N(c4cccc5c4-c4ccccc4C5(C)C)c4cccc5c4-c4ccccc4C5(C)C)ccc1B3c1ccccc1N2c1ccccc1]

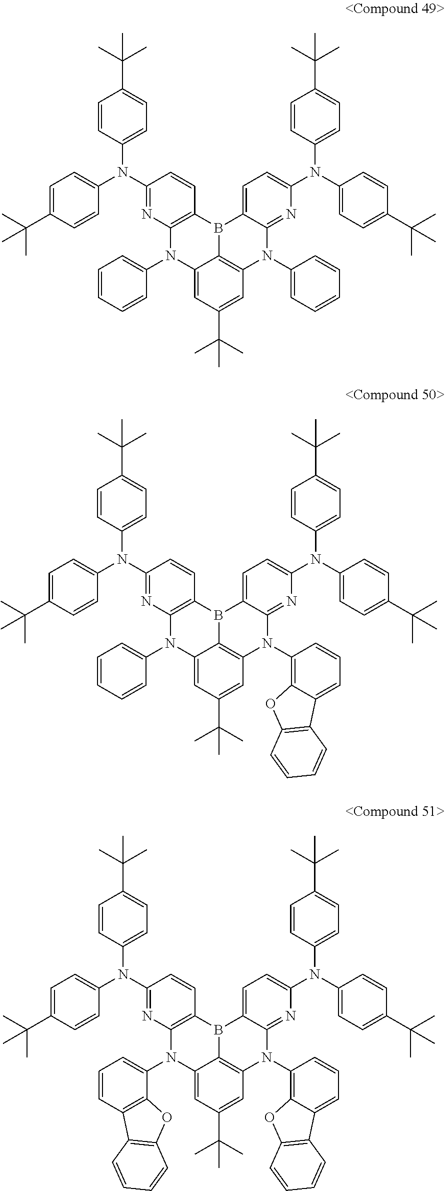

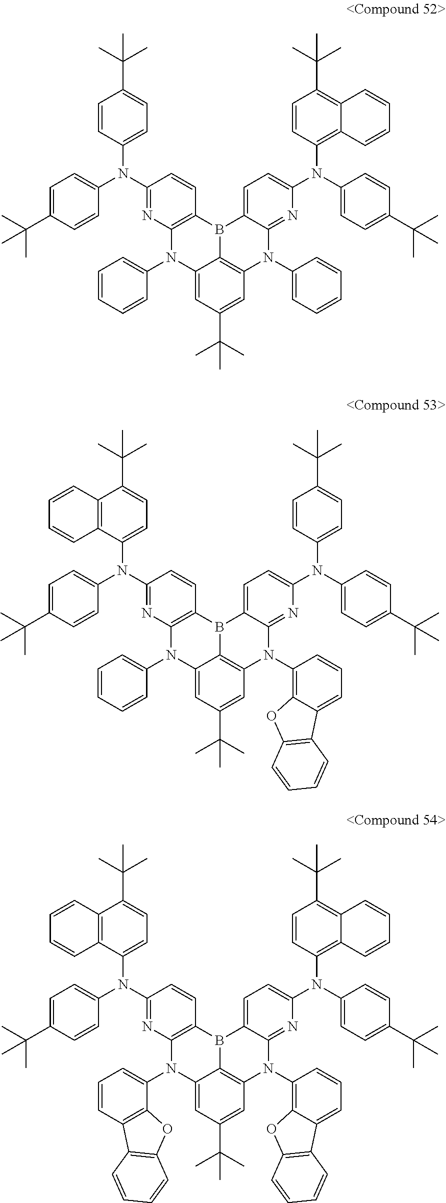

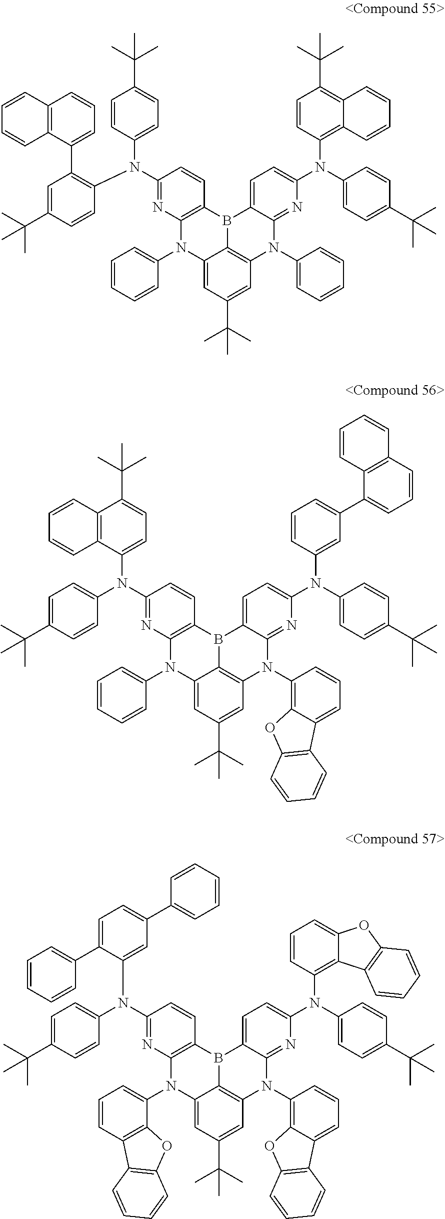

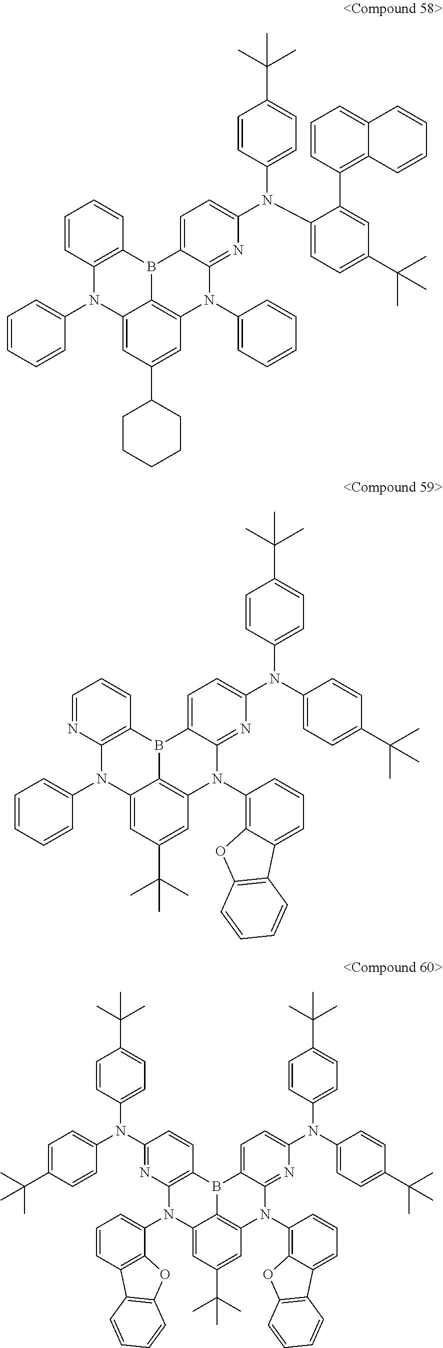

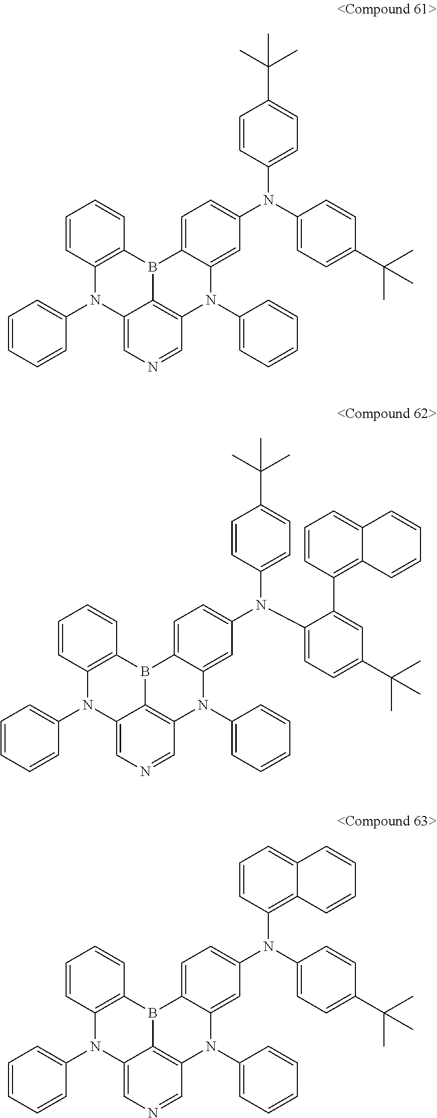 [SMILES: CC(C)(C)c1ccc(N(c2ccc(C(C)(C)C)cc2)c2ccc3c(c2)N(c2ccccc2)c2cncc4c2B3c2ccccc2N4c2ccccc2)cc1 ; CC(C)(C)c1ccc(N(c2ccc3c(c2)N(c2ccccc2)c2cncc4c2B3c2ccccc2N4c2ccccc2)c2ccc(C(C)(C)C)cc2-c2cccc3ccccc23)cc1 ; CC(C)(C)c1ccc(N(c2ccc3c(c2)N(c2ccccc2)c2cncc4c2B3c2ccccc2N4c2ccccc2)c2cccc3ccccc23)cc1]

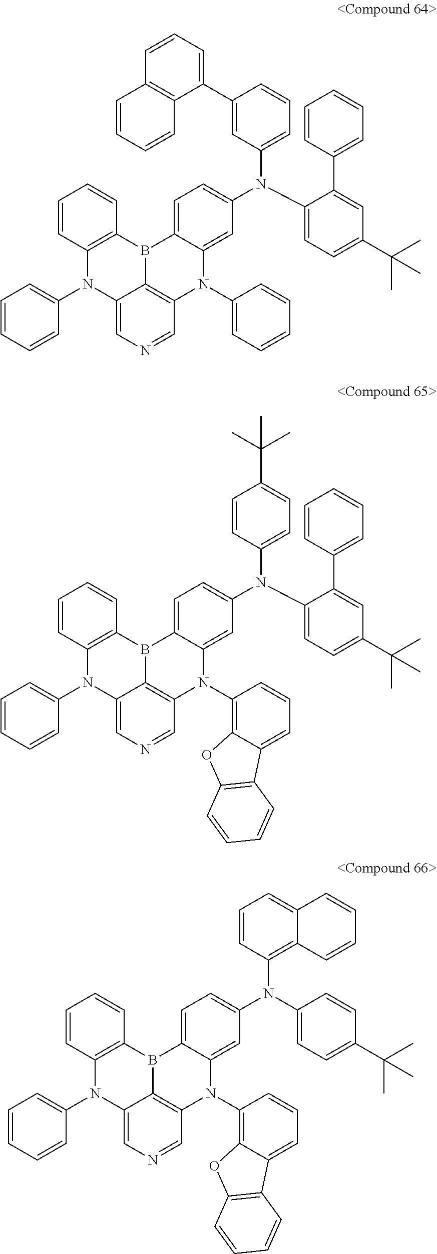 [SMILES: CC(C)(C)c1ccc(N(c2cccc(-c3cccc4ccccc34)c2)c2ccc3c(c2)N(c2ccccc2)c2cncc4c2B3c2ccccc2N4c2ccccc2)c(-c2ccccc2)c1 ; CC(C)(C)c1ccc(N(c2ccc3c(c2)N(c2cccc4c2oc2ccccc24)c2cncc4c2B3c2ccccc2N4c2ccccc2)c2ccc(C(C)(C)C)cc2-c2ccccc2)cc1 ; CC(C)(C)c1ccc(N(c2ccc3c(c2)N(c2cccc4c2oc2ccccc24)c2cncc4c2B3c2ccccc2N4c2ccccc2)c2cccc3ccccc23)cc1]

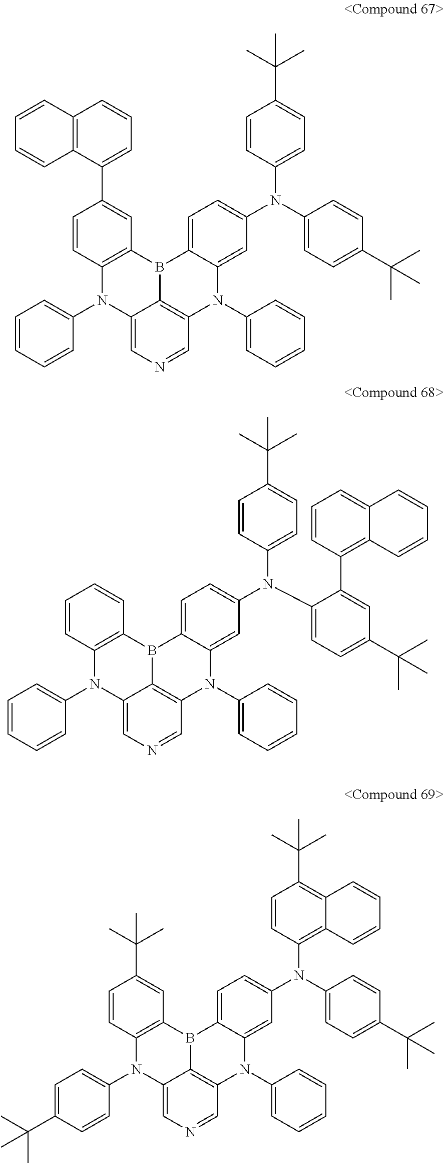

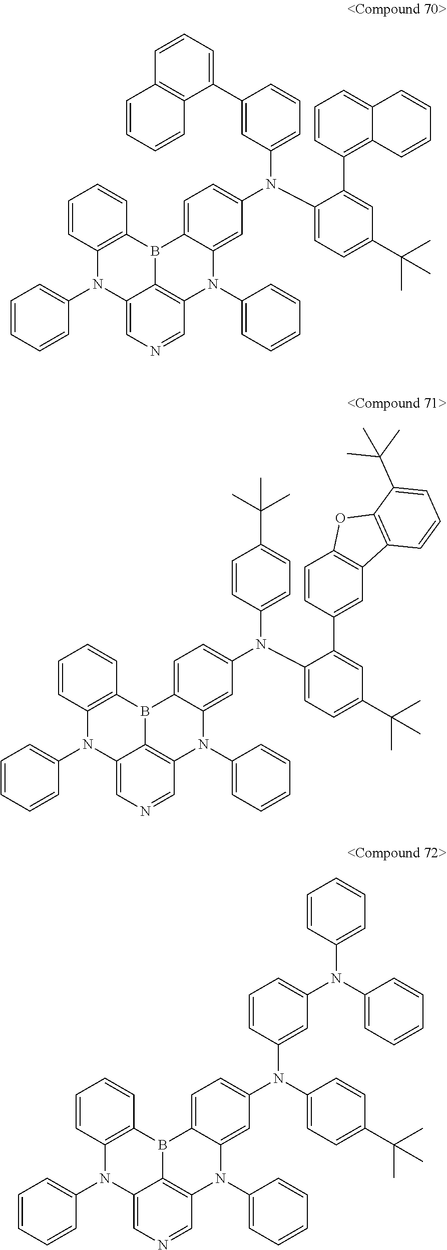 [SMILES: CC(C)(C)c1ccc(N(c2cccc(-c3cccc4ccccc34)c2)c2ccc3c(c2)N(c2ccccc2)c2cncc4c2B3c2ccccc2N4c2ccccc2)c(-c2cccc3ccccc23)c1 ; CC(C)(C)c1ccc(N(c2ccc3c(c2)N(c2ccccc2)c2cncc4c2B3c2ccccc2N4c2ccccc2)c2ccc(C(C)(C)C)cc2-c2ccc3oc4c(C(C)(C)C)cccc4c3c2)cc1 ; CC(C)(C)c1ccc(N(c2cccc(N(c3ccccc3)c3ccccc3)c2)c2ccc3c(c2)N(c2ccccc2)c2cncc4c2B3c2ccccc2N4c2ccccc2)cc1]

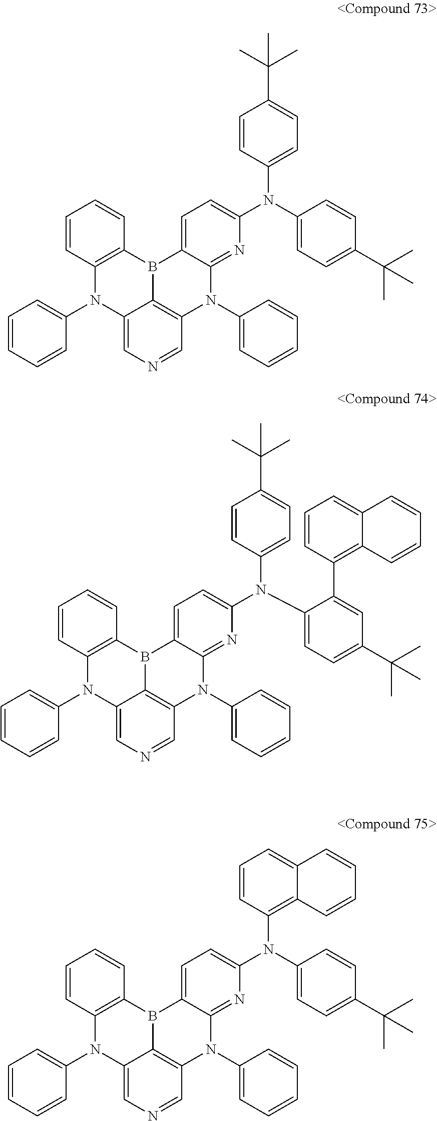 [SMILES: CC(C)(C)c1ccc(N(c2ccc(C(C)(C)C)cc2)c2ccc3c(n2)N(c2ccccc2)c2cncc4c2B3c2ccccc2N4c2ccccc2)cc1 ; CC(C)(C)c1ccc(N(c2ccc3c(n2)N(c2ccccc2)c2cncc4c2B3c2ccccc2N4c2ccccc2)c2ccc(C(C)(C)C)cc2-c2cccc3ccccc23)cc1 ; CC(C)(C)c1ccc(N(c2ccc3c(n2)N(c2ccccc2)c2cncc4c2B3c2ccccc2N4c2ccccc2)c2cccc3ccccc23)cc1]

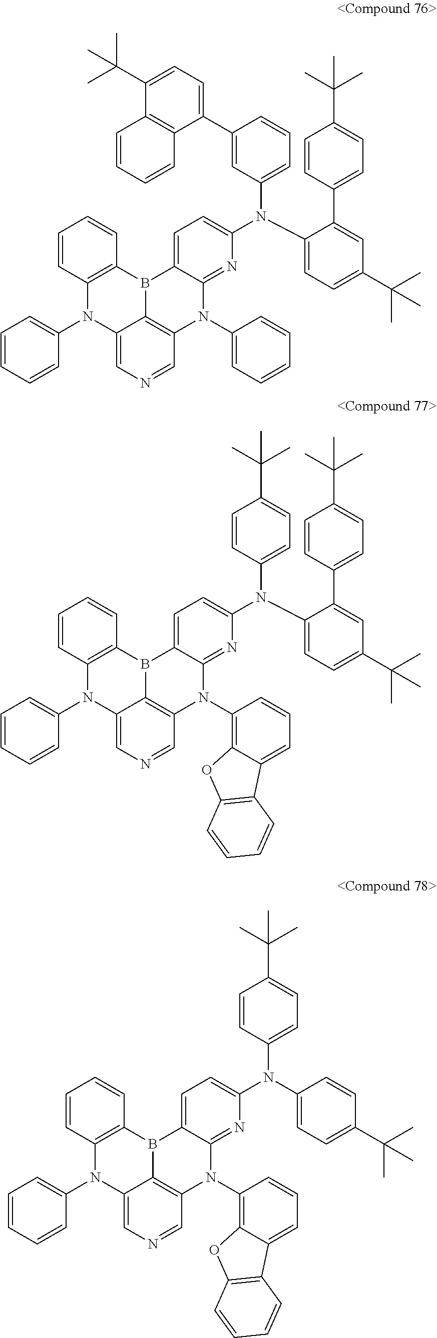 [SMILES: CC(C)(C)c1ccc(-c2cc(C(C)(C)C)ccc2N(c2cccc(-c3ccc(C(C)(C)C)c4ccccc34)c2)c2ccc3c(n2)N(c2ccccc2)c2cncc4c2B3c2ccccc2N4c2ccccc2)cc1 ; CC(C)(C)c1ccc(-c2cc(C(C)(C)C)ccc2N(c2ccc(C(C)(C)C)cc2)c2ccc3c(n2)N(c2cccc4c2oc2ccccc24)c2cncc4c2B3c2ccccc2N4c2ccccc2)cc1 ; CC(C)(C)c1ccc(N(c2ccc(C(C)(C)C)cc2)c2ccc3c(n2)N(c2cccc4c2oc2ccccc24)c2cncc4c2B3c2ccccc2N4c2ccccc2)cc1]

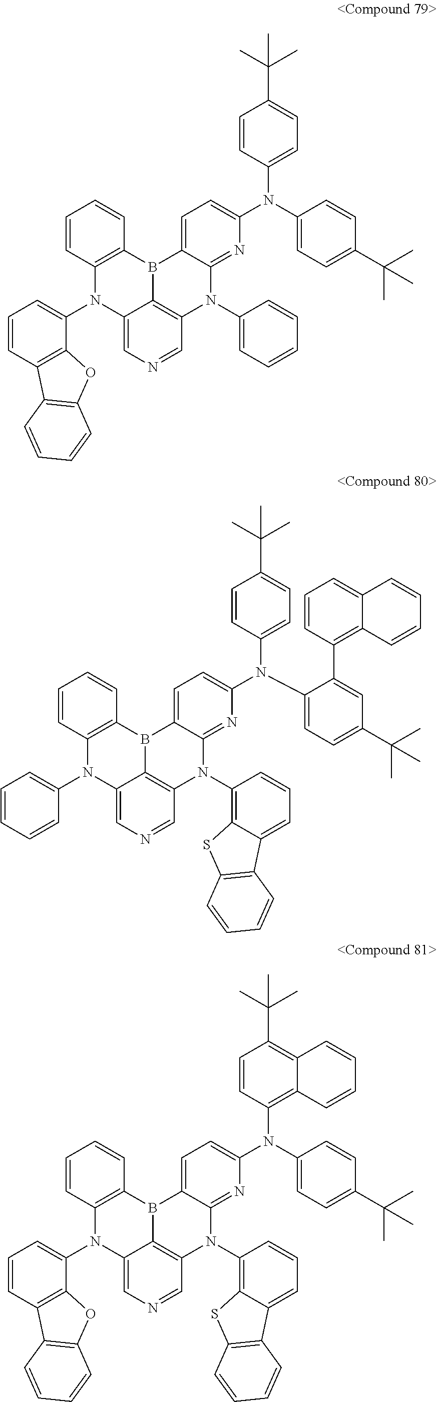

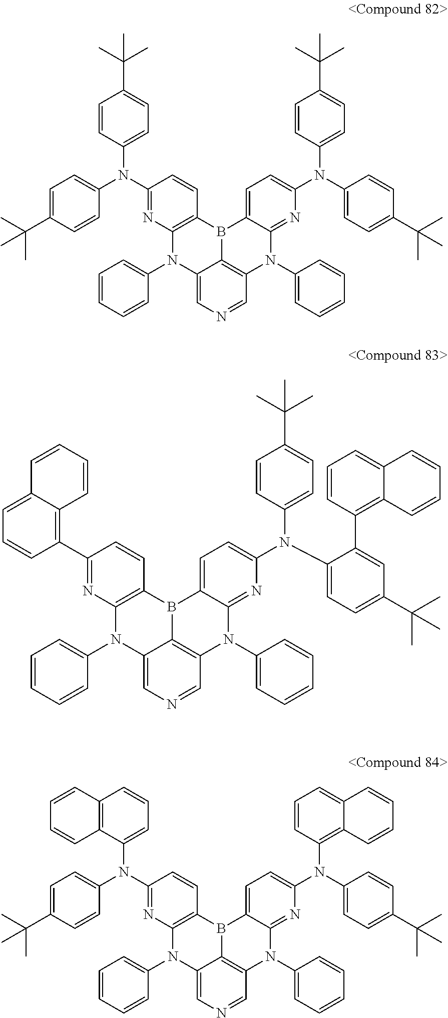

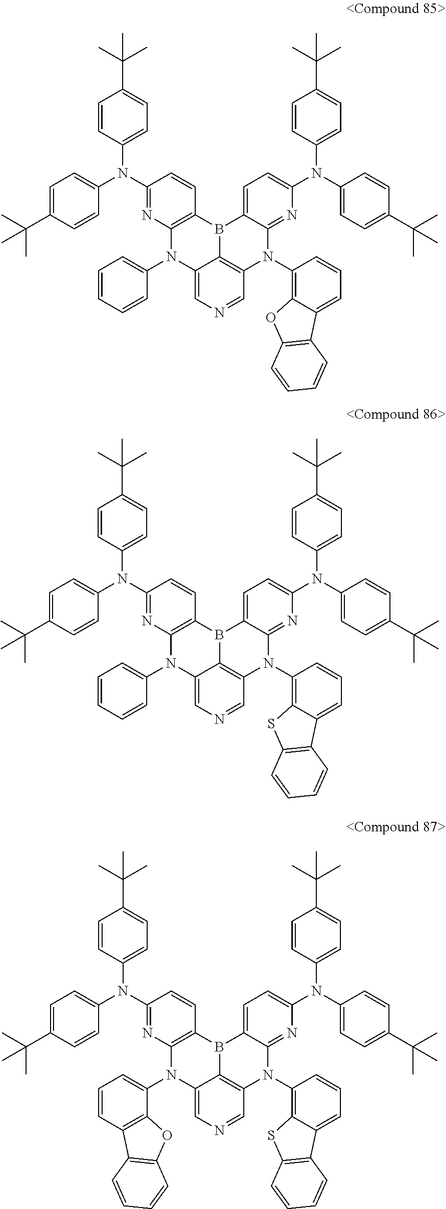

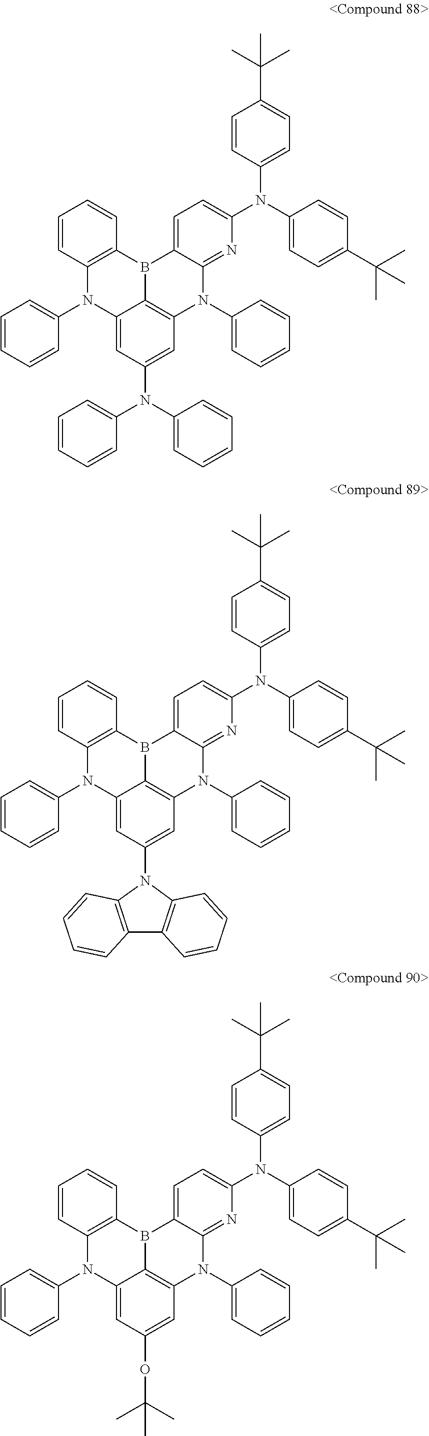 [SMILES: CC(C)(C)c1ccc(N(c2ccc(C(C)(C)C)cc2)c2ccc3c(n2)N(c2ccccc2)c2cc(N(c4ccccc4)c4ccccc4)cc4c2B3c2ccccc2N4c2ccccc2)cc1 ; CC(C)(C)c1ccc(N(c2ccc(C(C)(C)C)cc2)c2ccc3c(n2)N(c2ccccc2)c2cc(-n4c5ccccc5c5ccccc54)cc4c2B3c2ccccc2N4c2ccccc2)cc1 ; CC(C)(C)Oc1cc2c3c(c1)N(c1ccccc1)c1nc(N(c4ccc(C(C)(C)C)cc4)c4ccc(C(C)(C)C)cc4)ccc1B3c1ccccc1N2c1ccccc1]

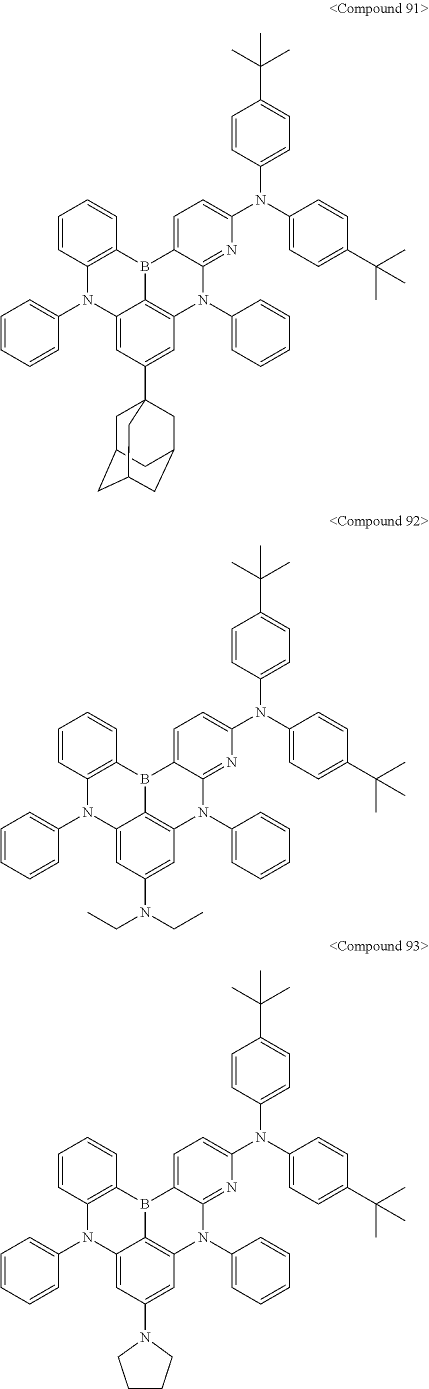 [SMILES: CC(C)(C)c1ccc(N(c2ccc(C(C)(C)C)cc2)c2ccc3c(n2)N(c2ccccc2)c2cc(C45CC6CC(CC(C6)C4)C5)cc4c2B3c2ccccc2N4c2ccccc2)cc1 ; CCN(CC)c1cc2c3c(c1)N(c1ccccc1)c1nc(N(c4ccc(C(C)(C)C)cc4)c4ccc(C(C)(C)C)cc4)ccc1B3c1ccccc1N2c1ccccc1 ; CC(C)(C)c1ccc(N(c2ccc(C(C)(C)C)cc2)c2ccc3c(n2)N(c2ccccc2)c2cc(N4CCCC4)cc4c2B3c2ccccc2N4c2ccccc2)cc1]

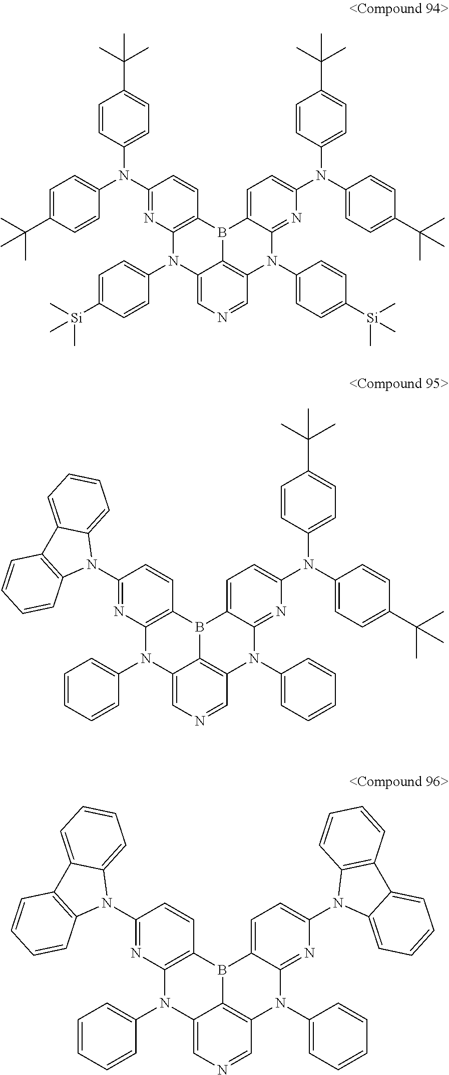 [SMILES: CC(C)(C)c1ccc(N(c2ccc(C(C)(C)C)cc2)c2ccc3c(n2)N(c2ccc([Si](C)(C)C)cc2)c2cncc4c2B3c2ccc(N(c3ccc(C(C)(C)C)cc3)c3ccc(C(C)(C)C)cc3)nc2N4c2ccc([Si](C)(C)C)cc2)cc1 ; CC(C)(C)c1ccc(N(c2ccc(C(C)(C)C)cc2)c2ccc3c(n2)N(c2ccccc2)c2cncc4c2B3c2ccc(-n3c5ccccc5c5ccccc53)nc2N4c2ccccc2)cc1 ; c1ccc(N2c3cncc4c3B(c3ccc(-n5c6ccccc6c6ccccc65)nc32)c2ccc(-n3c5ccccc5c5ccccc53)nc2N4c2ccccc2)cc1]

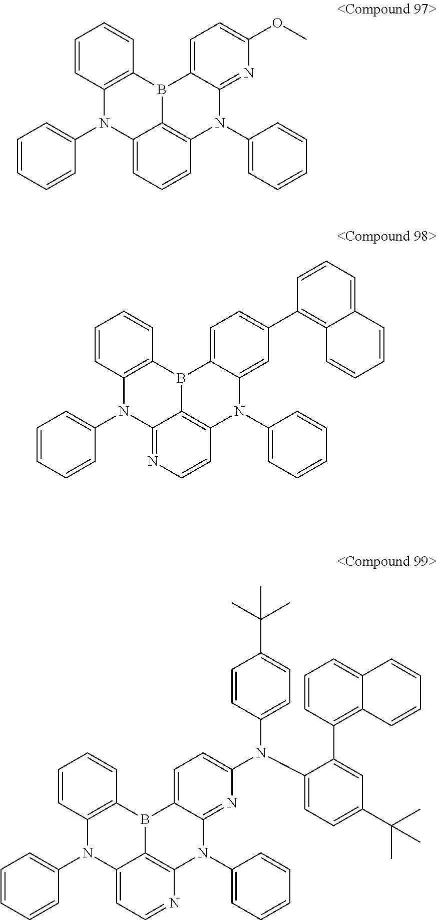 [SMILES: COc1ccc2c(n1)N(c1ccccc1)c1cccc3c1B2c1ccccc1N3c1ccccc1 ; c1ccc(N2c3cc(-c4cccc5ccccc45)ccc3B3c4ccccc4N(c4ccccc4)c4nccc2c43)cc1 ; CC(C)(C)c1ccc(N(c2ccc3c(n2)N(c2ccccc2)c2nccc4c2B3c2ccccc2N4c2ccccc2)c2ccc(C(C)(C)C)cc2-c2cccc3ccccc23)cc1]

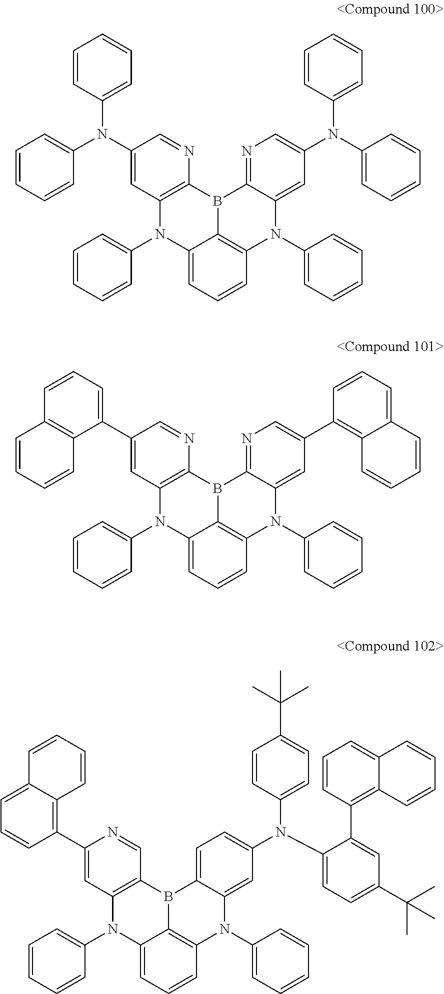 [SMILES: c1ccc(N(c2ccccc2)c2cnc3c(c2)N(c2ccccc2)c2cccc4c2B3c2ncc(N(c3ccccc3)c3ccccc3)cc2N4c2ccccc2)cc1 ; c1ccc(N2c3cc(-c4cccc5ccccc45)cnc3B3c4ncc(-c5cccc6ccccc56)cc4N(c4ccccc4)c4cccc2c43)cc1 ; CC(C)(C)c1ccc(N(c2ccc3c(c2)N(c2ccccc2)c2cccc4c2B3c2cnc(-c3cccc5ccccc35)cc2N4c2ccccc2)c2ccc(C(C)(C)C)cc2-c2cccc3ccccc23)cc1]

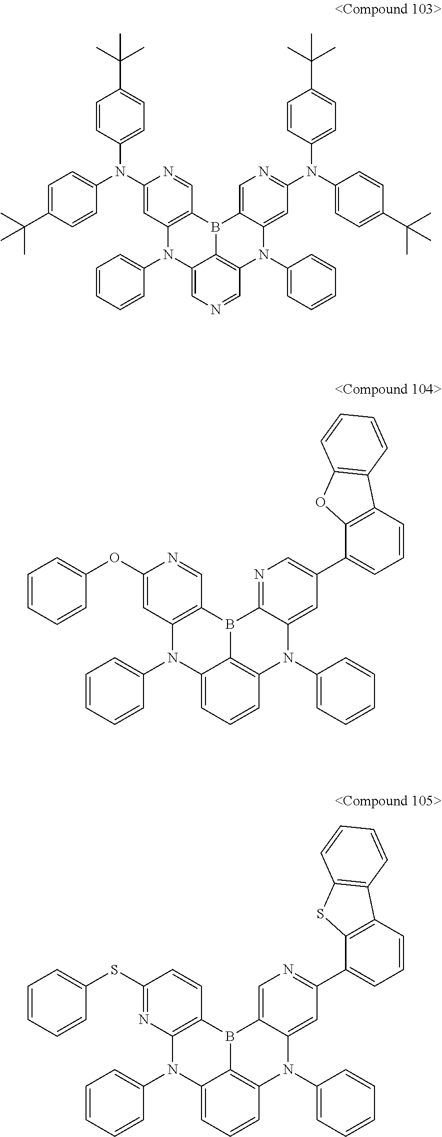 [SMILES: CC(C)(C)c1ccc(N(c2ccc(C(C)(C)C)cc2)c2cc3c(cn2)B2c4cnc(N(c5ccc(C(C)(C)C)cc5)c5ccc(C(C)(C)C)cc5)cc4N(c4ccccc4)c4cncc(c42)N3c2ccccc2)cc1 ; c1ccc(Oc2cc3c(cn2)B2c4ncc(-c5cccc6c5oc5ccccc56)cc4N(c4ccccc4)c4cccc(c42)N3c2ccccc2)cc1 ; c1ccc(Sc2ccc3c(n2)N(c2ccccc2)c2cccc4c2B3c2cnc(-c3cccc5c3sc3ccccc35)cc2N4c2ccccc2)cc1]

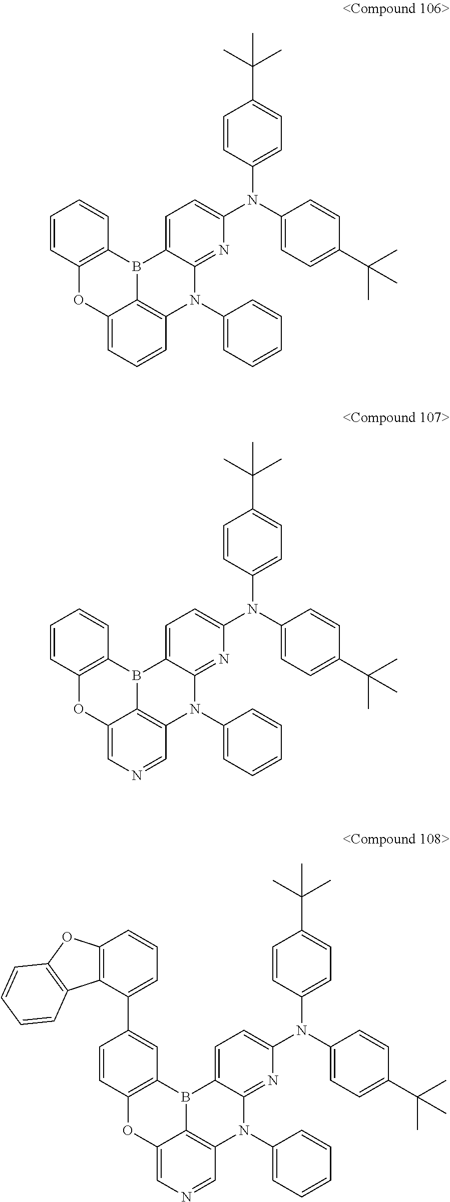 [SMILES: CC(C)(C)c1ccc(N(c2ccc(C(C)(C)C)cc2)c2ccc3c(n2)N(c2ccccc2)c2cccc4c2B3c2ccccc2O4)cc1 ; CC(C)(C)c1ccc(N(c2ccc(C(C)(C)C)cc2)c2ccc3c(n2)N(c2ccccc2)c2cncc4c2B3c2ccccc2O4)cc1 ; CC(C)(C)c1ccc(N(c2ccc(C(C)(C)C)cc2)c2ccc3c(n2)N(c2ccccc2)c2cncc4c2B3c2cc(-c3cccc5oc6ccccc6c35)ccc2O4)cc1]

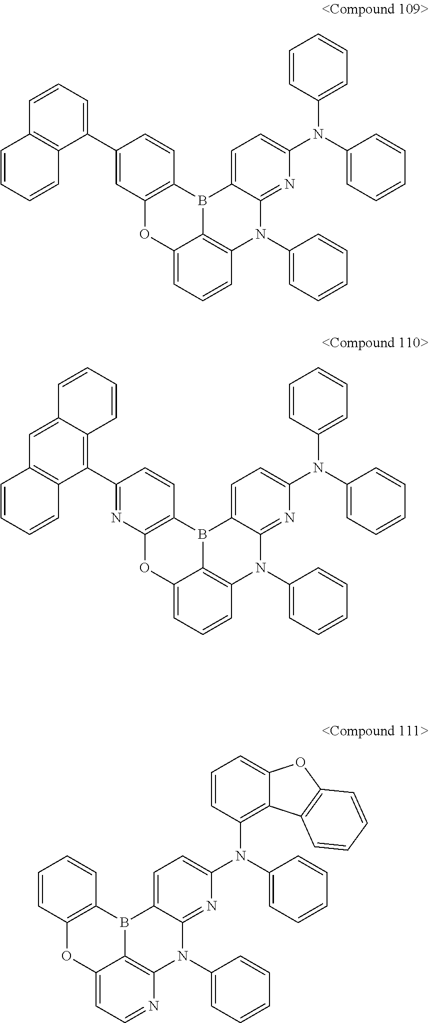 [SMILES: c1ccc(N(c2ccccc2)c2ccc3c(n2)N(c2ccccc2)c2cccc4c2B3c2ccc(-c3cccc5ccccc35)cc2O4)cc1 ; c1ccc(N(c2ccccc2)c2ccc3c(n2)N(c2ccccc2)c2cccc4c2B3c2ccc(-c3c5ccccc5cc5ccccc35)nc2O4)cc1 ; c1ccc(N2c3nc(N(c4ccccc4)c4cccc5oc6ccccc6c45)ccc3B3c4ccccc4Oc4ccnc2c43)cc1]

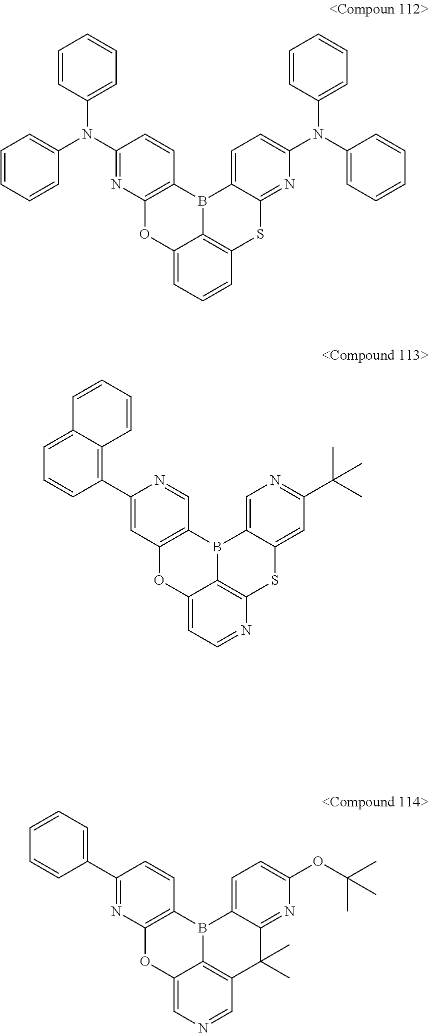 [SMILES: c1ccc(N(c2ccccc2)c2ccc3c(n2)Oc2cccc4c2B3c2ccc(N(c3ccccc3)c3ccccc3)nc2S4)cc1 ; CC(C)(C)c1cc2c(cn1)B1c3cnc(-c4cccc5ccccc45)cc3Oc3ccnc(c31)S2 ; CC(C)(C)Oc1ccc2c(n1)C(C)(C)c1cncc3c1B2c1ccc(-c2ccccc2)nc1O3]

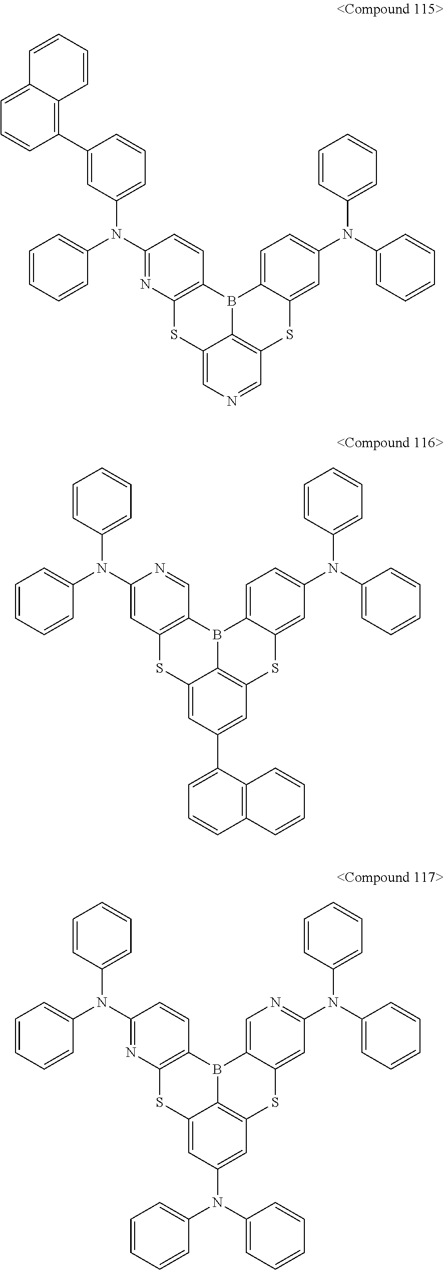 [SMILES: c1ccc(N(c2ccccc2)c2ccc3c(c2)Sc2cncc4c2B3c2ccc(N(c3ccccc3)c3cccc(-c5cccc6ccccc56)c3)nc2S4)cc1 ; c1ccc(N(c2ccccc2)c2ccc3c(c2)Sc2cc(-c4cccc5ccccc45)cc4c2B3c2cnc(N(c3ccccc3)c3ccccc3)cc2S4)cc1 ; c1ccc(N(c2ccccc2)c2cc3c4c(c2)Sc2nc(N(c5ccccc5)c5ccccc5)ccc2B4c2cnc(N(c4ccccc4)c4ccccc4)cc2S3)cc1]

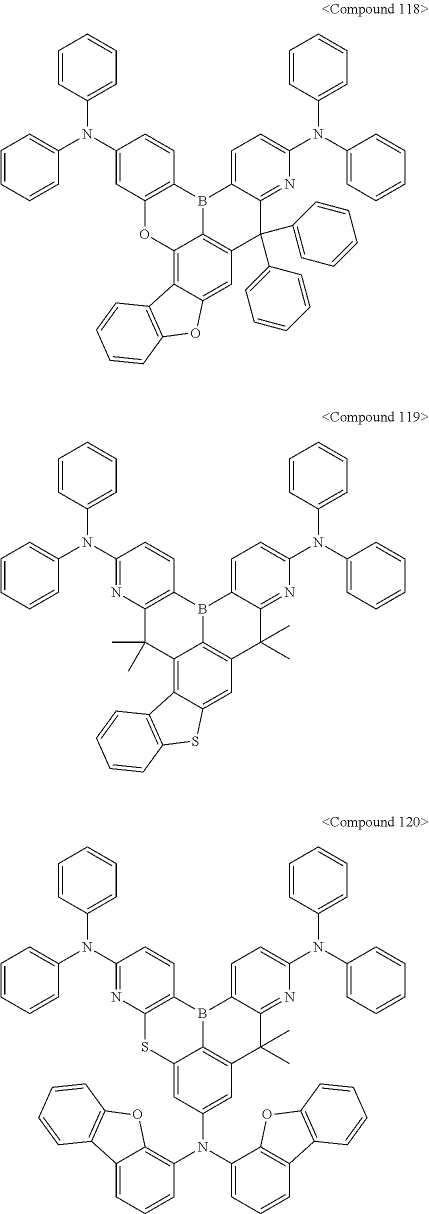 [SMILES: c1ccc(N(c2ccccc2)c2ccc3c(c2)Oc2c4c(cc5oc6ccccc6c25)C(c2ccccc2)(c2ccccc2)c2nc(N(c5ccccc5)c5ccccc5)ccc2B34)cc1 ; CC1(C)c2cc3sc4ccccc4c3c3c2B(c2ccc(N(c4ccccc4)c4ccccc4)nc21)c1ccc(N(c2ccccc2)c2ccccc2)nc1C3(C)C ; CC1(C)c2cc(N(c3cccc4c3oc3ccccc34)c3cccc4c3oc3ccccc34)cc3c2B(c2ccc(N(c4ccccc4)c4ccccc4)nc2S3)c2ccc(N(c3ccccc3)c3ccccc3)nc21]

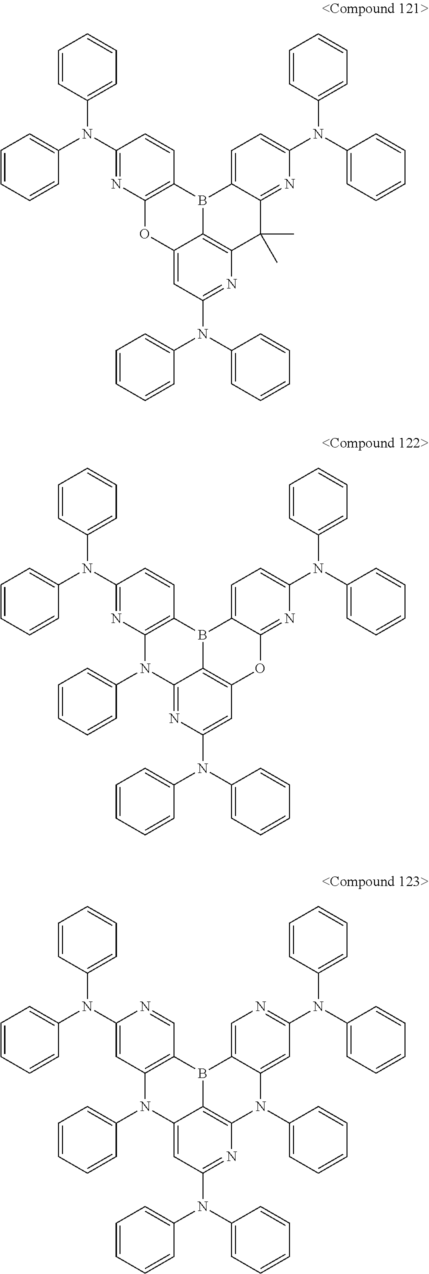 [SMILES: CC1(C)c2nc(N(c3ccccc3)c3ccccc3)ccc2B2c3ccc(N(c4ccccc4)c4ccccc4)nc3Oc3cc(N(c4ccccc4)c4ccccc4)nc1c32 ; c1ccc(N(c2ccccc2)c2ccc3c(n2)Oc2cc(N(c4ccccc4)c4ccccc4)nc4c2B3c2ccc(N(c3ccccc3)c3ccccc3)nc2N4c2ccccc2)cc1 ; c1ccc(N(c2ccccc2)c2cc3c(cn2)B2c4cnc(N(c5ccccc5)c5ccccc5)cc4N(c4ccccc4)c4nc(N(c5ccccc5)c5ccccc5)cc(c42)N3c2ccccc2)cc1]

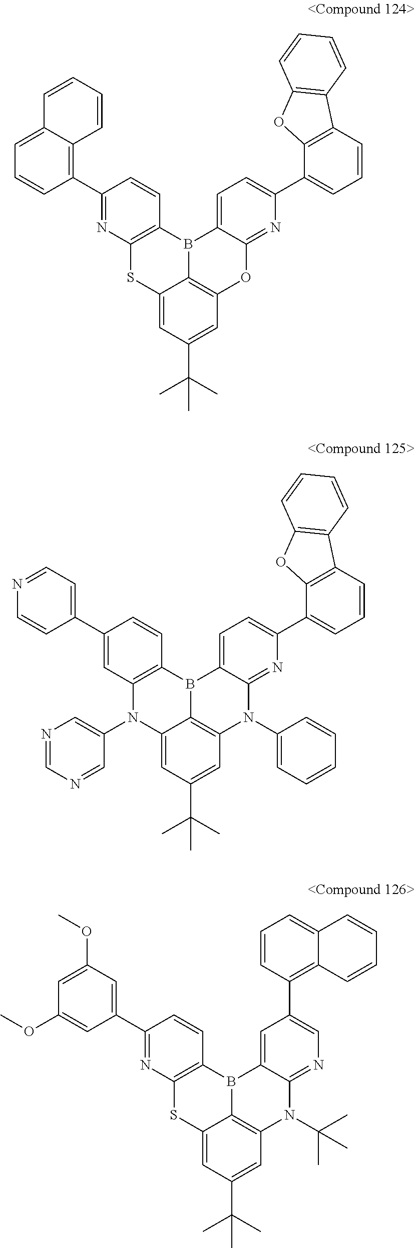 [SMILES: CC(C)(C)c1cc2c3c(c1)Sc1nc(-c4cccc5ccccc45)ccc1B3c1ccc(-c3cccc4c3oc3ccccc34)nc1O2 ; CC(C)(C)c1cc2c3c(c1)N(c1ccccc1)c1nc(-c4cccc5c4oc4ccccc45)ccc1B3c1ccc(-c3ccncc3)cc1N2c1cncnc1 ; COc1cc(OC)cc(-c2ccc3c(n2)Sc2cc(C(C)(C)C)cc4c2B3c2cc(-c3cccc5ccccc35)cnc2N4C(C)(C)C)c1]

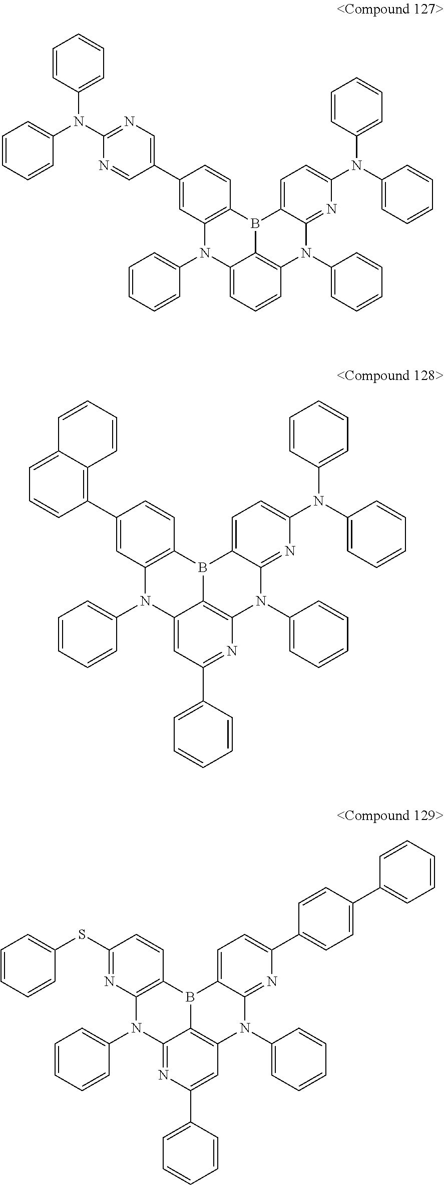 [SMILES: c1ccc(N(c2ccccc2)c2ccc3c(n2)N(c2ccccc2)c2cccc4c2B3c2ccc(-c3cnc(N(c5ccccc5)c5ccccc5)nc3)cc2N4c2ccccc2)cc1 ; c1ccc(-c2cc3c4c(n2)N(c2ccccc2)c2nc(N(c5ccccc5)c5ccccc5)ccc2B4c2ccc(-c4cccc5ccccc45)cc2N3c2ccccc2)cc1 ; c1ccc(Sc2ccc3c(n2)N(c2ccccc2)c2nc(-c4ccccc4)cc4c2B3c2ccc(-c3ccc(-c5ccccc5)cc3)nc2N4c2ccccc2)cc1]

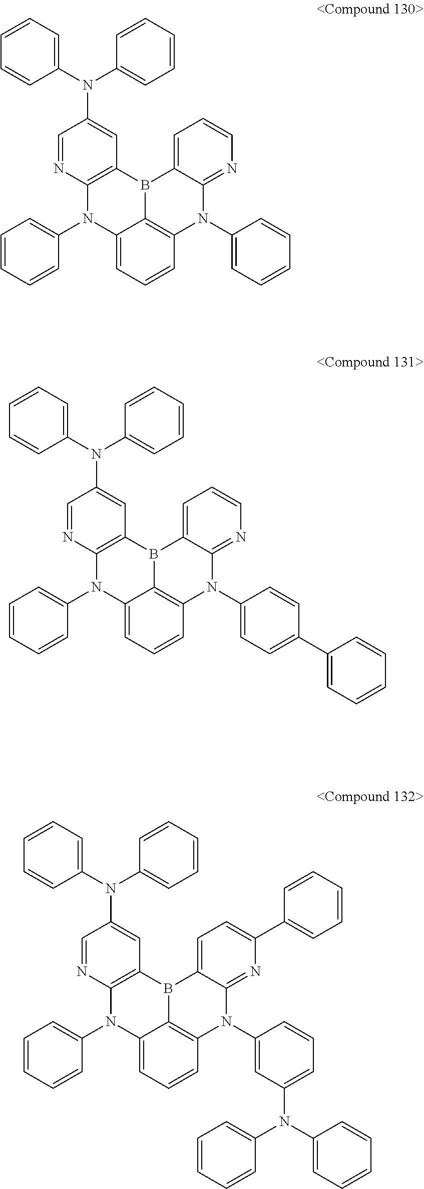 [SMILES: c1ccc(N(c2ccccc2)c2cnc3c(c2)B2c4cccnc4N(c4ccccc4)c4cccc(c42)N3c2ccccc2)cc1 ; c1ccc(-c2ccc(N3c4cccc5c4B(c4cccnc43)c3cc(N(c4ccccc4)c4ccccc4)cnc3N5c3ccccc3)cc2)cc1 ; c1ccc(-c2ccc3c(n2)N(c2cccc(N(c4ccccc4)c4ccccc4)c2)c2cccc4c2B3c2cc(N(c3ccccc3)c3ccccc3)cnc2N4c2ccccc2)cc1]

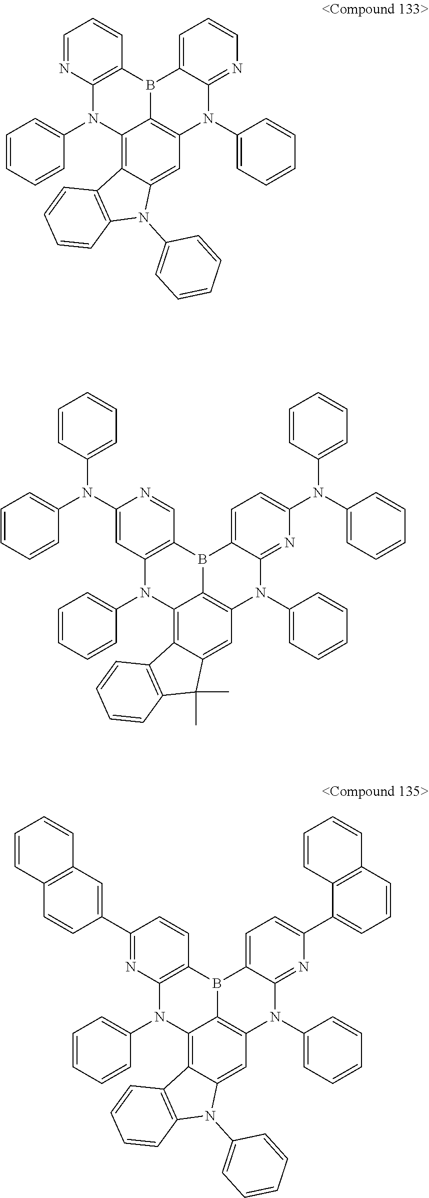 [SMILES: c1ccc(N2c3cc4c(c5c3B(c3cccnc32)c2cccnc2N5c2ccccc2)c2ccccc2n4-c2ccccc2)cc1 ; CC1(C)c2ccccc2-c2c1cc1c3c2N(c2ccccc2)c2cc(N(c4ccccc4)c4ccccc4)ncc2B3c2ccc(N(c3ccccc3)c3ccccc3)nc2N1c1ccccc1 ; c1ccc(N2c3cc4c(c5c3B(c3ccc(-c6cccc7ccccc67)nc32)c2ccc(-c3ccc6ccccc6c3)nc2N5c2ccccc2)c2ccccc2n4-c2ccccc2)cc1]

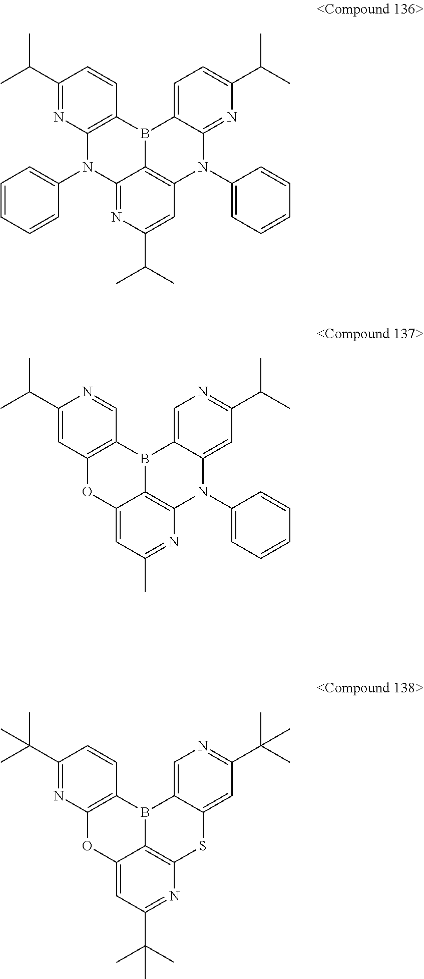

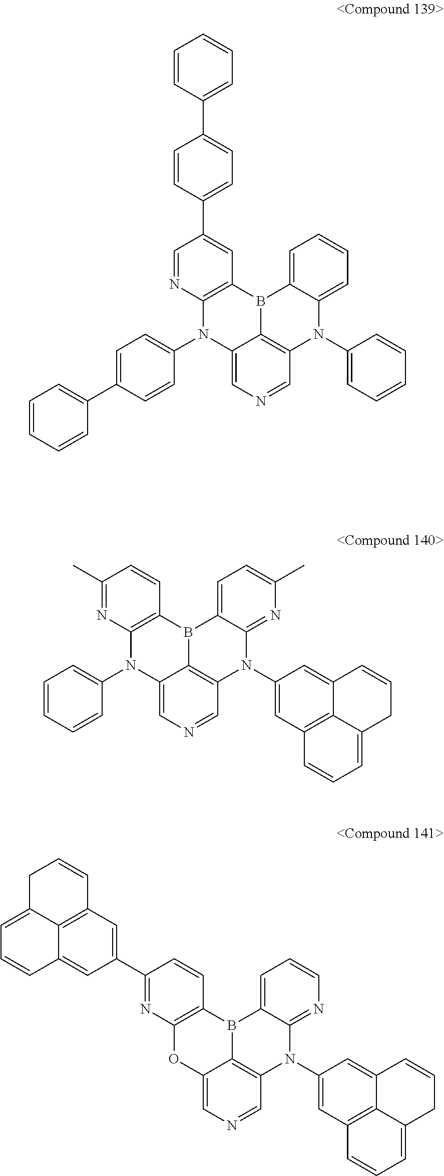 [SMILES: c1ccc(-c2ccc(-c3cnc4c(c3)B3c5ccccc5N(c5ccccc5)c5cncc(c53)N4c3ccc(-c4ccccc4)cc3)cc2)cc1 ; Cc1ccc2c(n1)N(c1ccccc1)c1cncc3c1B2c1ccc(C)nc1N3c1cc2c3c(cccc3c1)CC=C2 ; C1=Cc2cc(-c3ccc4c(n3)Oc3cncc5c3B4c3cccnc3N5c3cc4c5c(cccc5c3)CC=C4)cc3cccc(c23)C1]

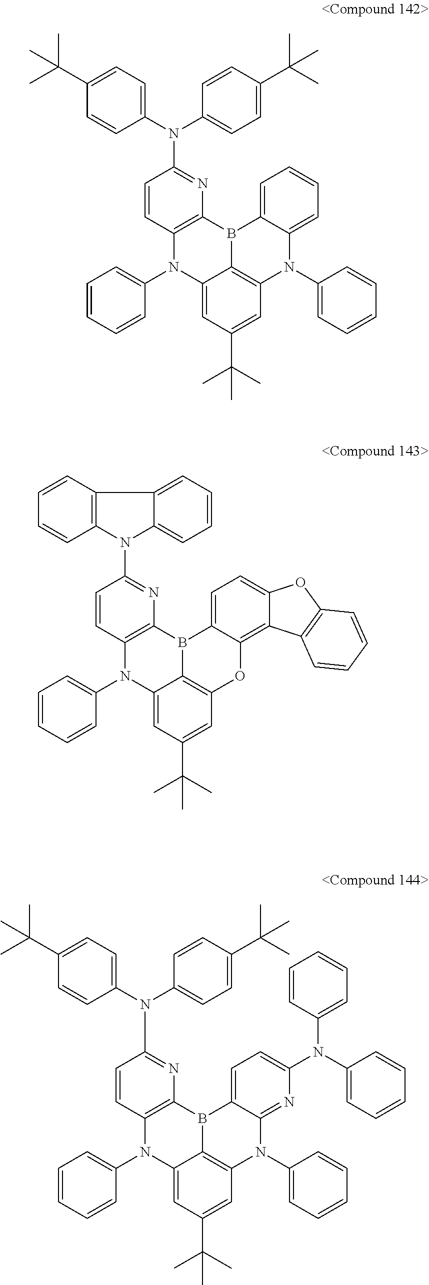 [SMILES: CC(C)(C)c1ccc(N(c2ccc(C(C)(C)C)cc2)c2ccc3c(n2)B2c4ccccc4N(c4ccccc4)c4cc(C(C)(C)C)cc(c42)N3c2ccccc2)cc1 ; CC(C)(C)c1cc2c3c(c1)N(c1ccccc1)c1ccc(-n4c5ccccc5c5ccccc54)nc1B3c1ccc3oc4ccccc4c3c1O2 ; CC(C)(C)c1ccc(N(c2ccc(C(C)(C)C)cc2)c2ccc3c(n2)B2c4ccc(N(c5ccccc5)c5ccccc5)nc4N(c4ccccc4)c4cc(C(C)(C)C)cc(c42)N3c2ccccc2)cc1]

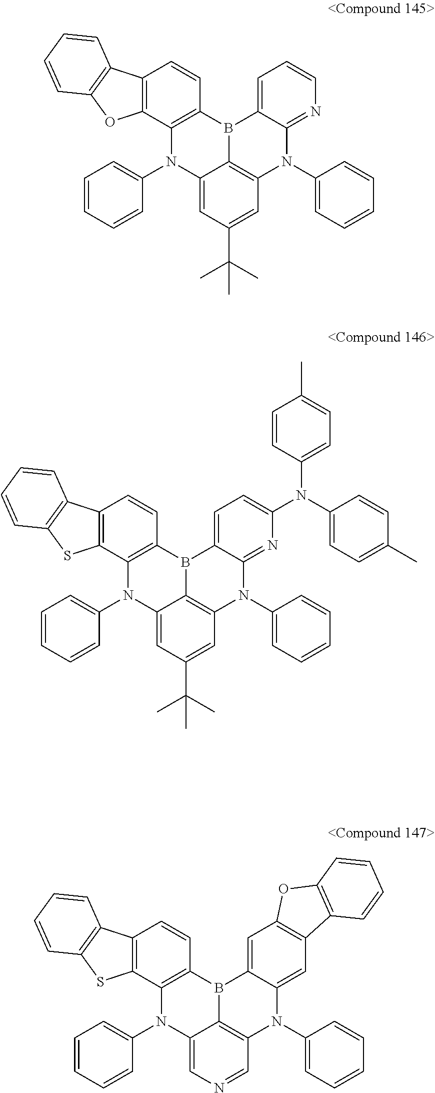 [SMILES: CC(C)(C)c1cc2c3c(c1)N(c1ccccc1)c1c(ccc4c1oc1ccccc14)B3c1cccnc1N2c1ccccc1 ; Cc1ccc(N(c2ccc(C)cc2)c2ccc3c(n2)N(c2ccccc2)c2cc(C(C)(C)C)cc4c2B3c2ccc3c(sc5ccccc53)c2N4c2ccccc2)cc1 ; c1ccc(N2c3cc4c(cc3B3c5ccc6c(sc7ccccc76)c5N(c5ccccc5)c5cncc2c53)oc2ccccc24)cc1]

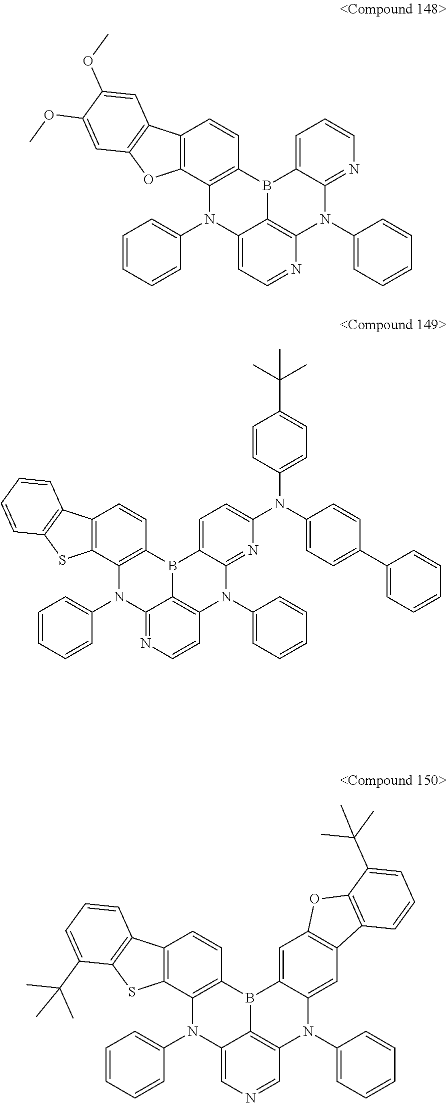 [SMILES: COc1cc2oc3c4c(ccc3c2cc1OC)B1c2cccnc2N(c2ccccc2)c2nccc(c21)N4c1ccccc1 ; CC(C)(C)c1ccc(N(c2ccc(-c3ccccc3)cc2)c2ccc3c(n2)N(c2ccccc2)c2ccnc4c2B3c2ccc3c(sc5ccccc53)c2N4c2ccccc2)cc1 ; CC(C)(C)c1cccc2c1oc1cc3c(cc12)N(c1ccccc1)c1cncc2c1B3c1ccc3c(sc4c(C(C)(C)C)cccc43)c1N2c1ccccc1]

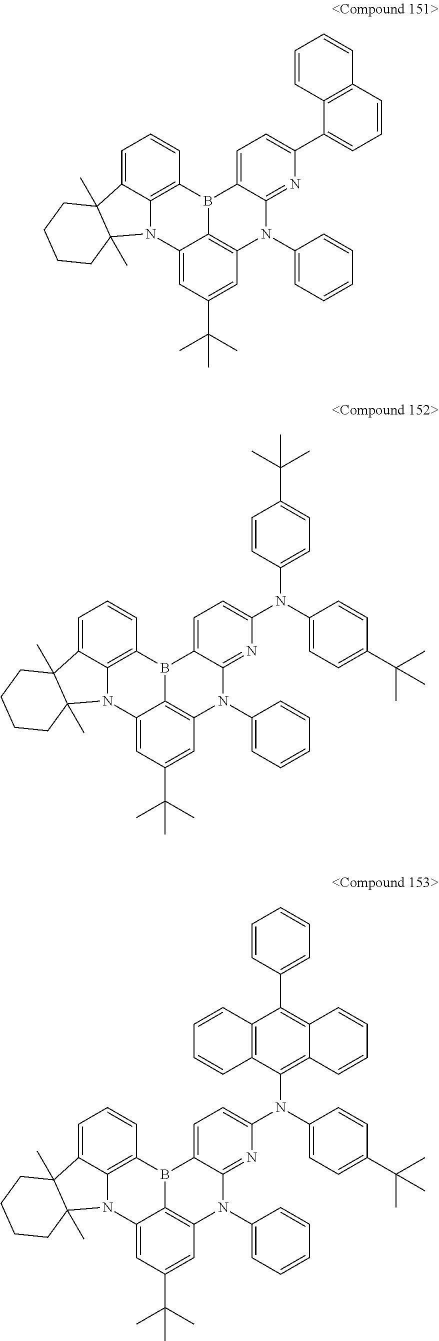 [SMILES: CC(C)(C)c1cc2c3c(c1)N1c4c(cccc4C4(C)CCCCC14C)B3c1ccc(-c3cccc4ccccc34)nc1N2c1ccccc1 ; CC(C)(C)c1ccc(N(c2ccc(C(C)(C)C)cc2)c2ccc3c(n2)N(c2ccccc2)c2cc(C(C)(C)C)cc4c2B3c2cccc3c2N4C2(C)CCCCC32C)cc1 ; CC(C)(C)c1ccc(N(c2ccc3c(n2)N(c2ccccc2)c2cc(C(C)(C)C)cc4c2B3c2cccc3c2N4C2(C)CCCCC32C)c2c3ccccc3c(-c3ccccc3)c3ccccc23)cc1]

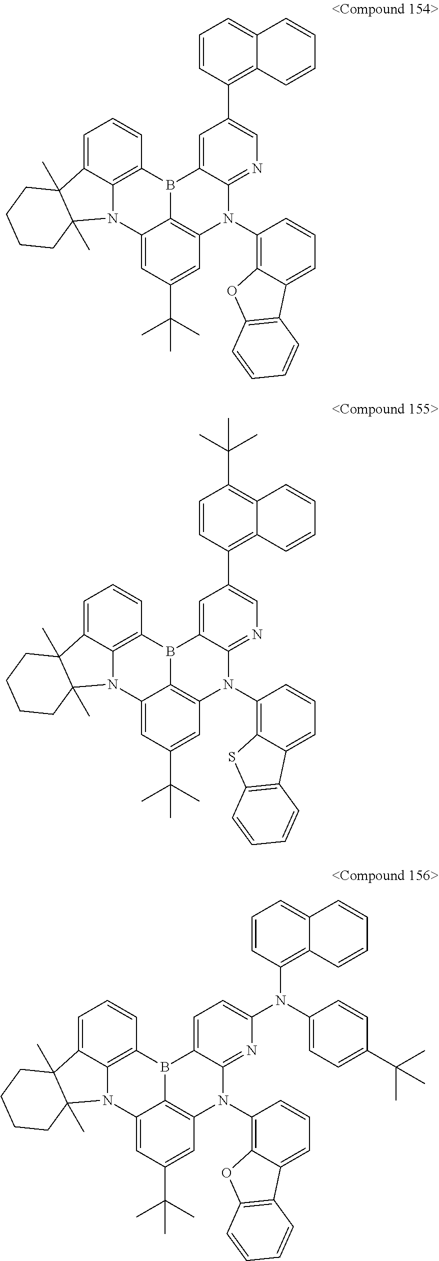

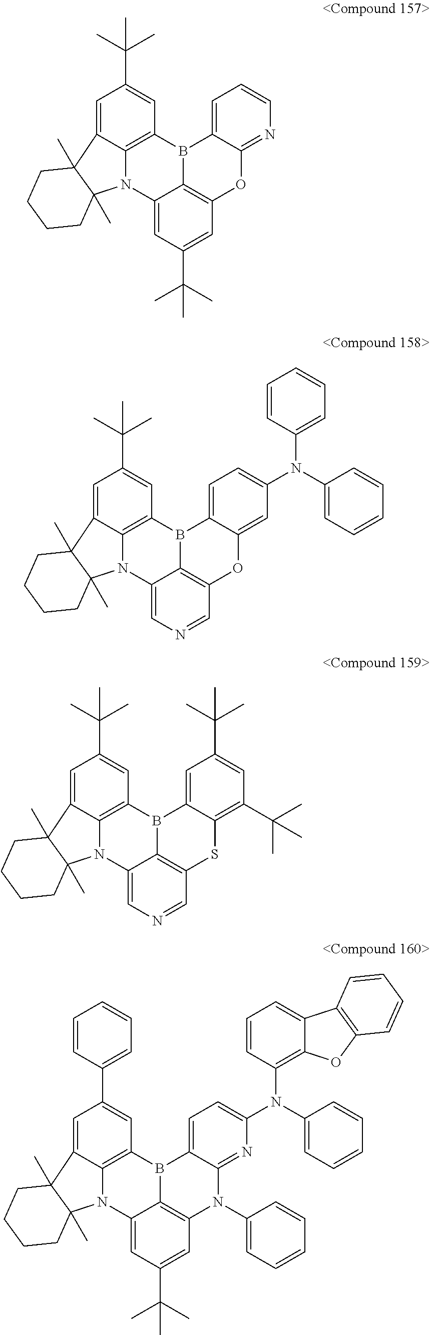 [SMILES: CC(C)(C)c1cc2c3c(c1)N1c4c(cc(C(C)(C)C)cc4C4(C)CCCCC14C)B3c1cccnc1O2 ; CC(C)(C)c1cc2c3c(c1)C1(C)CCCCC1(C)N3c1cncc3c1B2c1ccc(N(c2ccccc2)c2ccccc2)cc1O3 ; CC(C)(C)c1cc2c(c(C(C)(C)C)c1)Sc1cncc3c1B2c1cc(C(C)(C)C)cc2c1N3C1(C)CCCCC21C ; CC(C)(C)c1cc2c3c(c1)N1c4c(cc(-c5ccccc5)cc4C4(C)CCCCC14C)B3c1ccc(N(c3ccccc3)c3cccc4c3oc3ccccc34)nc1N2c1ccccc1]

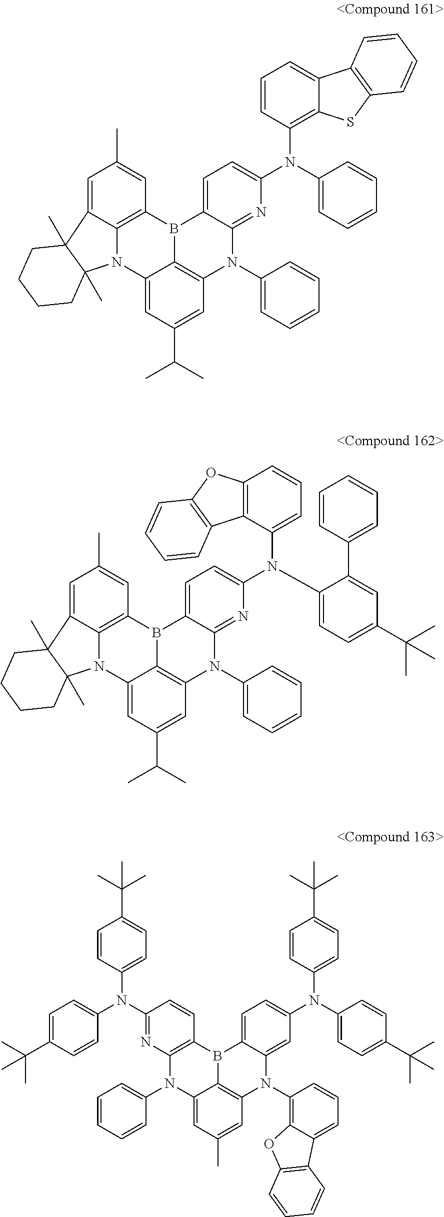

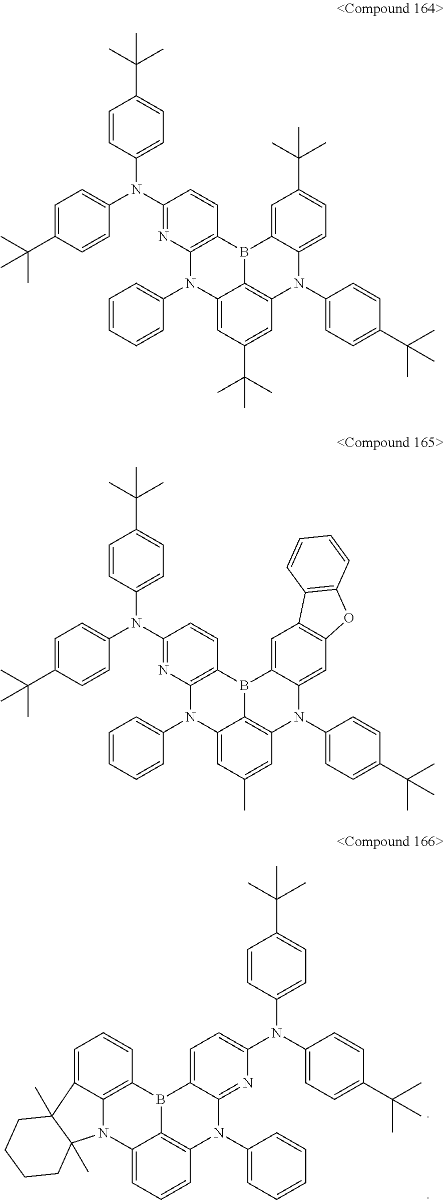

14. An organic light-emitting diode, comprising:
a first electrode;
a second electrode facing the second electrode; and
an organic layer interposed between the first electrode and the second electrode, wherein the organic layer includes the boron compound of claim 1.

15. The organic light-emitting diode of claim 14, wherein the organic layer comprises at least one of a hole injection layer, a hole transport layer, a functional layer capable of both hole injection and hole transport, an electron blocking layer, a light-emitting layer, an electron transport layer, an electron injection layer, and a capping layer.

16. The organic light-emitting diode of claim 14, wherein the organic layer disposed between the first electrode and the second electrode includes a light-emitting layer composed of a host and a dopant, the boron compound represented by Chemical Formula A servings as the dopant.

17. The organic light-emitting diode of claim 16, wherein the light-emitting layer uses an anthracene derivative represented by the following Chemical Formula D as the host: 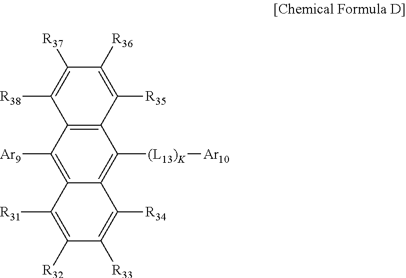
wherein,
R₃₁ to R₃₈, which are same or different, are each as defined for R₁ to R₁₁ in claim 1;
Ar₉ and Ar₁₀, which are same or different, are each independently any one selected from a hydrogen atom, a deuterium atom, a substituted or unsubstituted alkyl of 1 to 30 carbon atoms, a substituted or unsubstituted aryl of 6 to 50 carbon atoms, a substituted or unsubstituted alkenyl of 2 to 30 carbon atoms, a substituted or unsubstituted alkynyl 2 to 20 carbon atoms, a substituted or unsubstituted cycloalkyl of 3 to 30 carbon atoms, a substituted or unsubstituted cycloalkenyl 5 to 30 carbon atoms, a substituted or unsubstituted heteroaryl of 2 to 50 carbon atoms, a substituted or unsubstituted heterocycloalkyl of 2 to 30 carbon atoms, a substituted or unsubstituted alkoxy of 1 to 30 carbon atoms, a substituted or unsubstituted aryloxy of 6 to 30 carbon atoms, a substituted or unsubstituted alkylthioxy of 1 to 30 carbon atoms, a substituted or unsubstituted arylthioxy of 6 to 30 carbon atoms, a substituted or unsubstituted alkylamine of 1 to 30 carbon atoms, a substituted or unsubstituted arylamine of 6 to 30 carbon atoms, a substituted or unsubstituted alkylsilyl of 1 to 30 carbon atoms, and a substituted or unsubstituted arylsilyl of 6 to 30 carbon atoms;
L₁₃, which functions as a linker, is a single bond or is selected from a substituted or unsubstituted arylene of 6 to 20 carbon atoms, and a substituted or unsubstituted heteroarylene of 2 to 20 carbon atoms; and
k is an integer of 1 to 3, wherein when k is 2 or greater, the corresponding L₁₃'s are same or different,
wherein the term “substituted” in the expression “substituted or unsubstituted” is as defined in claim 1.

18. The organic light-emitting diode of claim 17, wherein Ar9 in Chemical Formula D is a substituent represented by the following Chemical Formula D-1: 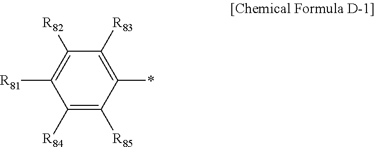
wherein, R₈₁ to R₈₅, which are same or different, each are as defined for R₁ to R₁₁ in claim 1; and can each be linked to an adjacent one to form a saturated or unsaturated cyclic ring.

19. The organic light-emitting diode of claim 15, wherein at least one selected from among the layers is deposited using a deposition process or a solution process.

20. The organic light-emitting diode of claim 14, wherein the organic light-emitting diode is used for a device selected from among a flat display device; a flexible display device; a monochrome or grayscale flat illumination; and a monochrome or grayscale flexible illumination device.
